(19) United States
(12) Patent Application Publication
(10) Pub. No.: US 2025/0306088 A1
(43) Pub. Date: Oct. 2, 2025

(54) ELECTRICAL CONNECTOR AND TEST DEVICE COMPRISING THE SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG, Gyeonggi-do (KR)

(73) Assignee: POINT ENGINEERING CO., LTD., Chungcheongnam-do (KR)

(21) Appl. No.: 19/092,096

(22) Filed: Mar. 27, 2025

(30) Foreign Application Priority Data
Mar. 29, 2024 (KR) 10-2024-0043084

(51) Int. Cl. G01R 31/28

(52) U.S. Cl. CPC G01R 31/2884

(57) ABSTRACT

The electrical connector of the present invention comprises a plurality of unit needle pins arranged to be spaced apart from each other and having beam portions extending in a longitudinal direction to be elastically deformed; and a connecting portion fixing the plurality of unit needle pins to be spaced apart from each other. By including these components, the present invention provides an electrical connector with a significantly increased surface area, resulting in improved current carrying capacity (CCC), and an inspection apparatus comprising the same. Additionally, the present invention provides a highly reliable electrical connector and an inspection apparatus comprising the same.

### CROSS REFERENCE TO RELATED APPLICATION

The present application claims priority to Korean Patent Application No. 10-2024-0043084, filed Mar. 29, 2024, the entire contents of which is incorporated herein for all purposes by this reference.

### BACKGROUND OF THE INVENTION

### Field of the Invention

The present invention relates to an electrical connector for electrical connection and an inspection apparatus comprising the same.

### Description of the Related Art

Inspection targets such as semiconductor devices or display panels undergo predetermined defect inspections to determine their defect status. For this purpose, the inspection target can be judged for defects by electrical signals from the inspection device while being electrically connected to the inspection device.

The electrical characteristic test of a semiconductor device is performed by bringing the inspection target (semiconductor wafer or semiconductor package) close to an inspection device equipped with multiple electrical connectors and contacting the conductive pins to corresponding external terminals (such as solder balls or bumps) on the inspection target. Examples of inspection devices include probe cards or test sockets, but are not limited to these.

The inspection at the semiconductor package level is performed by a test socket. For example, test sockets include pogo-type test sockets and rubber-type test sockets.

The electrical connector used in a pogo-type test socket comprises a pin portion and a barrel that houses it. The pin portion is configured to provide necessary contact pressure and absorb impact at the contact position by installing a spring member between plungers at both ends. For the pin portion to slide within the barrel, there must be a gap between the outer surface of the pin portion and the inner surface of the barrel. However, since the pogo-type connector is used by separately manufacturing the barrel and the pin portion and then combining them, it is difficult to precisely manage the gap, leading to issues such as the outer surface of the pin portion being excessively spaced from the inner surface of the barrel. Consequently, there is a problem of inconsistent contact stability due to signal loss and distortion during the transmission of electrical signals through the barrel via the plungers at both ends. Additionally, it is challenging to manufacture in small sizes because the barrel and pin portion are separately made and then combined. Therefore, conventional pogo-type electrical connectors have limitations in responding to fine-pitch technology trends.

On the other hand, the electrical connector used in a rubber-type test socket has a structure where conductive particles are placed inside a rubber material such as silicone rubber. When the inspection target (e.g., semiconductor package) is placed and the socket is closed, applying stress causes the conductive particles to press against each other, increasing conductivity and establishing an electrical connection. However, this rubber-type electrical connector has the problem of requiring high pressing force to ensure contact stability. Additionally, repeated contact with the semiconductor package terminals can cause the conductive particles to detach or become embedded in the silicone rubber, ultimately failing to function as a connector. Furthermore, conventional rubber-type electrical connectors are made by preparing a molding material with conductive particles distributed in an elastic material, inserting the molding material into a predetermined mold, and applying a magnetic field in the thickness direction to align the conductive particles in the thickness direction. If the magnetic field spacing is narrow, the conductive particles may align irregularly, causing signals to flow in the plane direction. Therefore, conventional rubber-type electrical connectors have limitations in responding to fine-pitch technology trends.

To overcome these limitations, technologies for manufacturing electrical connectors using MEMS processes have recently been developed (e.g., Korean Patent Publication No. 10-2024-0032783, Korean Patent Publication No. 10-2024-0017651).

Meanwhile, when high-frequency testing is required, such as for RF (Radio Frequency) semiconductor devices, the current carrying capacity (CCC) of the electrical connector needs to be large. However, the proposed structures so far have limitations in significantly improving the current carrying capacity (CCC). Additionally, there is a need to develop highly reliable electrical connectors during the inspection process.

### PRIOR ART DOCUMENTS

### Patent Documents

(Patent Document 1) Korean Patent Publication No. 10-2024-0032783
(Patent Document 2) Korean Patent Publication No. 10-2024-0017651

### SUMMARY OF THE INVENTION

The present invention has been devised to solve the problems of the prior art described above, and its purpose is to provide an electrical connector for electrical connection with an increased surface area for improved current carrying capacity (CCC) and an inspection apparatus comprising the same.

Additionally, the present invention aims to provide a highly reliable electrical connector and an inspection apparatus comprising the same.

To achieve the above objectives, the electrical connector according to the present invention comprises a plurality of unit needle pins arranged to be spaced apart from each other and having beam portions extending in a longitudinal direction to be elastically deformed; and a connecting portion fixing the plurality of unit needle pins to be spaced apart from each other.

Additionally, the connecting portion is formed in a first direction and a second direction perpendicular to the longitudinal direction of the unit needle pin.

Furthermore, the unit needle pin includes a beam portion and a tip portion, and the unit needle pins adjacent to each other are bundled to be spaced apart from each other through the connecting portion provided between the beam portion and the tip portion.

Moreover, the unit needle pin includes a beam portion and a tip portion, and the plurality of unit needle pins are connected to each other by the connecting portion, and each of the beam portions are spaced apart from each other and each of the tip portions are also spaced apart from each other.

Meanwhile, the electrical connector according to the present invention comprises a deformation array having a plurality of beam portions extending in a longitudinal direction to be elastically deformed; and a connecting portion to which the beam portions of the deformation array are connected.

Additionally, the deformation array has the beam portions spaced apart from each other in a first direction.

Furthermore, the deformation array has the beam portions spaced apart from each other in the first direction and also spaced apart from each other in a second direction perpendicular to the first direction.

Moreover, the electrical connector further comprises a tip portion provided on an upper portion of the connecting portion.

Additionally, the tip portion is provided to be spaced apart from each other in the first direction.

Furthermore, the tip portion is provided to be spaced apart from each other in the first direction and also spaced apart from each other in the second direction.

Moreover, the electrical connector further comprises a stopper preventing excessive compressive deformation of the deformation array.

Additionally, a length dimension of the connecting portion in the first direction is greater than a length dimension of the deformation array in the first direction.

Furthermore, a length dimension of the connecting portion in the second direction is greater than a length dimension of the deformation array in the second direction.

Moreover, a length dimension of the connecting portion in the first direction is greater than a length dimension of the deformation array in the first direction, and a length dimension of the connecting portion in the second direction is greater than a length dimension of the deformation array in the second direction.

Additionally, the connecting portion includes an upper connecting portion provided on an upper portion of the deformation array; and a lower connecting portion provided on a lower portion of the deformation array.

Furthermore, the electrical connector further comprises an upper tip portion provided on an upper portion of the upper connecting portion; and a lower tip portion provided on a lower portion of the lower connecting portion.

Moreover, the electrical connector comprises a subsequent plating layer formed on a surface of the electrical connector.

Additionally, the subsequent plating layer is also provided inside the connecting portion by penetrating through the inside of the connecting portion.

Meanwhile, the inspection apparatus according to the present invention comprises a guide plate having guide holes; and an electrical connector located inside the guide hole and including a deformation array having a plurality of beam portions extending in a longitudinal direction to be elastically deformed, and a connecting portion connecting the beam portions of the deformation array and capable of being caught on an upper end of the guide hole.

Furthermore, the deformation array has the beam portions spaced apart from each other in a first direction and also spaced apart from each other in a second direction perpendicular to the first direction.

The present invention provides an electrical connector with an increased surface area, resulting in improved current carrying capacity (CCC), and an inspection apparatus comprising the same.

Additionally, the present invention provides a highly reliable electrical connector and an inspection apparatus comprising the same.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of an electrical connector according to a preferred first embodiment of the present invention.

FIG. 2A is a front view of an electrical connector according to a preferred first embodiment of the present invention.

FIG. 2B is a sectional view taken along line A-A′ of FIG. 2A.

FIG. 2C is a sectional view taken along line B-B′ of FIG. 2A.

FIG. 2D is a sectional view taken along line C-C′ of FIG. 2A.

FIG. 3A is a view illustrating a step of forming a first space in a mold in the manufacturing method of the electrical connector according to the first embodiment, and FIG. 3B is a sectional view taken along line A-A′ of FIG. 3A, FIG. 3C is a sectional view taken along line B-B′ of FIG. 3A, and FIG. 3D is a sectional view taken along line C-C′ of FIG. 3A.

FIG. 4A is a view illustrating a step of forming a first metal layer and a second metal layer in the first space in the manufacturing method of the electrical connector according to the first embodiment, and FIG. 4B is a sectional view taken along line A-A′ of FIG. 4A, FIG. 4C is a sectional view taken along line B-B′ of FIG. 4A, and FIG. 4D is a sectional view taken along line C-C′ of FIG. 4A.

FIG. 5A is a view illustrating a step of forming a second space in a mold in the manufacturing method of the electrical connector according to the first embodiment, and FIG. 5B is a sectional view taken along line A-A′ of FIG. 5A, FIG. 5C is a sectional view taken along line B-B′ of FIG. 5A, and FIG. 5D is a sectional view taken along line C-C′ of FIG. 5A.

FIG. 6A is a view illustrating a step of removing the first metal layer using the second space in the manufacturing method of the electrical connector according to the first embodiment, and FIG. 6B is a sectional view taken along line A-A′ of FIG. 6A, FIG. 6C is a sectional view taken along line B-B′ of FIG. 6A, and FIG. 6D is a sectional view taken along line C-C′ of FIG. 6A.

FIG. 7A is a view illustrating a step of forming a second metal layer in the second space in the manufacturing method of the electrical connector according to the first embodiment, and FIG. 7B is a sectional view taken along line A-A′ of FIG. 7A, FIG. 7C is a sectional view taken along line B-B′ of FIG. 7A, and FIG. 7D is a sectional view taken along line C-C′ of FIG. 7A.

FIG. 8A is a view illustrating a step of removing the mold and the first metal layer in the manufacturing method of the electrical connector according to the first embodiment, and FIG. 8B is a sectional view taken along line A-A′ of FIG. 8A, FIG. 8C is a sectional view taken along line B-B′ of FIG. 8A, and FIG. 8D is a sectional view taken along line C-C′ of FIG. 8A.

FIG. 9A is a view illustrating a step of forming a subsequent plating layer on the surface of the electrical connector in the manufacturing method of the electrical connector according to the first embodiment, and FIG. 9B is a sectional view taken along line A-A′ of FIG. 9A, FIG. 9C is a sectional view taken along line B-B′ of FIG. 9A, and FIG. 9D is a sectional view taken along line C-C′ of FIG. 9A.

FIG. 10A is a view illustrating a step of leaving a part of the first metal layer at the position corresponding to the connecting portion in the step of removing the first metal layer using the second space, and FIG. 10B is a view illustrating a step of forming a second metal layer in the second space while a part of the first metal layer remains at the position corresponding to the connecting portion, FIG. 10C is a view illustrating a step of forming a void by removing the remaining part of the first metal layer at the position corresponding to the connecting portion, and FIG. 10D is a view illustrating a step of forming a subsequent plating layer in the void at the position corresponding to the connecting portion.

FIG. 11 is a sectional view showing the state in which the electrical connector according to the first embodiment is installed on a guide plate.

FIG. 12 is a plan view showing the state in which the electrical connector according to the first embodiment is installed on a guide plate.

FIG. 13 is a view showing an inspection target being inspected using an inspection apparatus including an electrical connector and a guide plate.

FIG. 14 is a perspective view of an electrical connector according to a preferred second embodiment of the present invention.

FIG. 15 is a perspective view of an electrical connector according to a preferred third embodiment of the present invention.

FIG. 16A is a front view of an electrical connector according to a preferred third embodiment of the present invention.

FIG. 16B is a sectional view taken along line A-A′ of FIG. 16A.

FIG. 16C is a sectional view taken along line B-B′ of FIG. 16A.

FIG. 16D is a sectional view taken along line C-C′ of FIG. 16A.

FIG. 17 is a perspective view of an electrical connector according to a preferred fourth embodiment of the present invention.

FIG. 18A is a front view of an electrical connector according to a preferred fourth embodiment of the present invention.

FIG. 18B is a sectional view taken along line A-A′ of FIG. 18A.

FIG. 18C is a sectional view taken along line B-B′ of FIG. 18A.

FIG. 18D is a sectional view taken along line C-C′ of FIG. 18A.

FIG. 19 is a perspective view of an electrical connector according to a preferred fifth embodiment of the present invention.

FIG. 20A is a front view of an electrical connector according to a preferred fifth embodiment of the present invention.

FIG. 20B is a sectional view taken along line A-A′ of FIG. 20A.

FIG. 20C is a sectional view taken along line B-B′ of FIG. 20A.

FIG. 20D is a sectional view taken along line C-C′ of FIG. 20A.

FIG. 21 is a perspective view of an electrical connector according to a preferred sixth embodiment of the present invention.

FIG. 22A is a front view of an electrical connector according to a preferred sixth embodiment of the present invention.

FIG. 22B is a side view of an electrical connector according to a preferred sixth embodiment of the present invention.

FIG. 23 is a perspective view of an electrical connector according to a preferred seventh embodiment of the present invention.

FIG. 24A is a front view of an electrical connector according to a preferred seventh embodiment of the present invention.

FIG. 24B is a side view of an electrical connector according to a preferred seventh embodiment of the present invention.

FIG. 25 is a perspective view of an electrical connector according to a preferred eighth embodiment of the present invention.

FIG. 26A is a front view of an electrical connector according to a preferred eighth embodiment of the present invention.

FIG. 26B is a side view of an electrical connector according to a preferred eighth embodiment of the present invention.

FIG. 27 is a perspective view of an electrical connector according to a preferred ninth embodiment of the present invention.

FIG. 28A is a front view of an electrical connector according to a preferred ninth embodiment of the present invention.

FIG. 28B is a side view of an electrical connector according to a preferred ninth embodiment of the present invention.

FIG. 29 is a perspective view of an electrical connector according to a preferred tenth embodiment of the present invention.

FIG. 30A is a front view of an electrical connector according to a preferred tenth embodiment of the present invention.

FIG. 30B is a side view of an electrical connector according to a preferred tenth embodiment of the present invention.

FIG. 31 is a perspective view of an electrical connector according to a preferred eleventh embodiment of the present invention.

FIG. 32A is a front view of an electrical connector according to a preferred eleventh embodiment of the present invention.

FIG. 32B is a side view of an electrical connector according to a preferred eleventh embodiment of the present invention.

FIG. 33 is a perspective view of an electrical connector according to a preferred twelfth embodiment of the present invention.

FIG. 34A is a front view of an electrical connector according to a preferred twelfth embodiment of the present invention.

FIG. 34B is a side view of an electrical connector according to a preferred twelfth embodiment of the present invention.

FIG. 35A is a front view of a modified example of the electrical connector according to a preferred twelfth embodiment of the present invention.

FIG. 35B is a front view of a modified example of the electrical connector according to a preferred twelfth embodiment of the present invention.

FIG. 36A is a front view of a modified example of the electrical connector according to a preferred twelfth embodiment of the present invention.

FIG. 36B is a front view of a modified example of the electrical connector according to a preferred twelfth embodiment of the present invention.

FIG. 37 is a perspective view of a modified example of the electrical connector according to a preferred twelfth embodiment of the present invention.

FIG. 38A is a front view of FIG. 37.

FIG. 38B is a modified example of the electrical connector shown in FIG. 37.

FIG. 39A is a view showing an x-z plane at the position of the connecting portion according to a preferred embodiment of the present invention.

FIG. 39B is a view showing an x-z plane at the position of the connecting portion according to a preferred embodiment of the present invention.

FIG. 39C is a view showing an x-z plane at the position of the connecting portion according to a preferred embodiment of the present invention.

FIG. 39D is a view showing an x-z plane at the position of the connecting portion according to a preferred embodiment of the present invention.

FIG. 39E is a diagram showing an x-z plane view at the connecting portion according to a preferred embodiment of the present invention.

FIG. 39F is a diagram showing an x-z plane view at the connecting portion according to a preferred embodiment of the present invention.

FIG. 40A is a diagram showing an x-z plane view at the connecting portion according to a preferred embodiment of the present invention.

FIG. 40B is a diagram showing an x-z plane view at the connecting portion according to a preferred embodiment of the present invention.

FIG. 40C is a diagram showing an x-z plane view at the connecting portion according to a preferred embodiment of the present invention.

FIG. 40D is a diagram showing an x-z plane view at the connecting portion according to a preferred embodiment of the present invention.

### DETAILED DESCRIPTION OF THE INVENTION

The following content merely illustrates the principles of the invention. Therefore, those skilled in the art can devise various devices that embody the principles of the invention and fall within the concept and scope of the invention, even if not explicitly described or shown in this specification. Additionally, all conditional terms and embodiments listed in this specification are intended, in principle, solely to aid in understanding the concept of the invention and should not be understood as limiting the specifically listed embodiments and conditions.

The above-mentioned objectives, features, and advantages will become more apparent from the following detailed description in conjunction with the accompanying drawings, enabling those skilled in the art to easily implement the technical idea of the invention.

The embodiments described in this specification will be explained with reference to ideal exemplary cross-sectional and/or perspective views of the invention. The thicknesses of the films and regions shown in these drawings are exaggerated for effective explanation of the technical content. The shapes in the exemplary drawings may be modified due to manufacturing techniques and/or tolerances. Also, the number of structures shown in the drawings is illustrative and only a part of them is depicted. Therefore, the embodiments of the invention are not limited to the specific forms shown but also include variations generated according to the manufacturing process.

Hereinafter, the preferred embodiments of the present invention will be described in detail with reference to the accompanying drawings.

An electrical connector 100 according to a preferred embodiment of the present invention can be mounted on an inspection apparatus 10 to electrically and physically connect with an object to be inspected 20 and transmit electrical signals.

At least one of the objects to be inspected 20 may include a memory chip, microprocessor chip, logic chip, light-emitting device, substrate, or a combination thereof. At least one of the objects to be inspected 20 may include logic LSI (such as ASIC, FPGA, and ASSP), microprocessor (such as CPU and GPU), memory (such as DRAM, HMC (Hybrid Memory Cube), MRAM (Magnetic RAM), PCM (Phase-Change Memory), ReRAM (Resistive RAM), FeRAM (Ferroelectric RAM), and flash memory (NAND flash)), semiconductor light-emitting device (including LED, mini LED, micro LED, etc.), power device, analog IC (such as DC-AC converter and insulated gate bipolar transistor (IGBT)), MEMS (such as accelerometer, pressure sensor, vibrator, and gyro sensor), wireless device (such as GPS, FM, NFC, RFEM, MMIC, and WLAN), discrete device, BSI, CIS, camera module, CMOS, passive device, GAW filter, RF filter, RF IPD, APE, and BB. Hereinafter, a semiconductor device will be exemplified among the objects to be inspected 20, but it is not limited thereto, and the electrical connector according to a preferred embodiment of the present invention can be applied to inspect various objects to be inspected 20, including display panels, and the objects to be inspected 20 and the fields of use are not limited to any one.

The width direction of the electrical connector 100 described below is the ±x direction indicated in the drawings, the length direction of the electrical connector 100 is the ±y direction indicated in the drawings, and the thickness direction of the electrical connector 100 is the ±z direction indicated in the drawings.

### First Embodiment

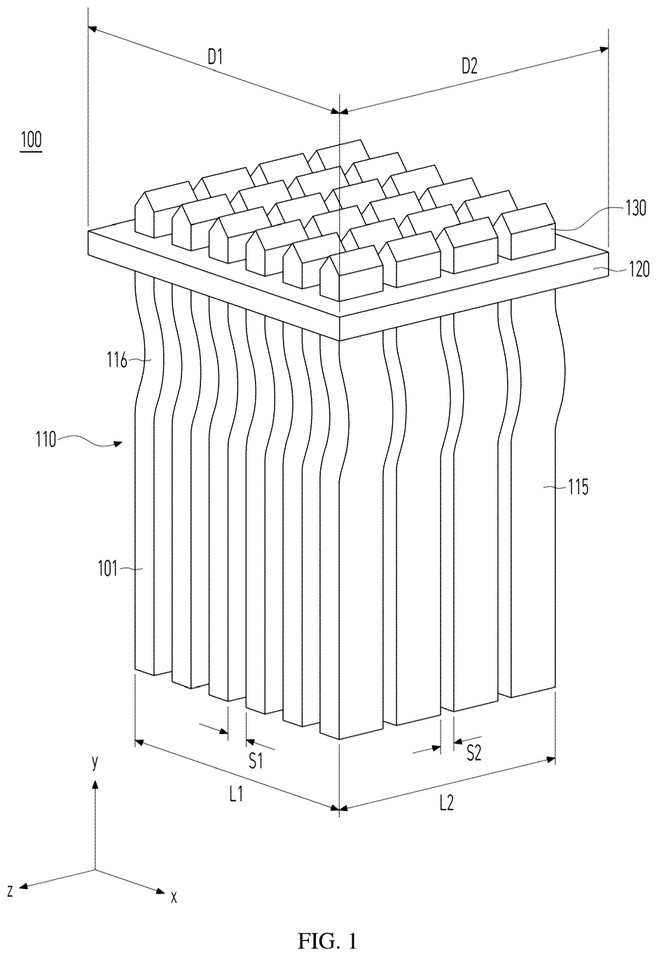

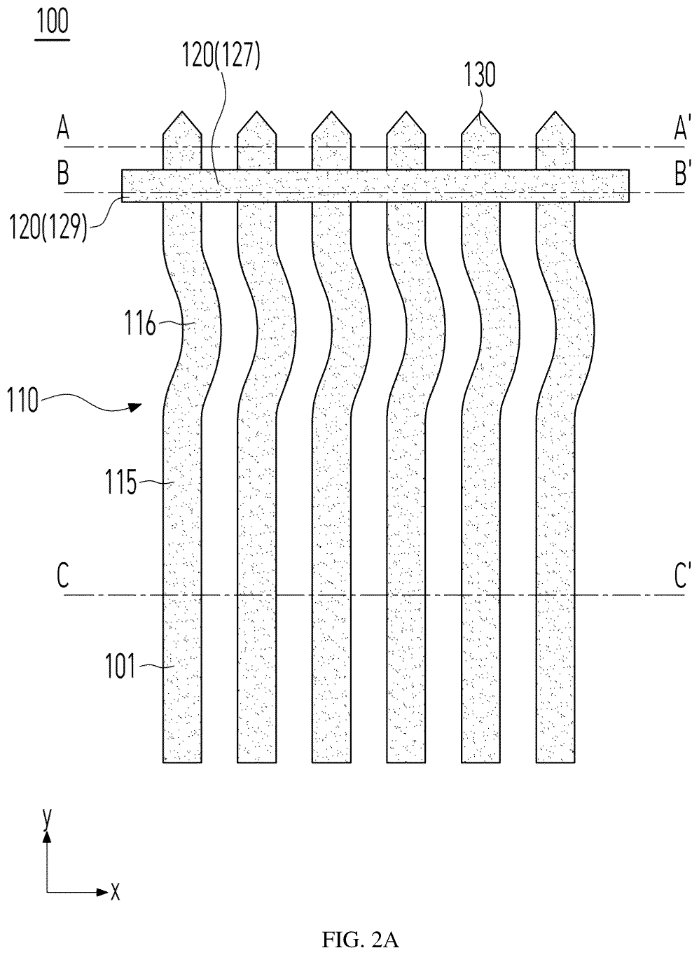

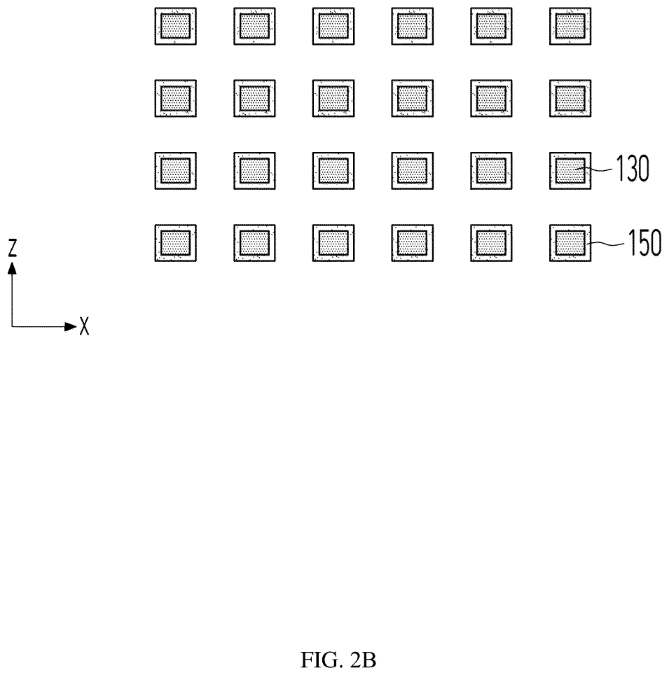

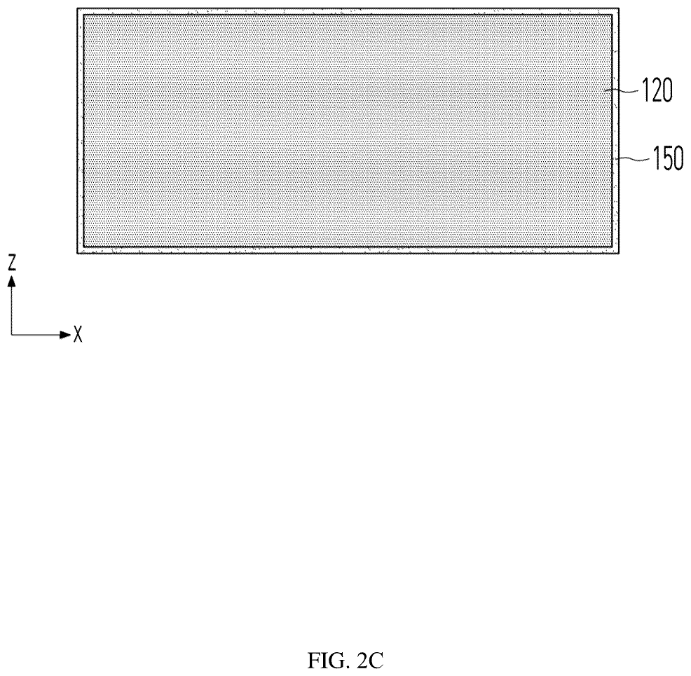

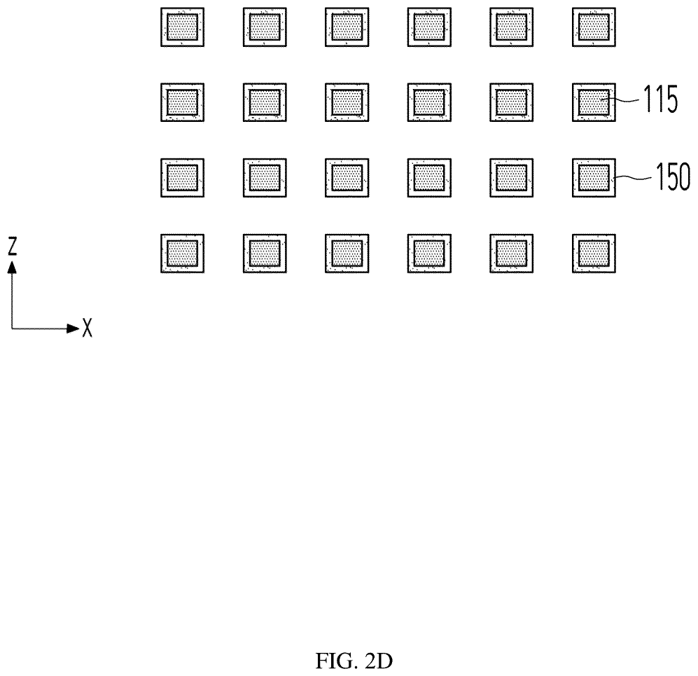

FIG. 1 is a perspective view of an electrical connector 100 according to a preferred first embodiment of the present invention, FIG. 2A is a front view of the electrical connector 100 according to the preferred first embodiment of the present invention, FIG. 2B is a cross-sectional view taken along line A-A′ of FIG. 2A, FIG. 2C is a cross-sectional view taken along line B-B′ of FIG. 2A, and FIG. 2D is a cross-sectional view taken along line C-C′ of FIG. 2A.

The electrical connector 100 comprises a deformation array 110 and a connecting portion 120.

The deformation array 110 includes a plurality of beam portions 115 extending in the longitudinal direction (±y direction) to be elastically deformed. Each beam portion 115 extends in the longitudinal direction (±y direction) and has a bent portion 116 formed in the middle. Each beam portion 115 is bent and deformed by an external force applied in the longitudinal direction (±y direction).

The cross-section of the beam portion 115 in the x-z plane is rectangular.

The beam portions 115 are spaced apart from each other in the first direction (±x direction). The plurality of beam portions 115 are spaced apart from each other by a first spacing gap S1 in the first direction (±x direction). Additionally, the beam portions 115 are spaced apart from each other in the second direction (±z direction) perpendicular to the first direction (±x direction). The plurality of beam portions 115 are spaced apart from each other by a second spacing gap S2 in the second direction (±z direction).

The deformation array 110 shown in FIG. 1 includes a plurality of beam portions 115 spaced apart from each other by a first spacing gap S1 in the first direction (±x direction) and also spaced apart from each other by a second spacing gap S2 in the second direction (Iz direction) perpendicular to the first direction (±x direction). The sizes of the first spacing gap S1 and the second spacing gap S2 may be the same or different.

The width of each beam portion 115 in the first direction (±x direction) is smaller than the thickness in the second direction (±z direction), and since it has a bent portion 116 bent in the first direction (±x direction), it is more easily elastically deformed in the first direction (±x direction) when subjected to compressive force in the longitudinal direction (±y direction).

The connecting portion 120 connects the beam portions 115 of the deformation array 110. The plurality of beam portions 115 are connected to one connecting portion 120. The plurality of beam portions 115 provided in a bundle form are connected to the connecting portion 120 while being spaced apart from each other and integrated.

The deformation array 110 has a length dimension L1 in the first direction (±x direction) and a length dimension L2 in the second direction (±z direction). Additionally, the connecting portion 120 has a length dimension D1 in the first direction (±x direction) and a length dimension D2 in the second direction (±z direction).

The length dimension D1 of the connecting portion 120 in the first direction (±x direction) is greater than the length dimension L1 of the deformation array 110 in the first direction (±x direction). Meanwhile, the length dimension D2 of the connecting portion 120 in the second direction (±z direction) is greater than the length dimension L2 of the deformation array 110 in the second direction (±z direction). As a result, the length dimension D1 of the connecting portion 120 in the first direction (±x direction) is greater than the length dimension L1 of the deformation array 110 in the first direction (±x direction), and the length dimension D2 of the connecting portion 120 in the second direction (±z direction) is greater than the length dimension L2 of the deformation array 110 in the second direction (±z direction).

A tip portion 130 is provided on the upper portion of the connecting portion 120. In other words, the tip portion 130 is provided on the upper portion of the connecting portion 120.

The tip portion 130 is provided to be spaced apart from each other in the first direction (±x direction). Meanwhile, the tip portion 130 is provided to be spaced apart from each other in the second direction (±z direction). Therefore, the tip portion 130 is provided to be spaced apart from each other in the first direction (±x direction) and also spaced apart from each other in the second direction (±z direction).

Each tip portion 130 can be provided in alignment with the longitudinal direction of each beam portion 115 corresponding to each beam portion 115.

The tip portion 130 includes a base portion with a constant cross-sectional area and a sharp portion located on the upper part of the base portion with a smaller cross-sectional area than the base portion. The sharp portion is the part that contacts the external terminal 21 of the object to be inspected 20, and the base portion is the part that ensures the rigidity of the sharp portion.

The spacing distance of the tip portions 130 in the first direction (±x direction) is the same as the spacing distance of the beam portions 115 in the first direction (±x direction), and the spacing distance of the tip portions 130 in the second direction (±z direction) is the same as the spacing distance of the beam portions 115 in the second direction (±z direction).

The electrical connector 100 comprises a plurality of unit needle pins 101 arranged to be spaced apart from each other and having beam portions 115 extending in a longitudinal direction to be elastically deformed, and at least one connecting portion 120 connecting them to each other. The electrical connector 100 is configured such that the plurality of unit needle pins 101 are connected to each other by the connecting portion 120, and each of the beam portions 115 are spaced apart from each other and each of the tip portions 130 are also spaced apart from each other. The unit needle pin 101 includes a beam portion 115 and a tip portion 130, and the unit needle pins 101 adjacent to each other are bundled to be spaced apart from each other through the connecting portion 120 provided between the beam portion 115 and the tip portion 130.

The connecting portion 120 is provided in a planar form, and the connecting portion 120 provided between the beam portion 115 and the tip portion 130 fills all the spaces between the unit needle pins 101, connecting the unit needle pins 101 without any gaps at the position where the connecting portion 120 is formed. This prevents foreign substances from penetrating into the beam portion 115 through the connecting portion 120. If foreign substances dropped from the inspection target 20 or introduced from the outside enter the beam portion 115, it adversely affects the elastic deformation of the beam portion 115. However, according to the embodiment of the present invention, since the connecting portion 120 and the unit needle pins 101 are connected without gaps, it blocks foreign substances from entering the beam portion 115, thereby maintaining the reliability of the electrical connector 100.

Since the unit needle pin 101 is provided with a bent portion 116, each unit needle pin 101 elastically deforms by an external force in the longitudinal direction (±y direction).

The connecting portion 120 fixes the plurality of unit needles 101 to be spaced apart from each other and allows the plurality ofunit needles 101 to move together. The connecting portion 120 is formed in the first direction (±x direction) and/or the second direction (±y direction) perpendicular to the longitudinal direction (±x direction) of the unit needle pin 101, performing the function of fixing the plurality of unit needle pins 101 to be spaced apart from each other, and such a connecting portion 120 may be provided at least one or more.

The connecting portion 120 includes an inner connecting portion 127 provided between the unit needle pins 101 and an outer connecting portion 129 provided in a cantilever form outwardly. The inner connecting portion 127 connects adjacent unit needle pins 101 to each other, and the outer connecting portion 129 connects a plurality of unit needle pins 101 on one side of the unit needle pins 101. The outer connecting portion is provided to protrude from the four sides of the electrical connector 100.

The body of the electrical connector 100 is preferably made of a metal with high wear resistance or rigidity, such as rhodium (Rd), platinum (Pt), iridium (Ir), palladium (Pd), nickel (Ni), manganese (Mn), tungsten (W), phosphorus (Ph), or alloys thereof, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy. However, it is not limited to these.

A subsequent plating layer 150 is formed on the surface of the electrical connector 100. The subsequent plating layer 150 is formed overall on the body of the electrical connector and is conformally formed along the body. The subsequent plating layer 150 is preferably made of a metal with high electrical conductivity, such as copper (Cu), silver (Ag), gold (Au), or alloys thereof. However, it is not limited to these. Preferably, it can be formed of gold (Au).

Conventionally, the elastically deformable part was composed of a single beam portion with a large cross-sectional area. However, according to a preferred embodiment of the present invention, instead of the conventional single beam portion, a configuration is adopted in which multiple beam portions 115 with small cross-sectional areas are arranged in an array form. In other words, the preferred embodiment of the present invention adopts a configuration in which a plurality of unit needle pins 101 are arranged in a bundled state by the connecting portion 120. According to the embodiment of the present invention, by arranging multiple beam portions 115 with small cross-sectional areas in an array form instead of a single beam portion with a large cross-sectional area, the surface area of the electrical connector 100 is significantly increased. Additionally, since the entire surface of the electrical connector 100 is coated with a metal with high electrical conductivity, the preferred embodiment of the present invention provides an electrical connector 100 with improved current carrying capacity (CCC) compared to the conventional one. Therefore, it can more effectively respond to high-frequency characteristic tests above the GHz range and improve reliability.

Hereinafter, a method for manufacturing the electrical connector 100 according to the first preferred embodiment of the present invention will be described with reference to the drawings.

The method for manufacturing the electrical connector 100 according to the first embodiment includes forming a first space 330 in a mold 310; forming a first metal layer 331 and a second metal layer 333 in the first space 330; forming a second space 340 in the mold 310; removing the first metal layer 331 using the second space 340; forming the second metal layer 333 in the second space 340; removing the mold 310 and the first metal layer 331; and forming a subsequent plating layer 150.

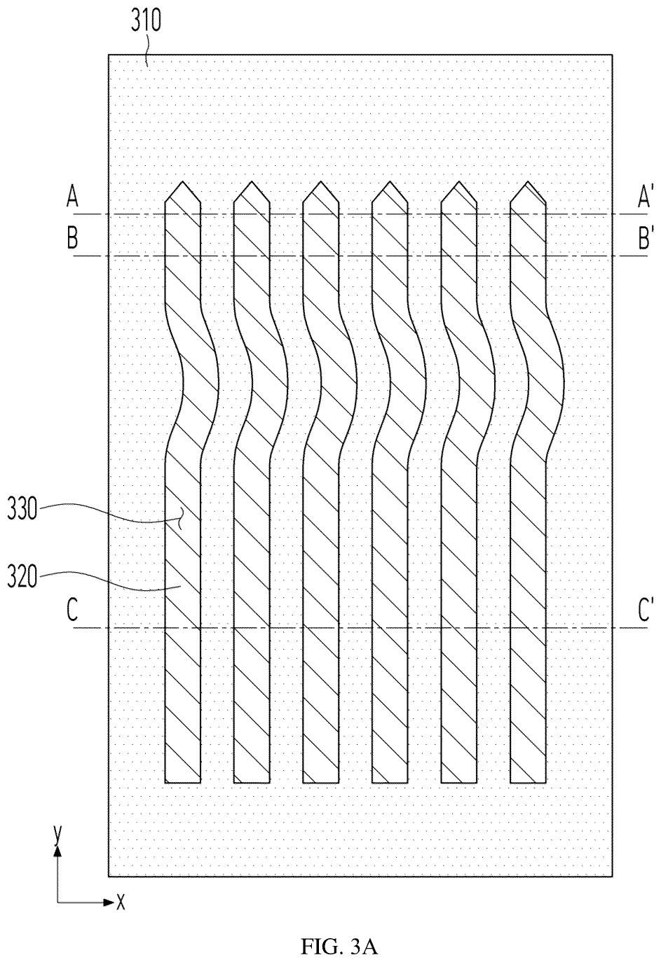

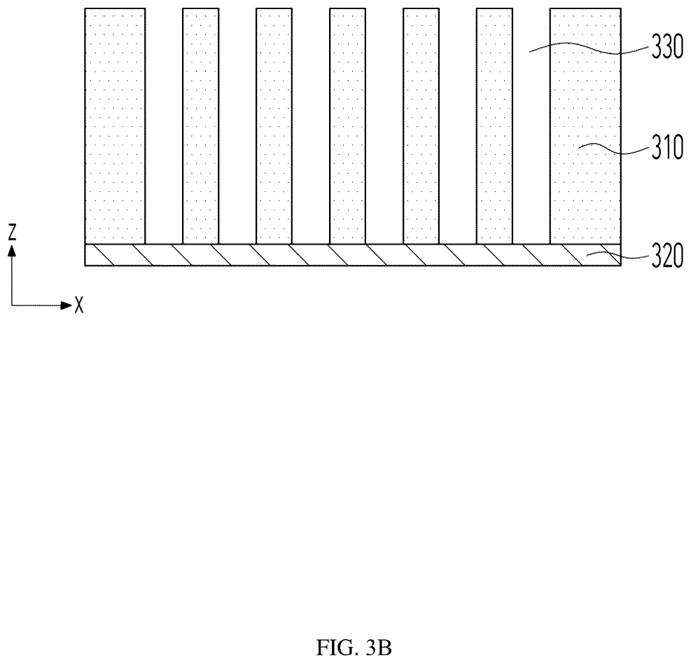

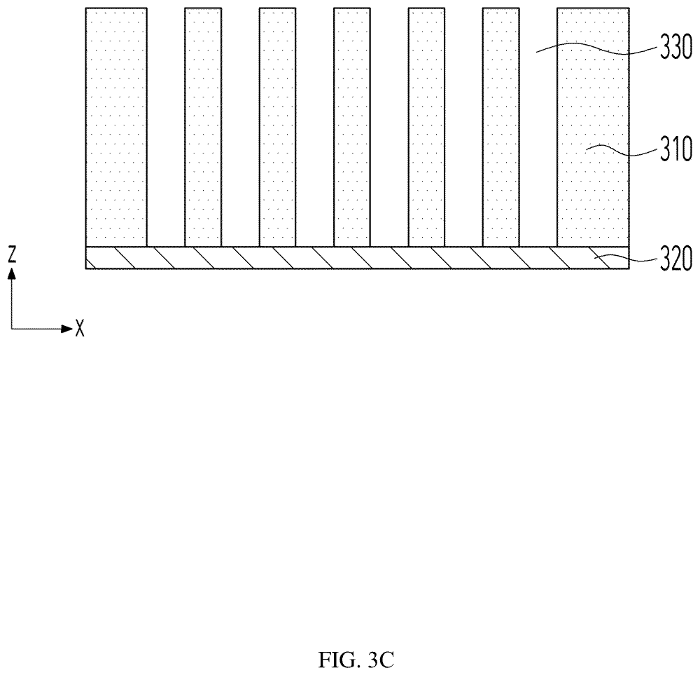

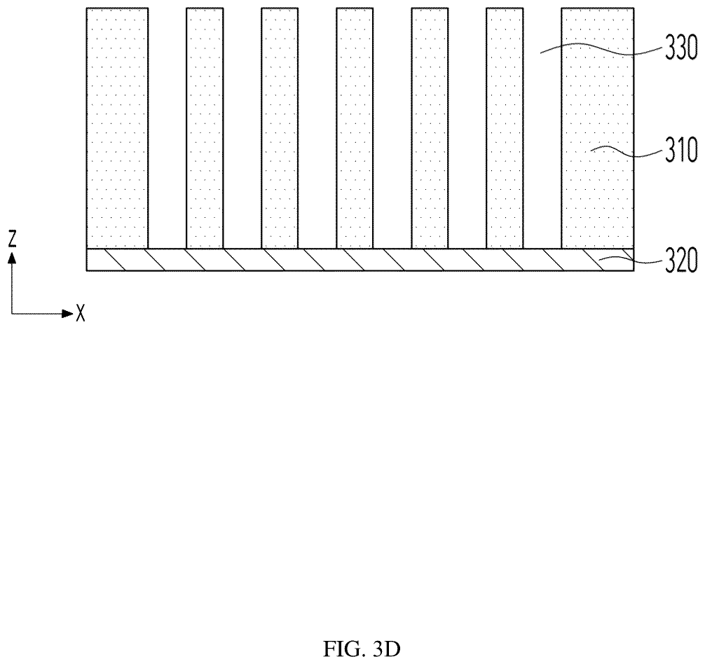

The step of forming the first space 330 in the mold 310 is performed. FIG. 3A is a view showing the first space 330 formed in the mold 310, FIG. 3B is a cross-sectional view taken along line A-A′ of FIG. 3A, FIG. 3C is a cross-sectional view taken along line B-B′ of FIG. 3A, and FIG. 3D is a cross-sectional view taken along line C-C′ of FIG. 3A.

The mold 310 may be made of anodized film, photoresist, silicon wafer, or similar material. However, preferably, the mold 310 may be made of anodized film material. An anodized film refers to a film formed by anodizing a base metal, and pores refer to holes formed during the process of forming the anodized film by anodizing the metal. For example, when the base metal is aluminum (Al) or an aluminum alloy, anodizing the base metal forms an anodized film of aluminum oxide (Al₂O₃) material on the surface of the base metal. However, the base metal is not limited to this and includes Ta, Nb, Ti, Zr, Hf, Zn, W, Sb, or alloys thereof. The anodized film formed as described above is divided into a barrier layer, which is not vertically formed with pores inside, and a porous layer, which is formed with pores inside. When the base metal with an anodized film having a barrier layer and a porous layer on the surface is removed, only the anodized film of aluminum oxide (Al₂O₃) material remains. The anodized film may be formed in a structure where the barrier layer formed during anodizing is removed, and the pores penetrate vertically, or in a structure where the barrier layer formed during anodizing remains, sealing one end of the pores. In FIG. 3A, the extension direction of the pores is the z-axis direction.

A seed layer 320 is provided on the back of the mold 310. A support substrate (not shown) is formed on the back of the seed layer 320 to improve the handling of the mold 310. The seed layer 320 is a layer formed for electroplating and can be formed by a deposition method.

The first space 330 can be formed by wet etching the mold 310 made of anodized film material. To do this, a photoresist is provided on the upper surface of the mold 310 (the opposite surface to the one with the seed layer 320), and after patterning it, the anodized film in the patterned and opened area reacts with the etching solution to form the first space 330.

The first space 330 is formed long in the longitudinal direction (±y direction). The shape of the first space 330 in the x-y plane becomes the shape of the tip portion 130 and the beam portion 115 in the x-y plane.

The first space 330 can be formed in the shape of needle pins.

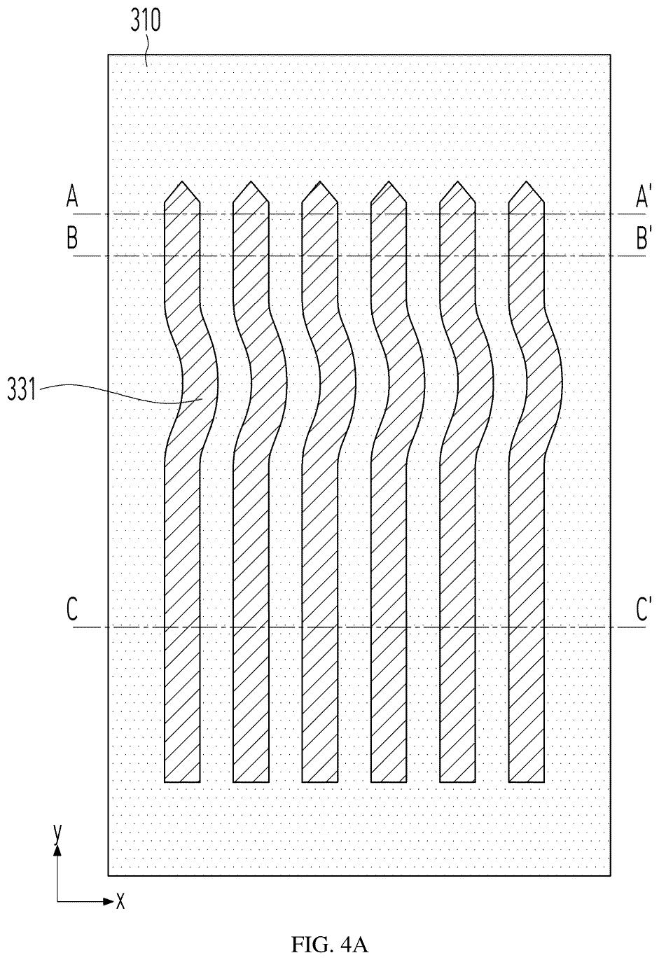

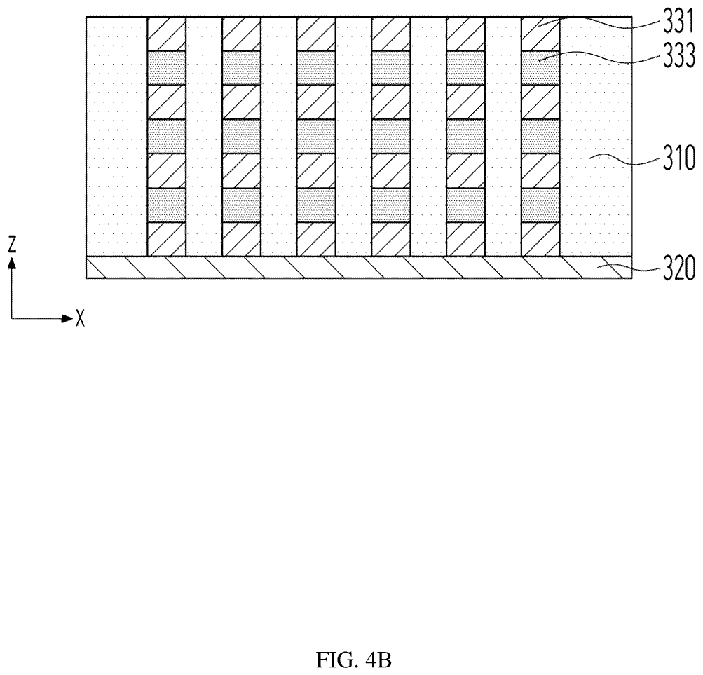

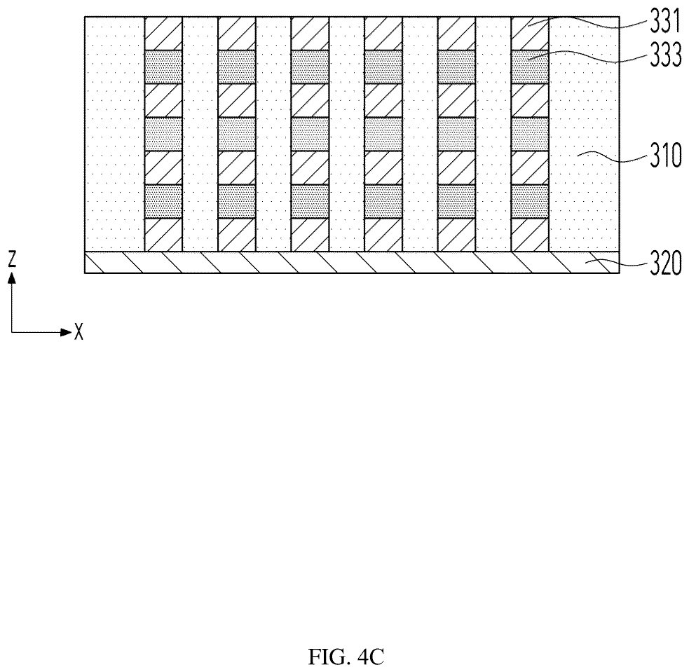

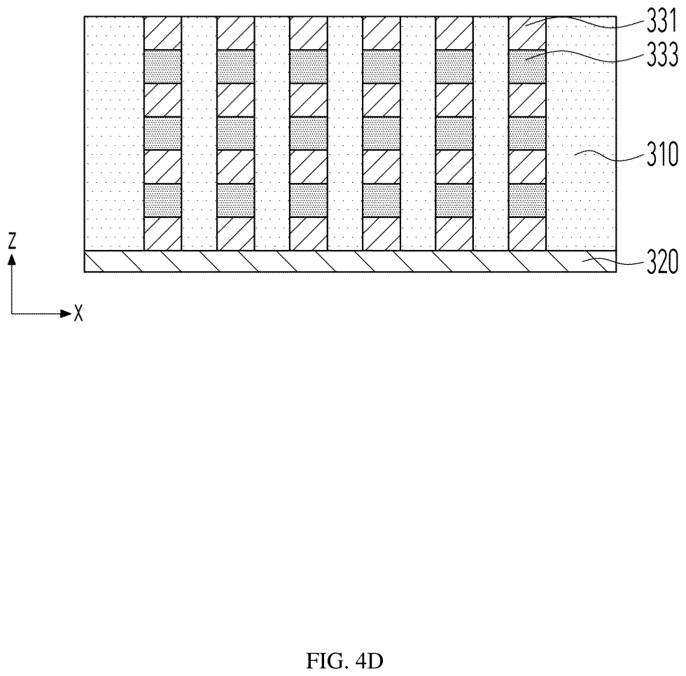

Next, the step of forming the first metal layer 331 and the second metal layer 333 in the first space 330 is performed. FIG. 4A is a view showing the first metal layer 331 and the second metal layer 333 formed in the first space 330, FIG. 4B is a cross-sectional view taken along line A-A′ of FIG. 4A, FIG. 4C is a cross-sectional view taken along line B-B′ of FIG. 4A, and FIG. 4D is a cross-sectional view taken along line C-C′ of FIG. 4A.

The first metal layer 331 is a sacrificial layer that is removed in a subsequent process to space the beam portions 115 apart from each other.

The first metal layer 331 may be copper (Cu). The second gap S2 in the second direction (±z direction) of the beam portions 115 is formed by the plating thickness of the first metal layer 331.

Since the second metal layer 333 determines the rigidity of the electrical connector 100, it is preferably made of a metal with high rigidity, such as rhodium (Rd), platinum (Pt), iridium (Ir), palladium (Pd), nickel (Ni), manganese (Mn), tungsten (W), phosphorus (Ph), or alloys thereof, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy. However, it is not limited to these.

Each second metal layer 333 is provided in the form of a unit needle pin 101, and the unit needle pin 101 is laminated with the first metal layer 331 in between. The unit needle pin 101 includes a beam portion 115 and a tip portion 130.

The sacrificial first metal layer 331 is plated first and also plated last. As a result, the first metal layer 331-second metal layer 333-first metal layer 331-second metal layer 333-first metal layer 331-second metal layer 333-first metal layer 331 can be sequentially plated. However, the number of layers is not limited to this and preferably can be formed in an odd number of layers.

As the first metal layer 331 plated first and the first metal layer 331 plated last are removed in a subsequent process, the connecting portion 120 and the deformation array 110 are stepped in the second direction (±z direction), and the length dimension D2 of the connecting portion 120 in the second direction (±z direction) becomes larger than the length dimension L2 of the deformation array 110 in the second direction (±z direction).

To increase the difference between the length dimension D2 of the connecting portion 120 and the length dimension L2 of the deformation array 110, the first metal layer 331 plated first and the first metal layer 331 plated last may have a greater plating thickness compared to the other first metal layers 331.

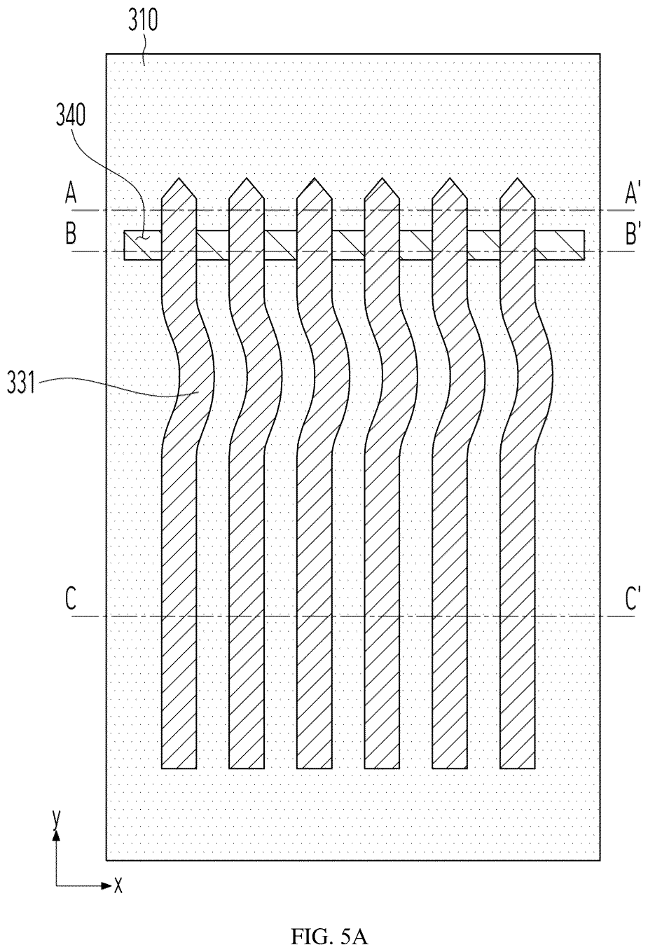

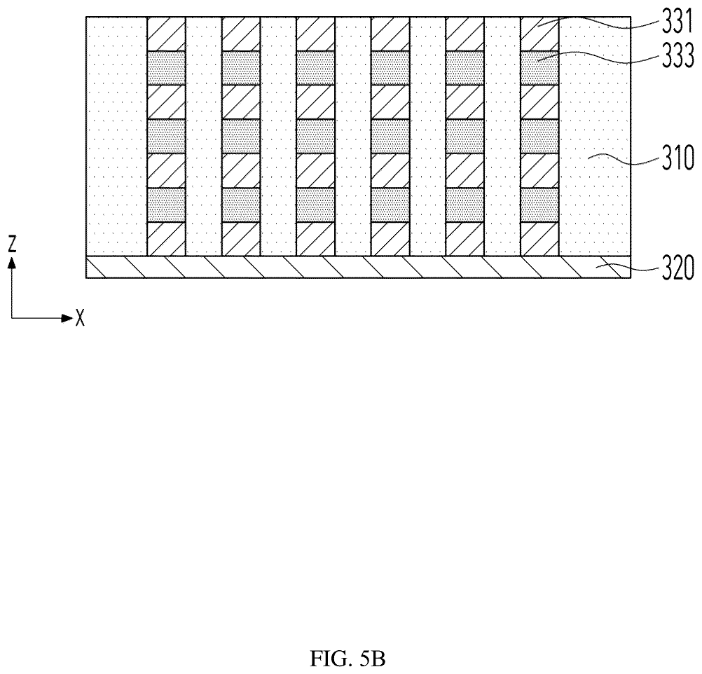

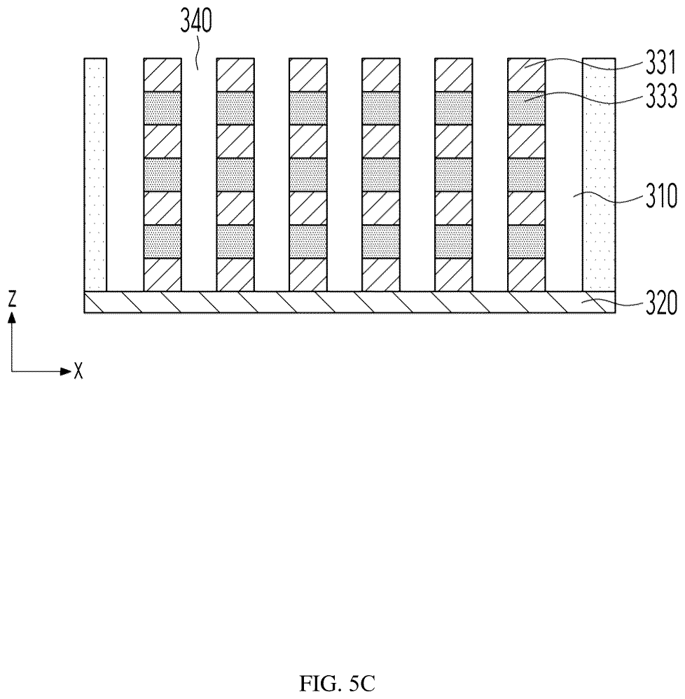

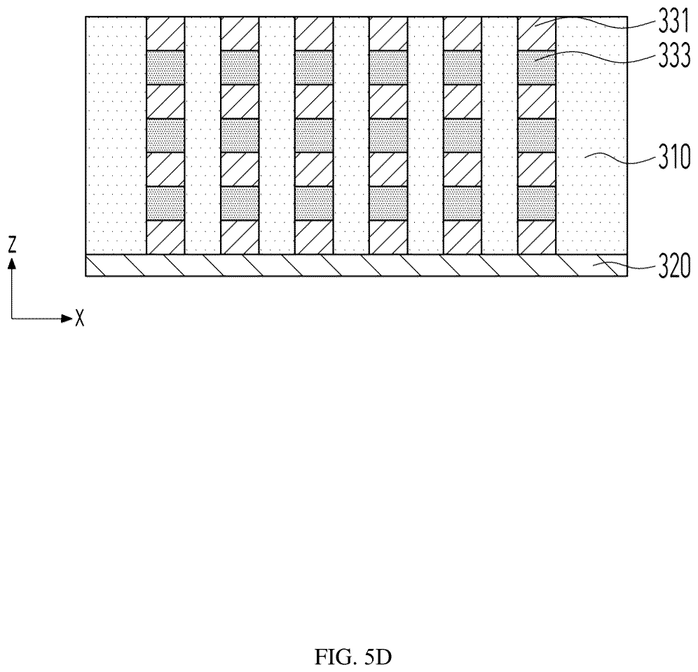

Next, a step of forming a second space 340 in the mold 310 is performed. FIG. 5A is a view showing the second space 340 formed in the mold 310, FIG. 5B is a cross-sectional view taken along line A-A′ of FIG. 5A, FIG. 5C is a cross-sectional view taken along line B-B′ of FIG. 5A, and FIG. 5D is a cross-sectional view taken along line C-C′ of FIG. 5A.

The second space 340 is a position where the connecting portion 120 is formed by a subsequent process.

The second space 340 is formed to be long in the first direction (±x direction), and the side surface of the first metal layer 331 provided at a position corresponding to the connecting portion 120 is exposed through the second space 340.

The second space 340 may be formed by wet etching the mold 310 made of an anodized film material. For this purpose, a photoresist is provided on the upper surface of the mold 310 and patterned, and then the anodized film in the patterned and opened area reacts with the etching solution to form the second space 340.

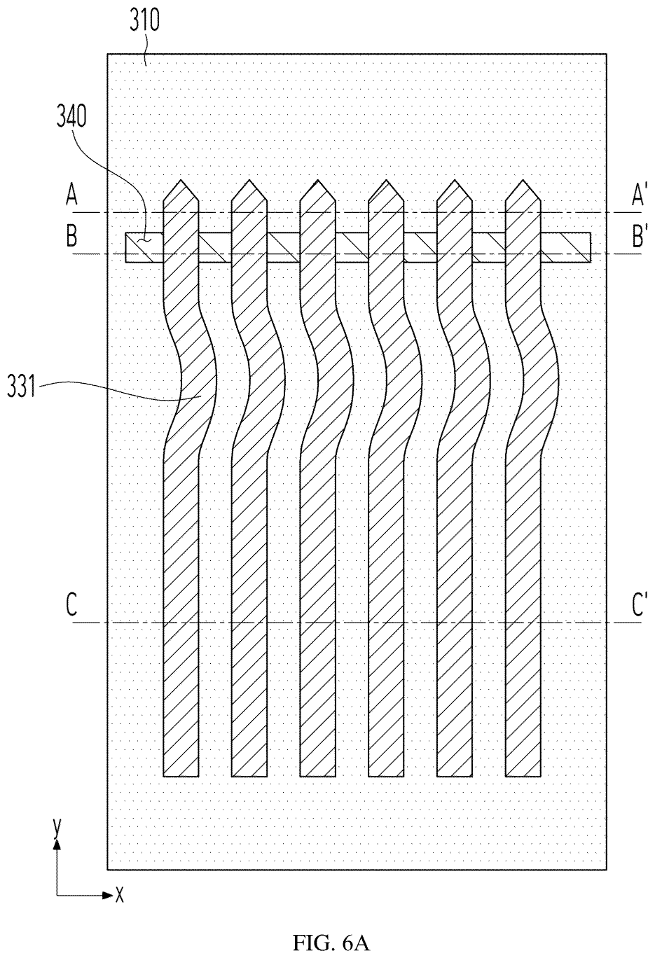

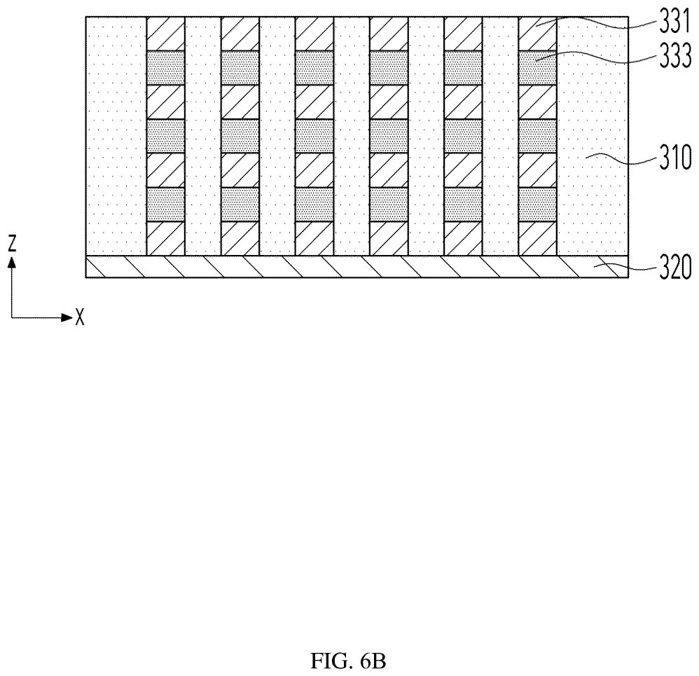

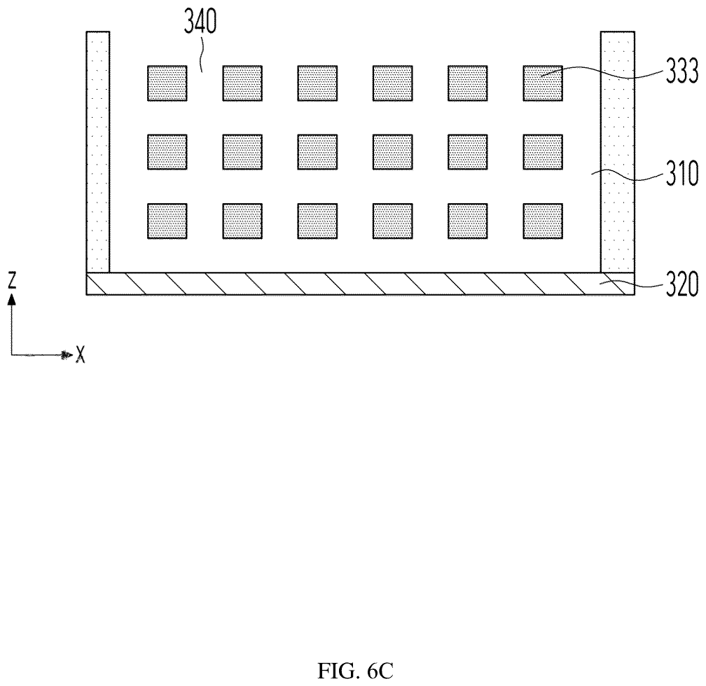

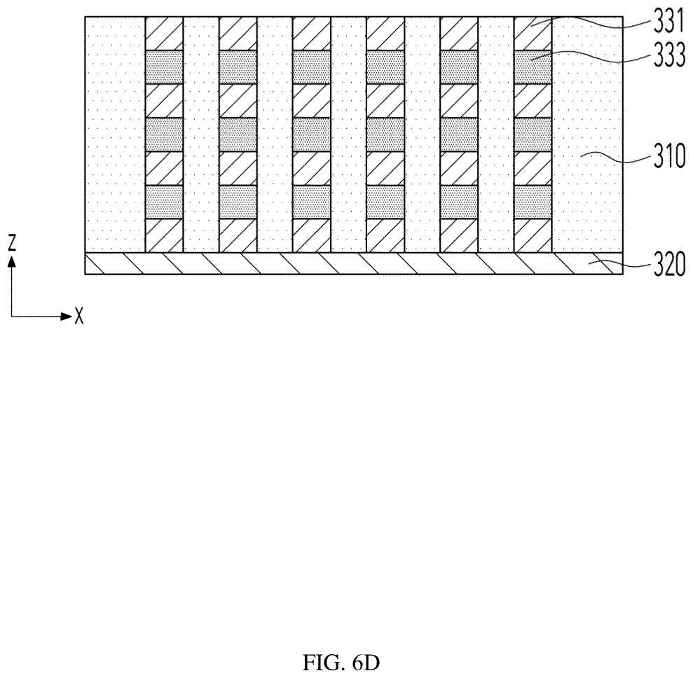

Next, a step of removing the first metal layer 331 using the second space 340 is performed. FIG. 6A is a view showing the first metal layer 331 removed using the second space 340, FIG. 6B is a cross-sectional view taken along line A-A′ of FIG. 6A, FIG. 6C is a cross-sectional view taken along line B-B′ of FIG. 6A, and FIG. 6D is a cross-sectional view taken along line C-C′ of FIG. 6A.

A solution that reacts only with the first metal layer 331 is introduced into the second space 340 to remove only the first metal layer 331. When the first metal layer 331 is copper (Cu), it can be removed using a copper etchant. As a result, only the second metal layer 333 remains in the second space 340, and the second metal layers 333 are spaced apart from each other in the z-axis direction.

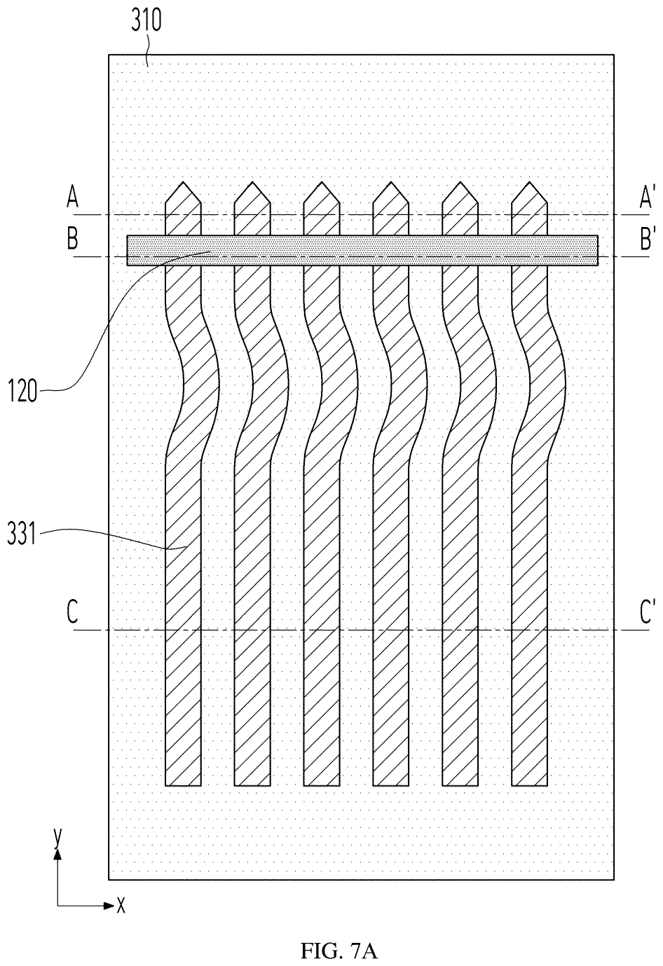

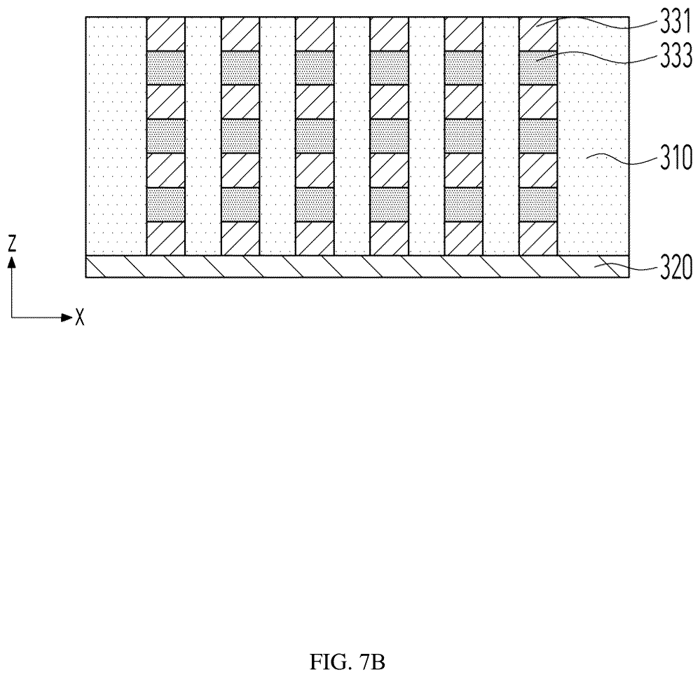

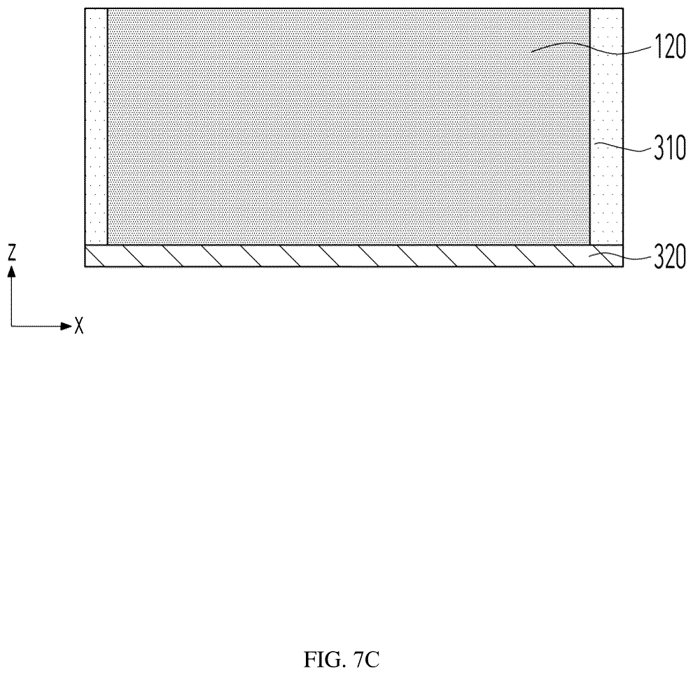

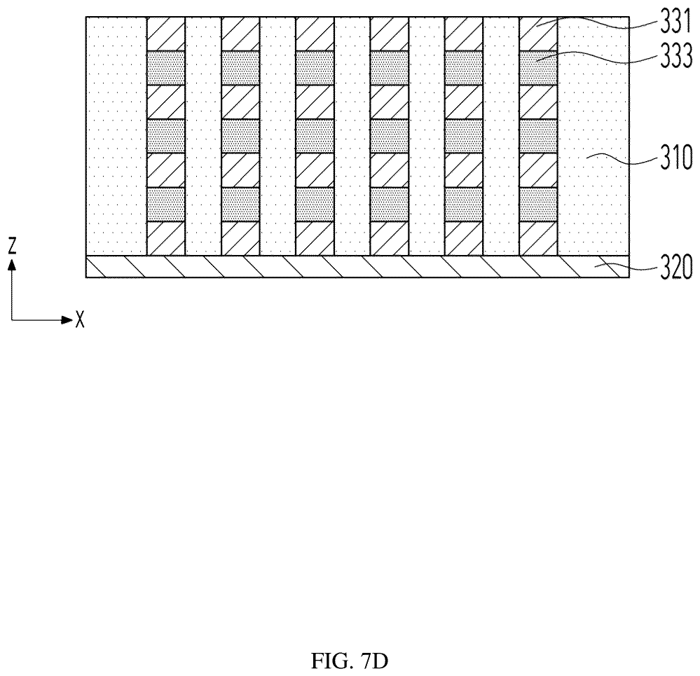

Next, a step of forming the second metal layer 333 in the second space 340 is performed. FIG. 7A is a view showing the second metal layer 333 formed in the second space 340, FIG. 7B is a cross-sectional view taken along line A-A′ of FIG. 7A, FIG. 7C is a cross-sectional view taken along line B-B′ of FIG. 7A, and FIG. 7D is a cross-sectional view taken along line C-C′ of FIG. 7A.

The second metal layer 333 may be of the same material or a different material as the metal of the second metal layer 333 formed in the previous process. For example, if the metal formed in the previous process is a nickel-cobalt (NiCo) alloy among the second metal layers 333, the metal formed in this process may be a nickel-cobalt (NiCo) alloy among the second metal layers 333 and be of the same material. Alternatively, if the metal formed in the previous process is a nickel-cobalt (NiCo) alloy among the second metal layers 333, the metal formed in this process may be a palladium-cobalt (PdCo) alloy among the second metal layers 333 and be of a different material. In the drawings, the metal formed in the previous process and the metal formed in this process are illustrated as being of the same material.

As the second metal layer 333 is formed, the unit needle pins 101 are bundled by the connecting portion 120.

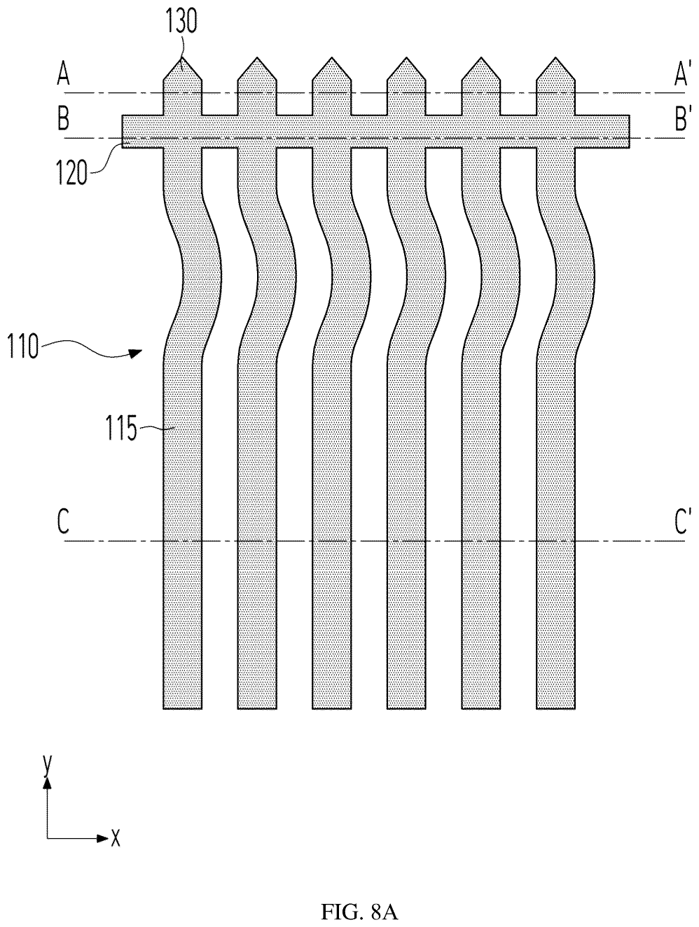

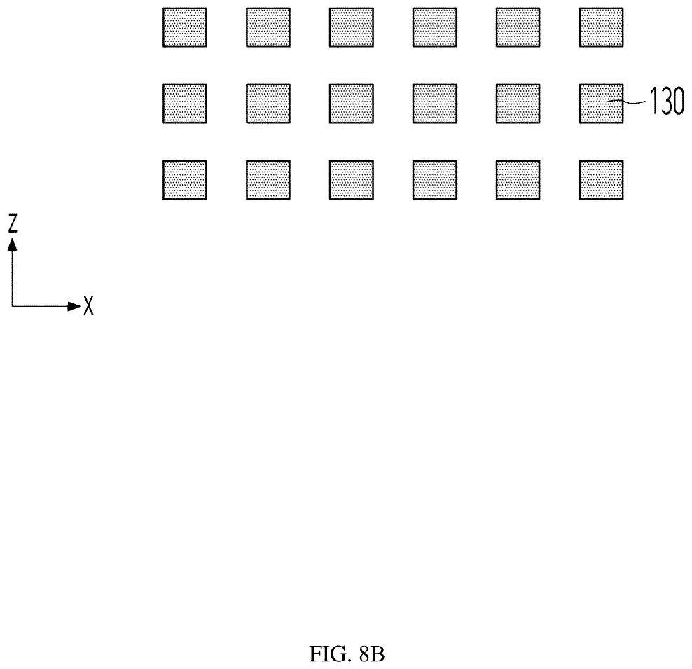

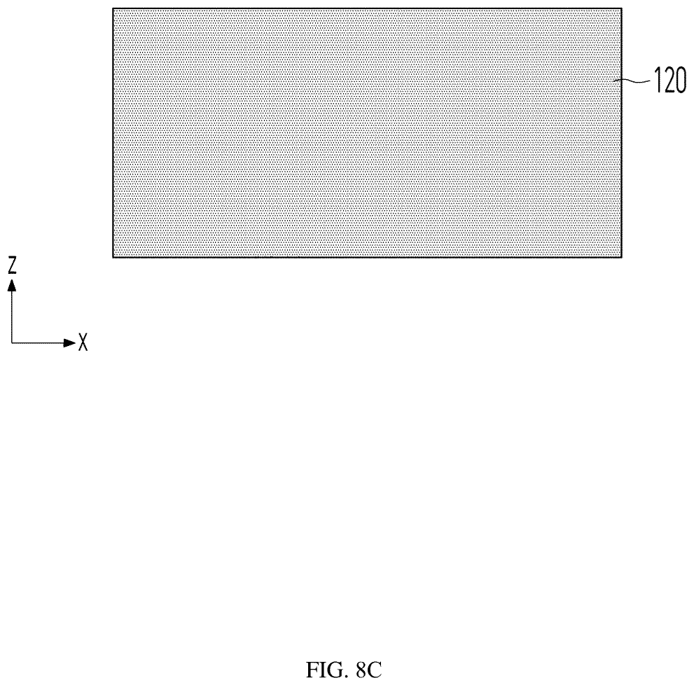

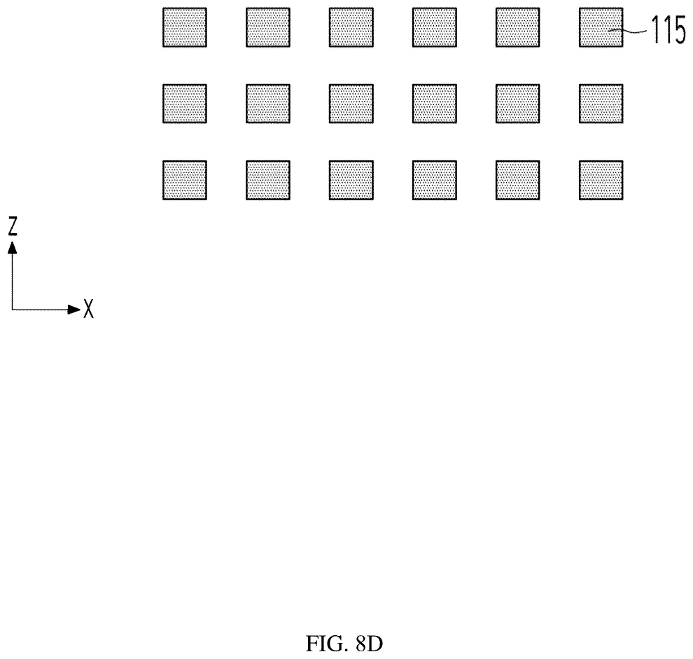

Next, a step of removing the mold 310 and the first metal layer 331 is performed. FIG. 8A is a view showing the remaining mold 310 removed and the first metal layer 331 removed, FIG. 8B is a cross-sectional view taken along line A-A′ of FIG. 8A, FIG. 8C is a cross-sectional view taken along line B-B′ of FIG. 8A, and FIG. 8D is a cross-sectional view taken along line C-C′ of FIG. 8A.

As the first metal layer 331 is removed, the beam portions 115 are spaced apart from each other with a second gap S2 in the second direction (±z direction). Also, the tip portions 130 are spaced apart from each other with a second gap S2 in the second direction (±z direction). In other words, the unit needle pins 101 are coupled through the connecting portion 120, and the beam portions 115 and tip portions 130 of the unit needle pins 101 are spaced apart from each other.

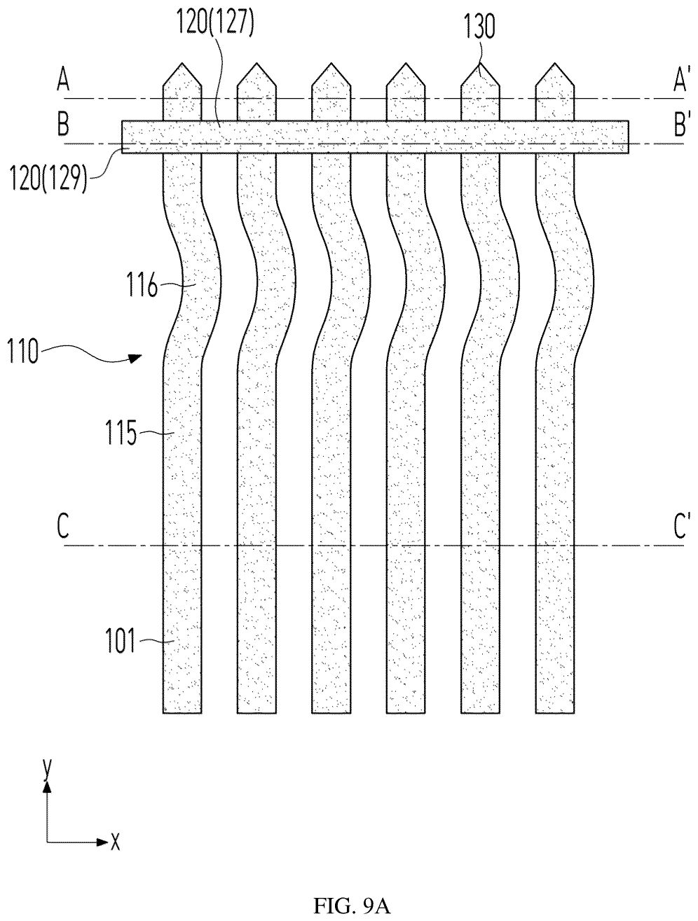

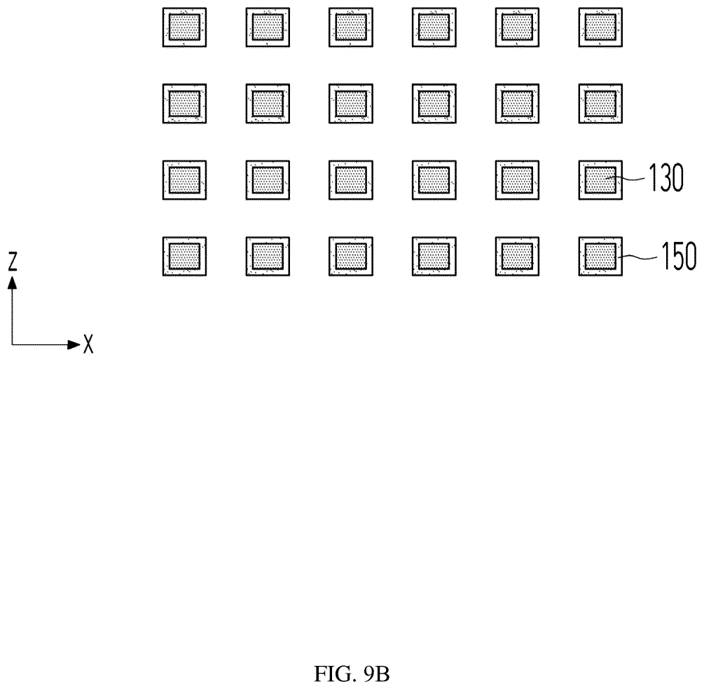

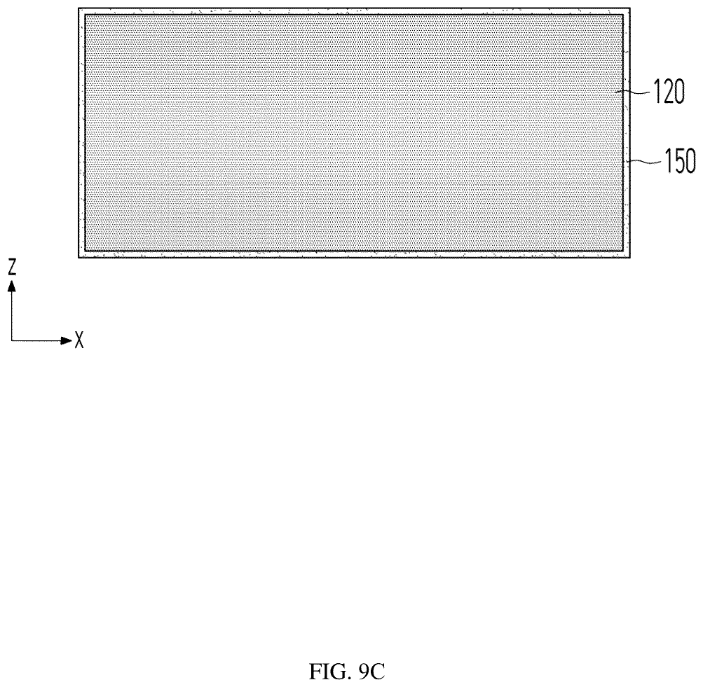

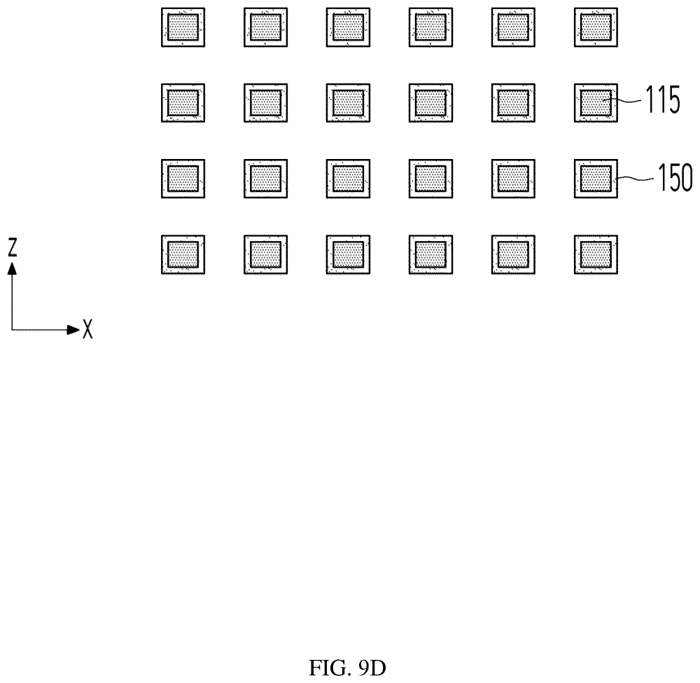

Next, a step of forming a subsequent plating layer 150 is performed. FIG. 9A is a view showing the subsequent plating layer 150 formed on the surface of the electrical connector 100, FIG. 9B is a cross-sectional view taken along line A-A′ of FIG. 9A, FIG. 9C is a cross-sectional view taken along line B-B′ of FIG. 9A and FIG. 9D is a cross-sectional view taken along line C-C′ of FIG. 9A.

The subsequent plating layer 150 is formed overall along the surface of the electrical connector 100. The subsequent plating layer 150 may be formed by flash plating.

The subsequent plating layer 150 is formed of a metal material with high electrical conductivity and preferably may be formed of a metal selected from copper (Cu), silver (Ag), gold (Au), or alloys thereof. However, it is not limited thereto. Preferably, it may be formed of gold (Au).

After forming the subsequent plating layer 150, an insulating material may additionally be coated on at least a part of the surface of the electrical connector.

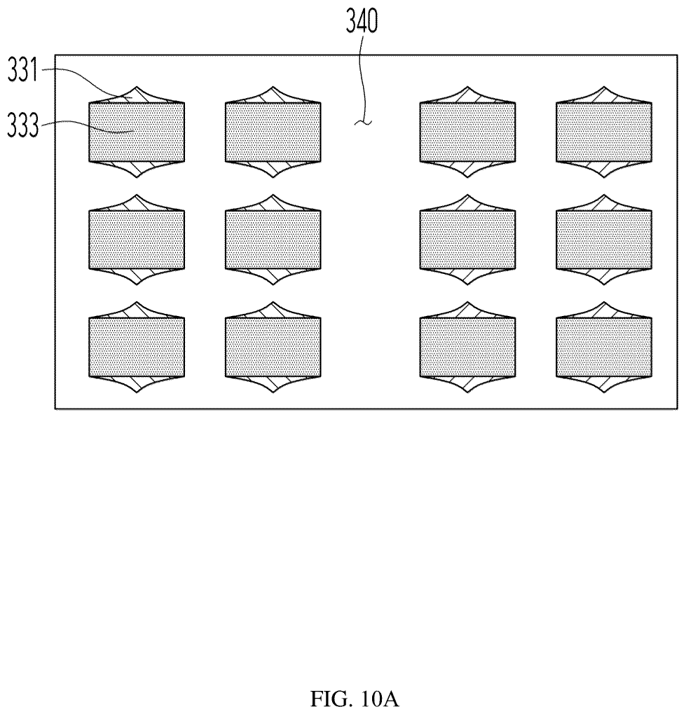

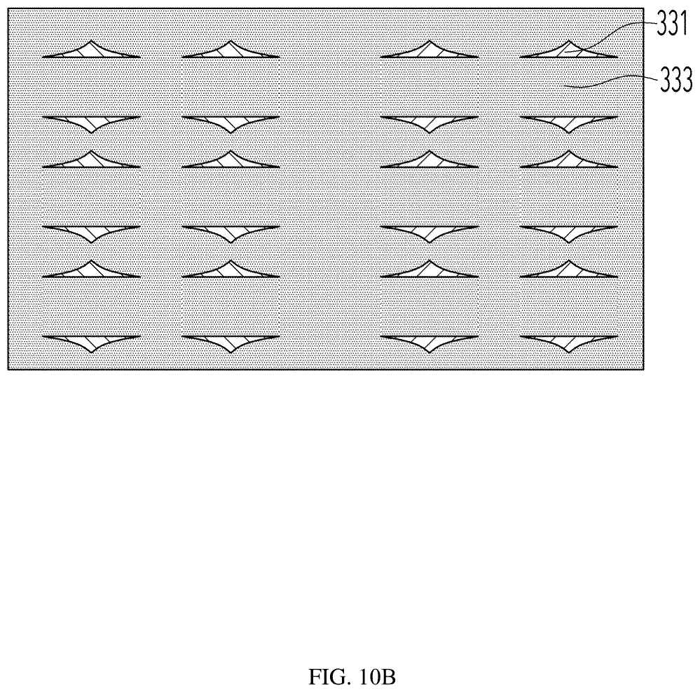

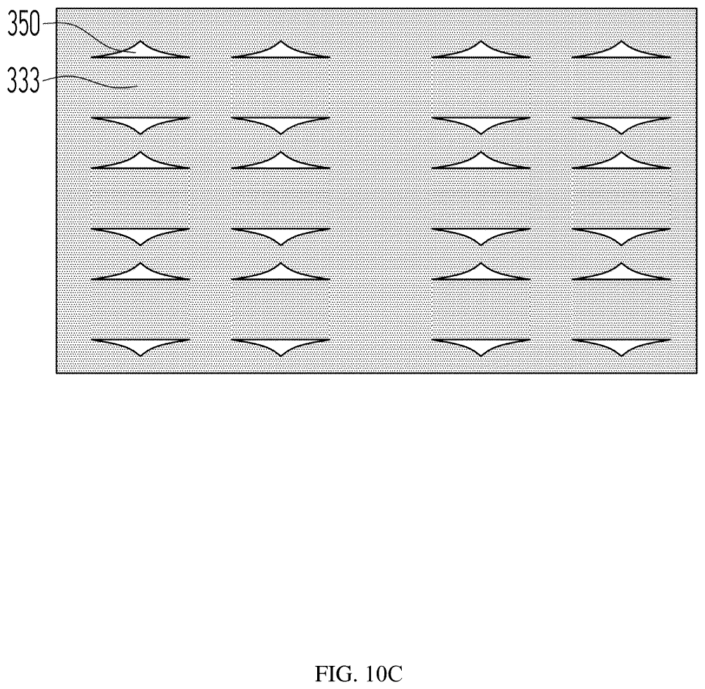

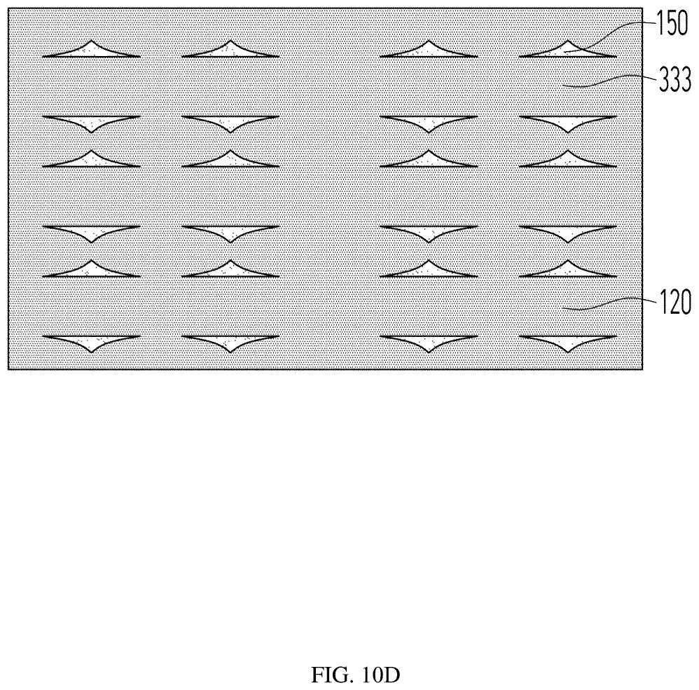

Meanwhile, in the step of removing the first metal layer 331 using the second space 340, the first metal layer 331 may be completely removed, but the first metal layer 331 may be left. Hereinafter, the structure and effect in the case where the first metal layer 331 is not removed will be specifically described with reference to FIGS. 10A to 10D.

FIG. 10A is a view for explaining that the first metal layer 331 remains partially at the position corresponding to the connecting portion 120 in the step of removing the first metal layer 331 using the second space 340, FIG. 10B is a view for explaining that the second metal layer 333 is formed in the second space 340 with the first metal layer 331 partially remaining at the position corresponding to the connecting portion 120, FIG. 10C is a view for explaining that a void 350 is formed at the position corresponding to the connecting portion 120 by removing the partially remaining first metal layer 331, and FIG. 10D is a view for explaining that a subsequent plating layer 150 is formed in the void 350 at the position corresponding to the connecting portion 120.

First, referring to FIG. 10A, in the step of removing the first metal layer 331 using the second space 340, the first metal layer 331 is left partially. Since the solution for removing the first metal layer 331 reacts isotropically with the first metal layer 331 and removes it, a part of the first metal layer 331 remains on the upper and lower surfaces of the second metal layer 333. The remaining first metal layer 331 becomes more as it goes toward the center of the second metal layer 333 based on one second metal layer 333.

Next, referring to FIG. 10B, when the second metal layer 333 is formed by plating in the second space 340, the second metal layer 333 is additionally formed on the surface of the remaining first metal layer 331 and the surface of the existing second metal layer 333. As a result, at the position corresponding to the connecting portion 120, the first metal layer 331 is embedded in the second metal layer 333.

Next, referring to FIG. 10C, in the process of removing the first metal layer 331 in the deformation array 110 and the tip portion 130, the first metal layer 331 remaining inside the connecting portion 120 is also removed together, and avoid 350 is formed at the position where the first metal layer 331 was inside the connecting portion 120.

Next, referring to FIG. 10D, in the process of forming the subsequent plating layer 150 on the surface of the electrical connector 100, the subsequent plating layer 150 also penetrates into the void 350 inside the connecting portion 120. As a result, the subsequent plating layer 150 is provided inside the connecting portion 120 by penetrating through the inside of the connecting portion 120 in the longitudinal direction (±y direction).

The subsequent plating layer 150 is formed overall on the surface of the electrical connector 100 and is also provided inside the connecting portion 120 by penetrating through the inside of the connecting portion 120. Therefore, the subsequent plating layer 150 formed on the surface of the tip portion 130 and the subsequent plating layer 150 formed on the surface of the beam portion 115 are linearly connected to each other through the subsequent plating layer 150 penetrating through the connecting portion 120. As a result, as the current path is shortened, the current carrying capacity (CCC) can be further improved.

FIG. 11 is a cross-sectional view showing the electrical connector 100 according to the first embodiment installed in the guide plate 200, and FIG. 12 is a plan view showing the electrical connector 100 according to the first embodiment installed in the guide plate 200.

The guide plate 200 has a plurality of guide holes 210. The electrical connector 100 is installed in each of the guide holes 210.

The length dimension L1 of the deformation array 110 in the first direction (±x direction) is smaller than the length dimension G1 of the guide hole 210 in the first direction (±x direction), and the length dimension L2 of the deformation array 110 in the second direction (±z direction) is smaller than the length dimension G2 of the guide hole 210 in the second direction (±z direction). Meanwhile, the length dimension D1 of the connecting portion 120 in the first direction (±x direction) is larger than the length dimension G1 of the guide hole 210 in the first direction (±x direction), and the length dimension D2 of the connecting portion 120 in the second direction (±z direction) is larger than the length dimension G2 of the guide hole 210 in the second direction (±z direction). As a result, the deformation array 110 of the electrical connector 100 is located inside the guide hole 210, and the connecting portion 120 can be caught on the upper end of the guide hole 210. More specifically, the outer connecting portion 129 of the connecting portion 120 can be caught on the upper surface of the guide plate 200. That is, the outer connecting portion 129 not only performs the function of connecting the unit needle pins 101 to each other but also performs the function of preventing the electrical connector 100 from falling when installed on the guide plate 200.

Meanwhile, the plurality of tip portions 130 are located within the area corresponding to the guide hole 210.

Conventional electrical connectors manufactured by MEMS processes are structured to be caught on the upper end of the guide hole only in the first direction (±x direction) or the second direction (±z direction). However, according to a preferred embodiment of the present invention, the structure can be caught on the upper end of the guide hole 210 in both the first direction (±x direction) and the second direction (±z direction). In other words, the electrical connector 100 can be caught on the upper surface of the guide plate 200 by the outer connecting portion 129 provided protruding on the four sides of the electrical connector 100.

Since the electrical connector 100 can be caught on the upper end of the guide hole 210 in all directions, the electrical connector 100 is more stably installed on the guide plate 200.

FIG. 13 is a view illustrating inspecting an object 20 using an inspection apparatus 10 including the electrical connector 100 and the guide plate 200.

Each electrical connector 100 corresponds to each external terminal 21 of the object 20 to be inspected and corresponds to each contact terminal 31 of the circuit unit 30.

When the lower end of the electrical connector 100 contacts the upper end of the external terminal 31 of the circuit unit 30, the lower surface of the connecting portion 120 can be provided spaced apart from the upper surface of the guide plate 200 by a predetermined distance. In this state, when the object 20 to be inspected approaches and the external terminal 21 contacts and presses the electrical connector 100, the deformation array 110 elastically deforms and inspects the object 20.

Meanwhile, the material of the guide plate 200 may be a material with high rigidity or an elastic material.

Meanwhile, it is also possible to configure the electrical connector 100 by embedding it in an insulating elastic connecting portion. Here, the insulating elastic connecting portion may be formed of a material including at least one of rubber, silicone, and urethane. The insulating elastic connecting portion is preferably a polymer material having a cross-linked structure. Various curable polymer material forming materials can be used to obtain such an insulating elastic connecting portion, and specific examples include conjugated diene rubbers such as polybutadiene rubber, natural rubber, polyisoprene rubber, styrene-butadiene copolymer rubber, acrylonitrile-butadiene copolymer rubber, and their hydrogenated products, block copolymer rubbers such as styrene-butadiene-diene block copolymer rubber, styrene-isoprene block copolymer, and their hydrogenated products, chloroprene rubber, urethane rubber, polyester rubber, epichlorohydrin rubber, silicone rubber, ethylene-propylene copolymer rubber, and ethylene-propylene-diene copolymer rubber.

The insulating elastic connecting portion integrates multiple electrical connectors 100 by connecting them to each other. In this case, the upper and lower parts of the electrical connector 100 can be exposed to the outside. In other words, the tip portion 130 of the electrical connector 100 can be exposed to the outside, and a part of the beam portion 115 of the electrical connector 100 can be exposed to the lower part.

### Second Embodiment

Next, a second embodiment of the electrical connector 100 according to the present invention will be described. However, the second embodiment described below will be mainly described with characteristic components compared to the first embodiment, and the description of components that are the same or similar to those of the first embodiment will be omitted as much as possible.

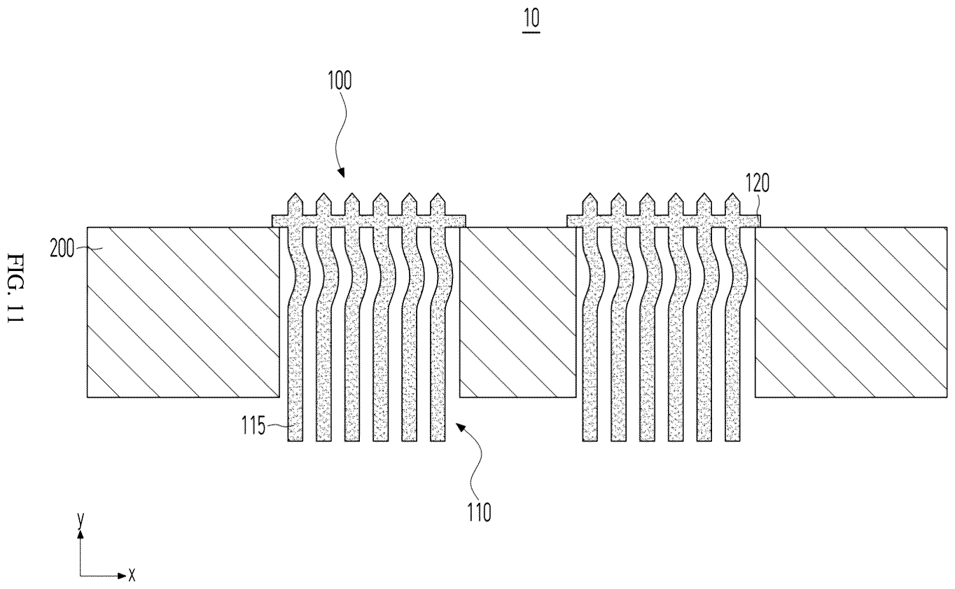

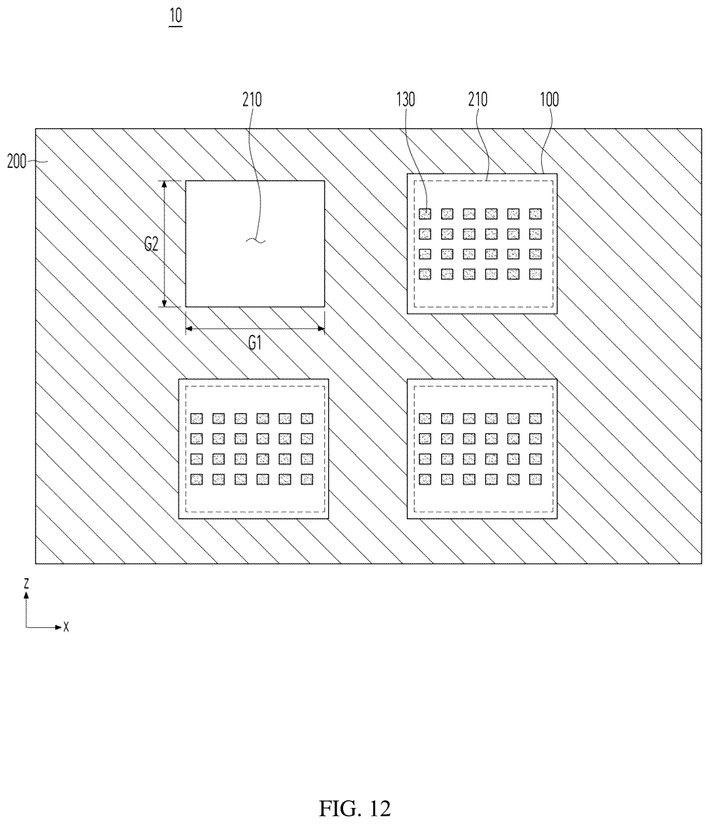

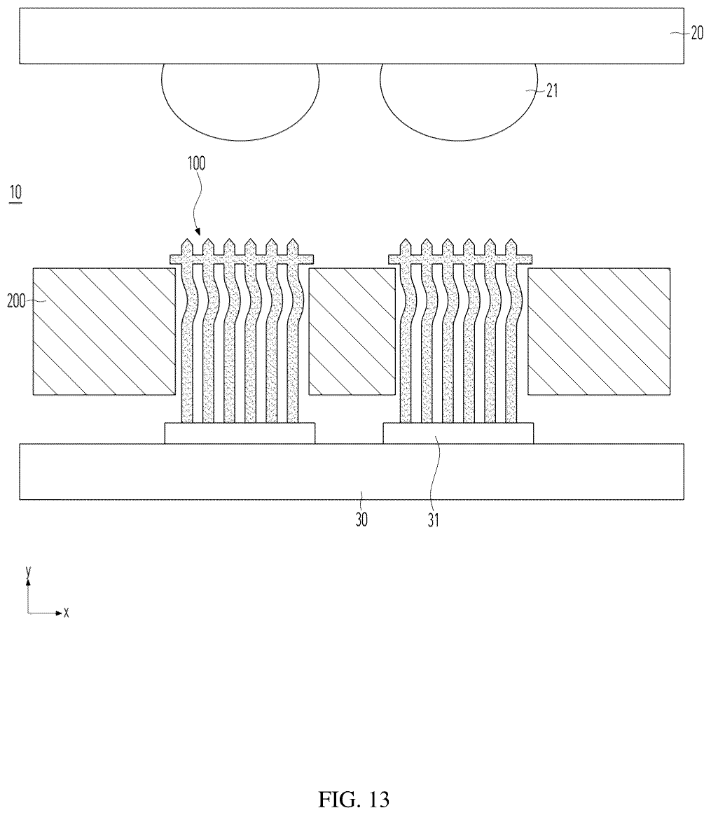

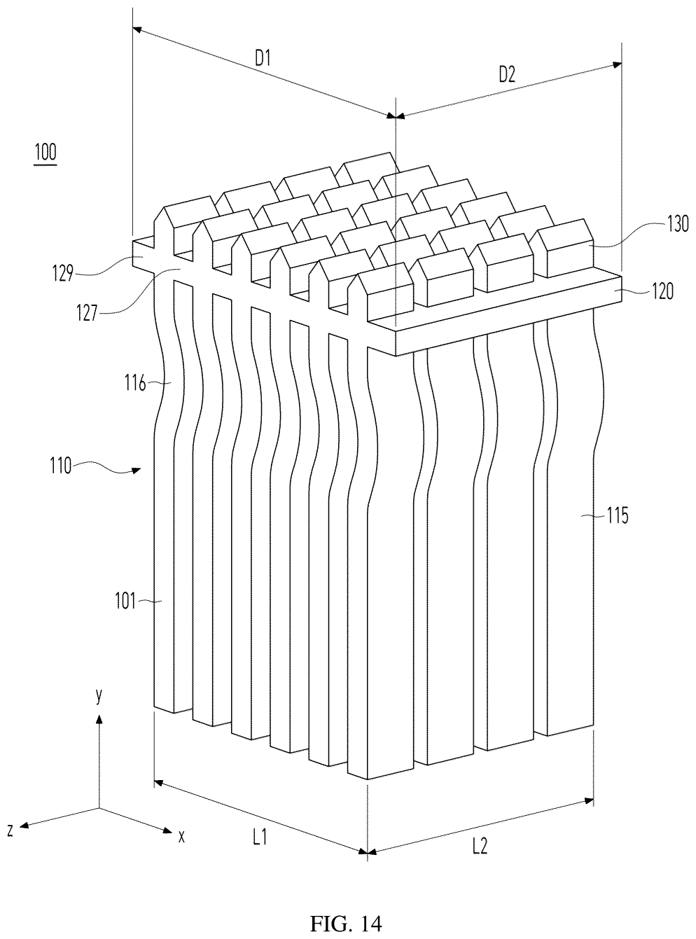

FIG. 14 is a perspective view of the electrical connector 100 according to a preferred second embodiment of the present invention.

The electrical connector 100 according to the second embodiment comprises a plurality of unit needle pins 101 arranged to be spaced apart from each other and a connecting portion 120 connecting them. The electrical connector 100 is configured such that the plurality of unit needle pins 101 are connected to each other by the connecting portion 120, and each beam portion 115 and tip portion 130 are spaced apart from each other.

The deformation array 110 has a length dimension L1 in the first direction (±x direction) and a length dimension L2 in the second direction (±z direction). Also, the connecting portion 120 has a length dimension D1 in the first direction (±x direction) and a length dimension D2 in the second direction (±z direction).

The second embodiment differs from the first embodiment in that the length dimension D1 of the connecting portion 120 in the first direction (±x direction) is greater than the length dimension L1 of the deformation array 110 in the first direction (±x direction), and the length dimension D2 of the connecting portion 120 in the second direction (±z direction) is the same as the length dimension L2 of the deformation array 110 in the second direction (±z direction). In other words, the connecting portion 120 of the second embodiment includes an inner connecting portion 127 and an outer connecting portion 129, but the outer connecting portion 129 is provided only in the first direction (±x direction) and not in the second direction (±z direction), which is different from the configuration of the first embodiment, and the rest of the configuration is the same.

### Third Embodiment

Next, a third embodiment of the electrical connector 100 according to the present invention will be described. However, the third embodiment described below will be mainly described with characteristic components compared to the second embodiment, and the description of components that are the same or similar to those of the second embodiment will be omitted as much as possible.

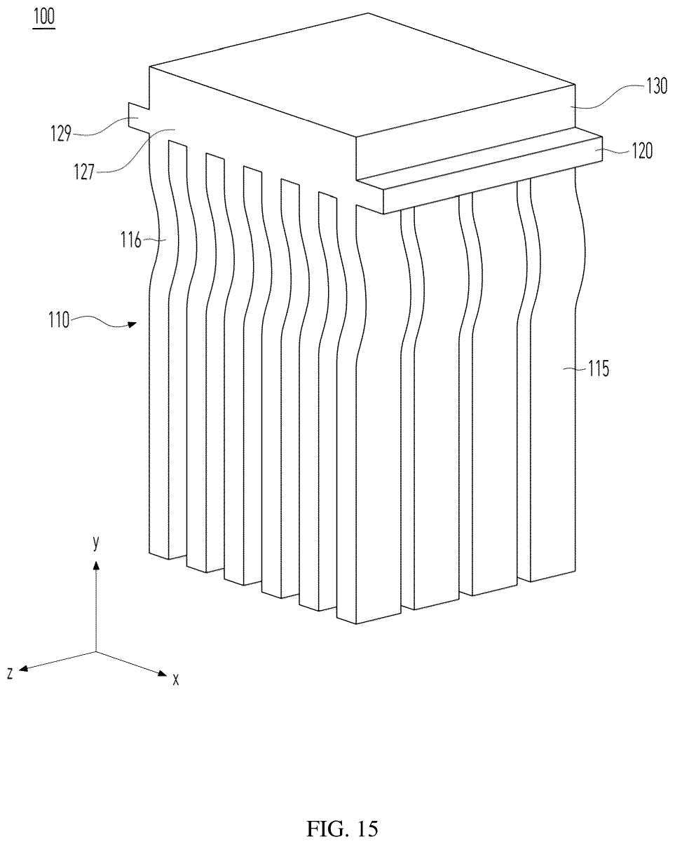

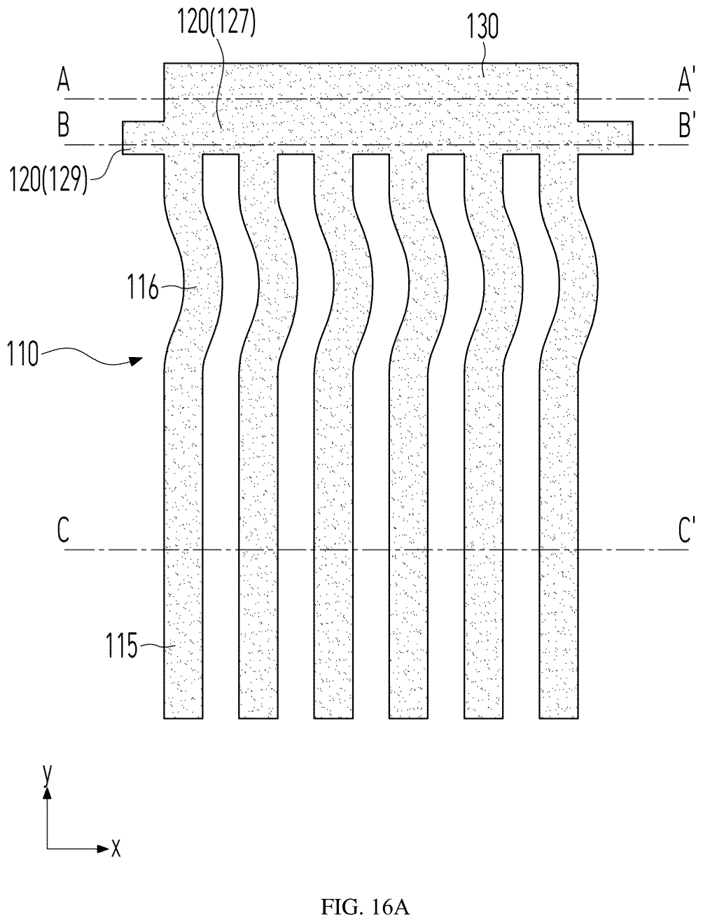

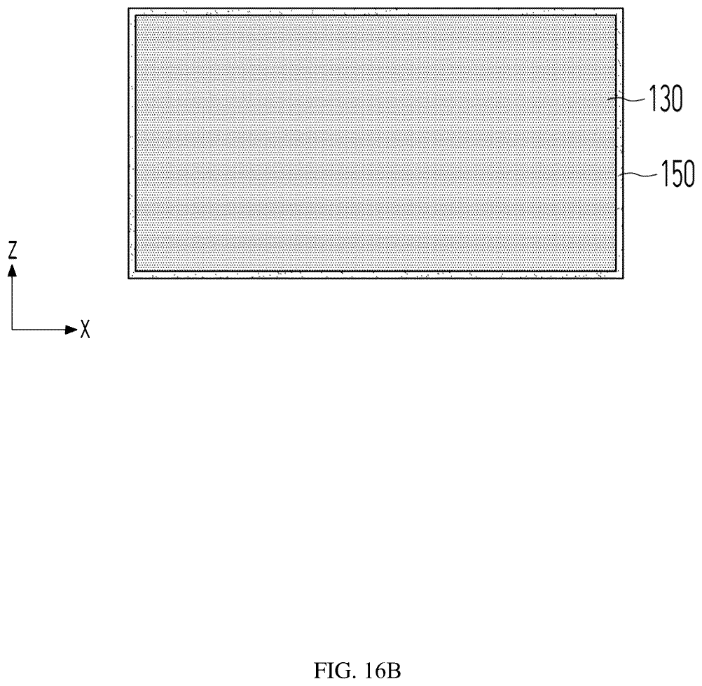

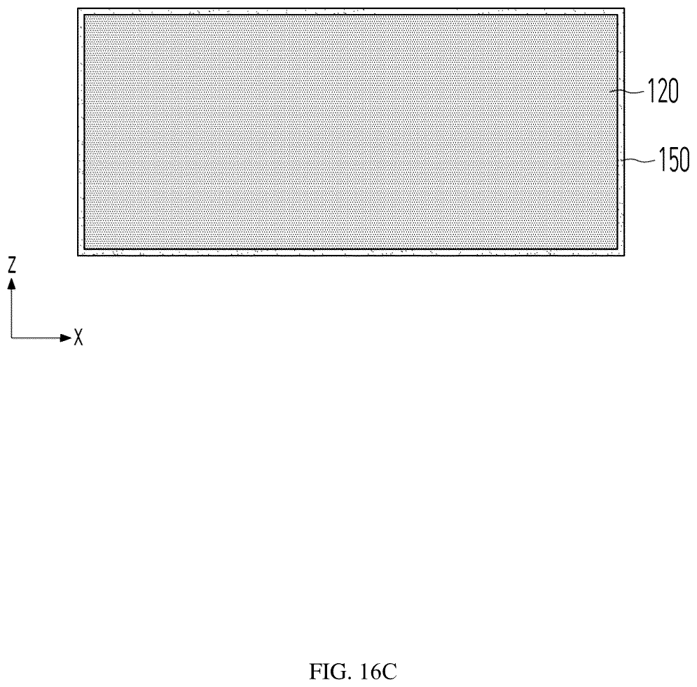

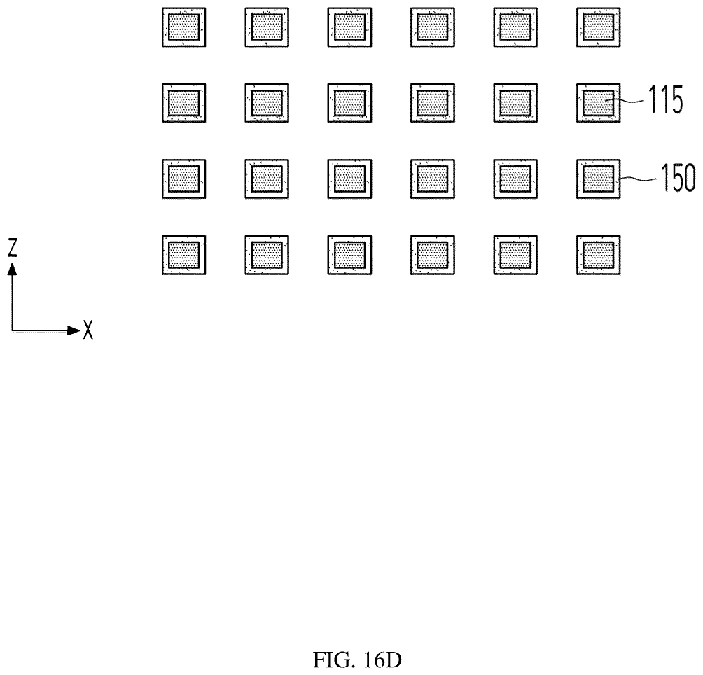

FIG. 15 is a perspective view of the electrical connector 100 according to a preferred third embodiment of the present invention, FIG. 16A is a front view of the electrical connector 100 according to a preferred third embodiment of the present invention, FIG. 16B is a cross-sectional view taken along line A-A′ of FIG. 16A, FIG. 16C is a cross-sectional view taken along line B-B′ of FIG. 16A, and FIG. 16D is a cross-sectional view taken along line C-C′ of FIG. 16A.

A tip portion 130 is provided on the upper part of the connecting portion 120.

The third embodiment differs from the second embodiment in that only one tip portion 130 is provided, not multiple tip portions 130, and the rest of the configuration is the same as that of the second embodiment.

### Fourth Embodiment

Next, a fourth embodiment of the electrical connector 100 according to the present invention will be described. However, the fourth embodiment described below will be mainly described with characteristic components compared to the second embodiment, and the description of components that are the same or similar to those of the second embodiment will be omitted as much as possible.

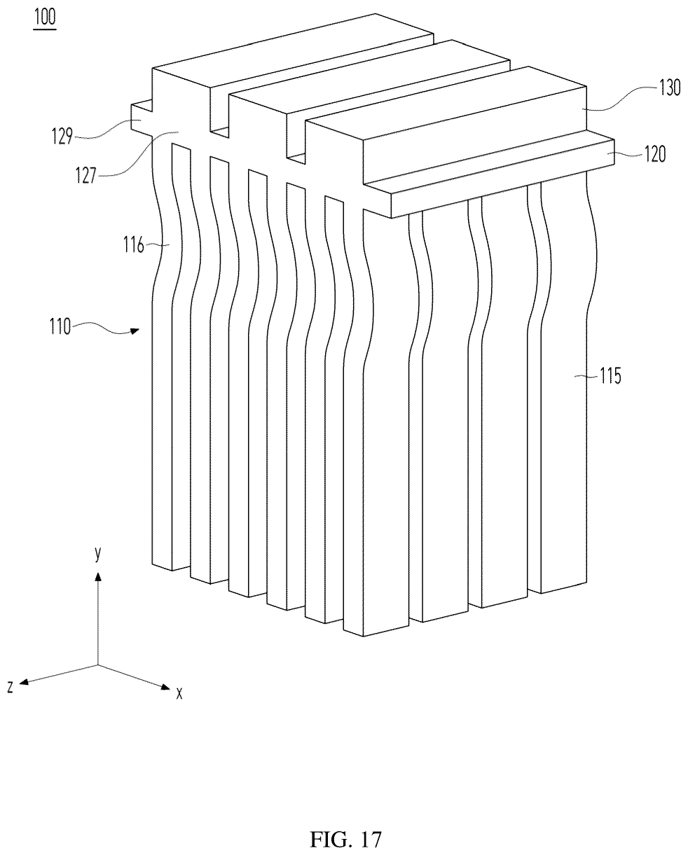

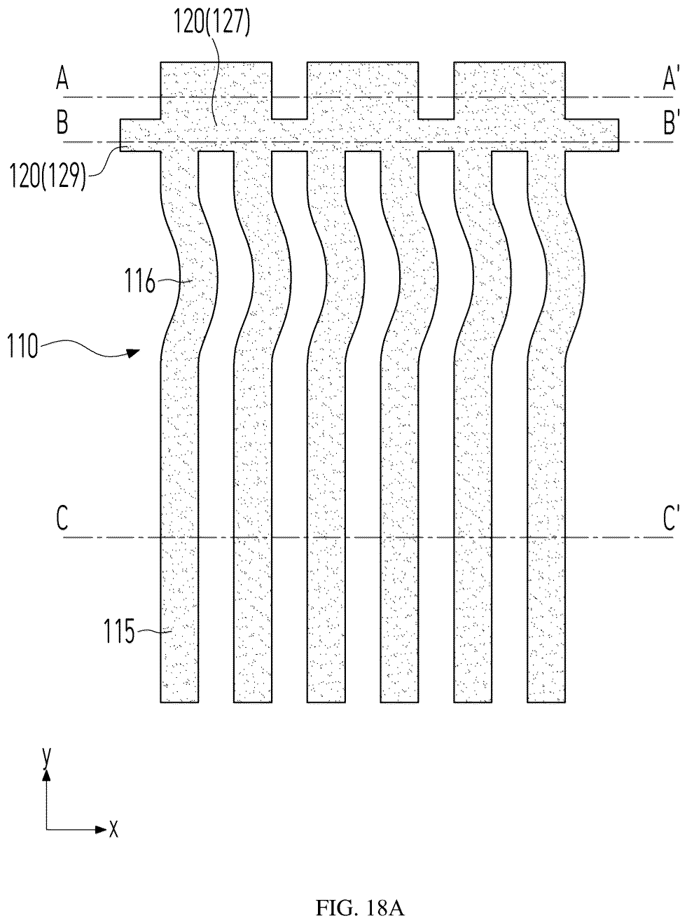

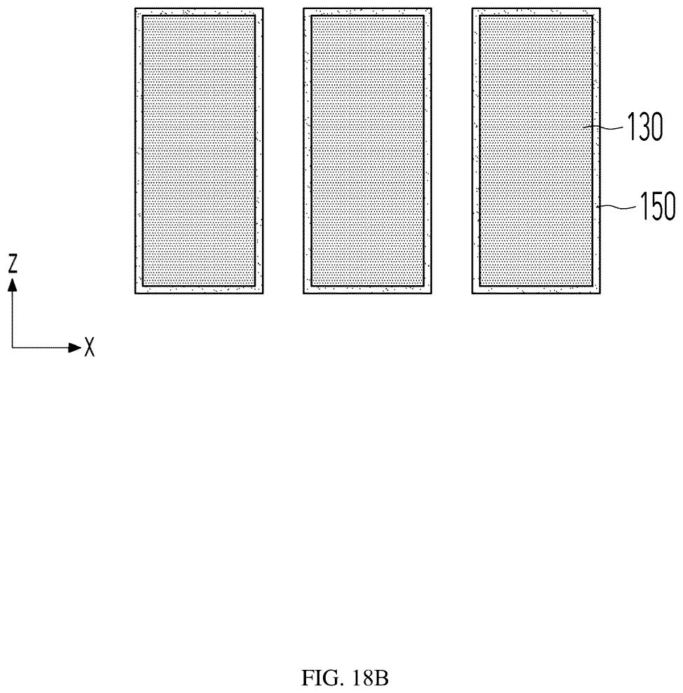

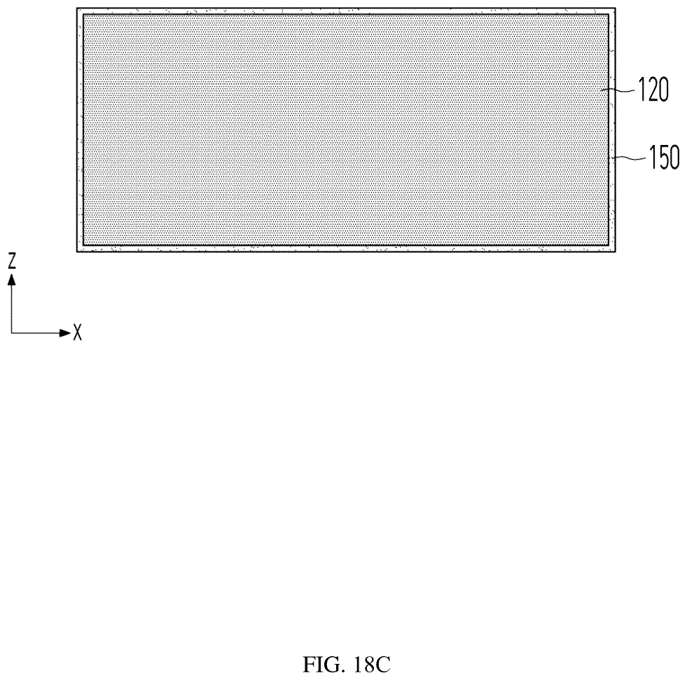

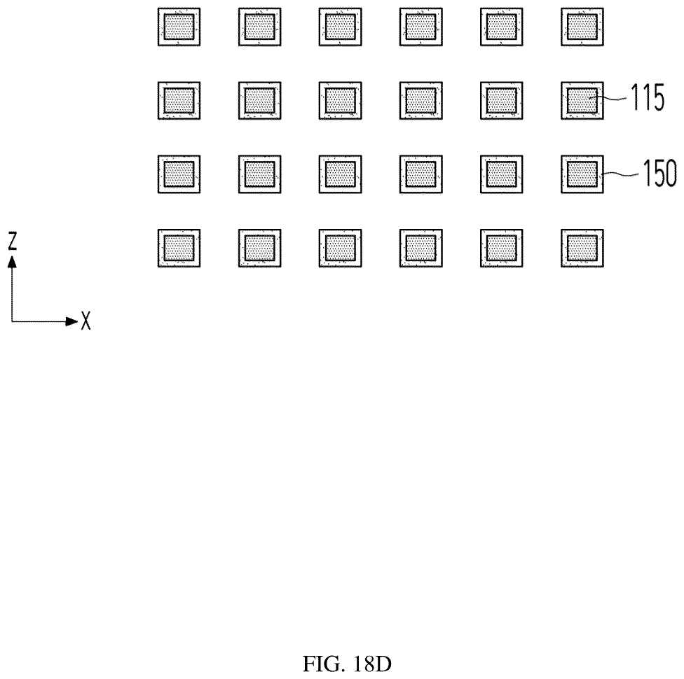

FIG. 17 is a perspective view of the electrical connector 100 according to a preferred fourth embodiment of the present invention, FIG. 18A is a front view of the electrical connector 100 according to a preferred fourth embodiment of the present invention, FIG. 18B is a cross-sectional view taken along line A-A′ of FIG. 18A, FIG. 18C is a cross-sectional view taken along line B-B′ of FIG. 18A, and FIG. 18D is a cross-sectional view taken along line C-C′ of FIG. 18A.

The fourth embodiment differs from the second embodiment in that the number of tip portions 130 is different from the number of beam portions 115, and the rest of the configuration is the same as that of the second embodiment.

More specifically, the fourth embodiment differs from the second embodiment in that the tip portions 130 are provided to be spaced apart from each other only in the first direction (±x direction), whereas in the second embodiment, the tip portions 130 are provided to be spaced apart from each other in both the first direction (±x direction) and the second direction (±y direction). Also, the fourth embodiment differs from the second embodiment in that the number of tip portions 130 is smaller than the number of beam portions 115, whereas in the second embodiment, the number of tip portions 130 is the same as the number of beam portions 115.

### Fifth Embodiment

Next, a fifth embodiment of the electrical connector 100 according to the present invention will be described. However, the fifth embodiment described below will be mainly described with characteristic components compared to the first embodiment, and the description of components that are the same or similar to those of the first embodiment will be omitted as much as possible.

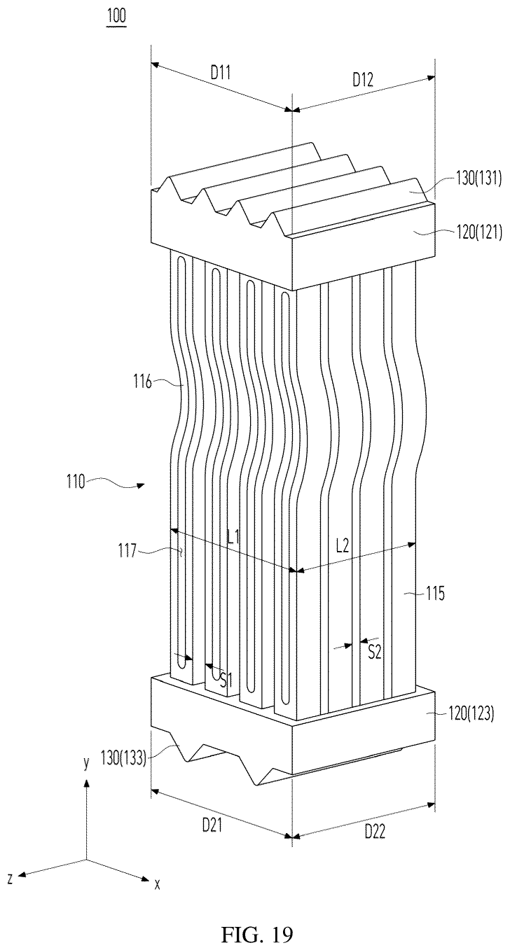

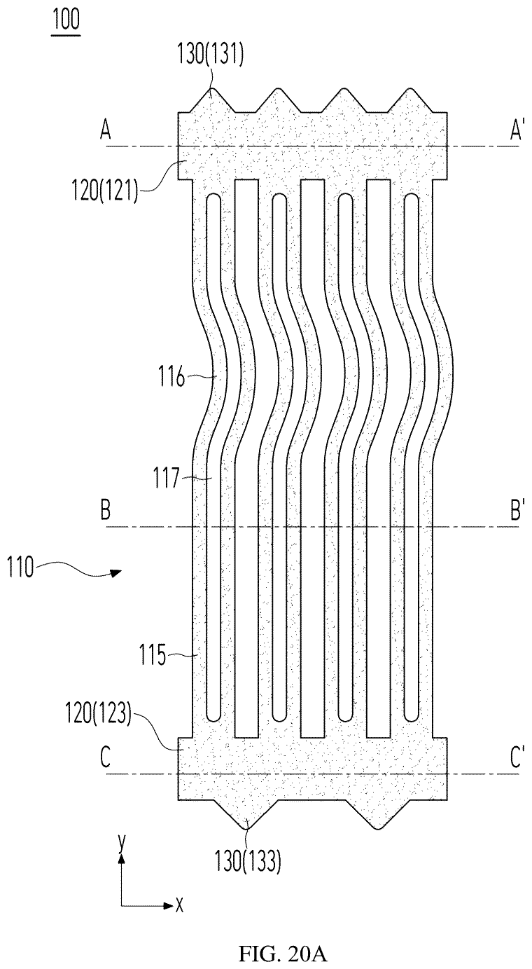

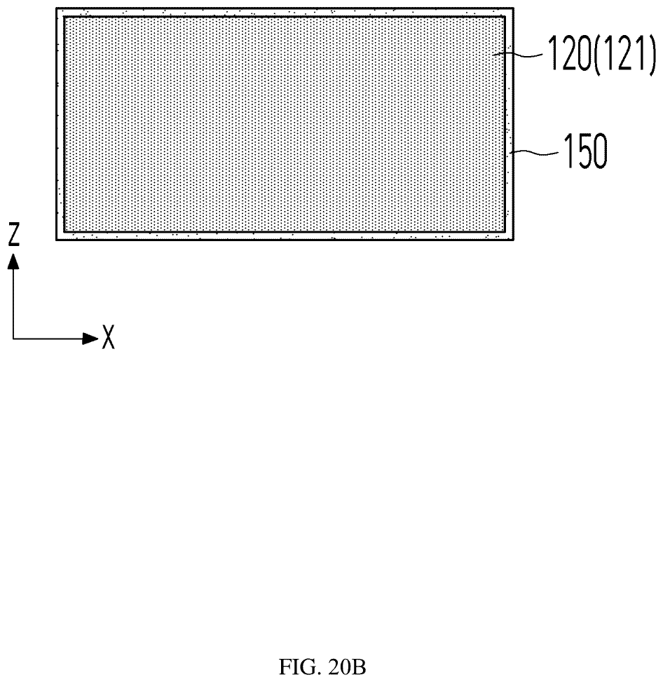

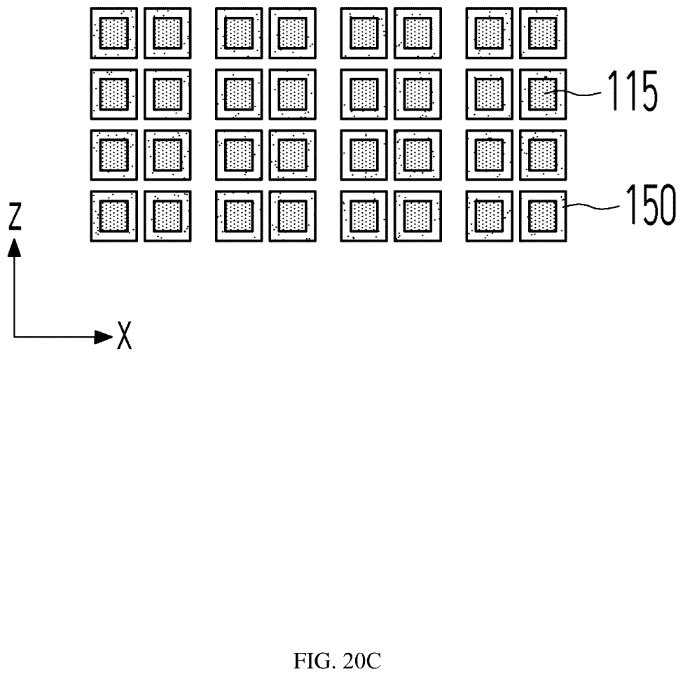

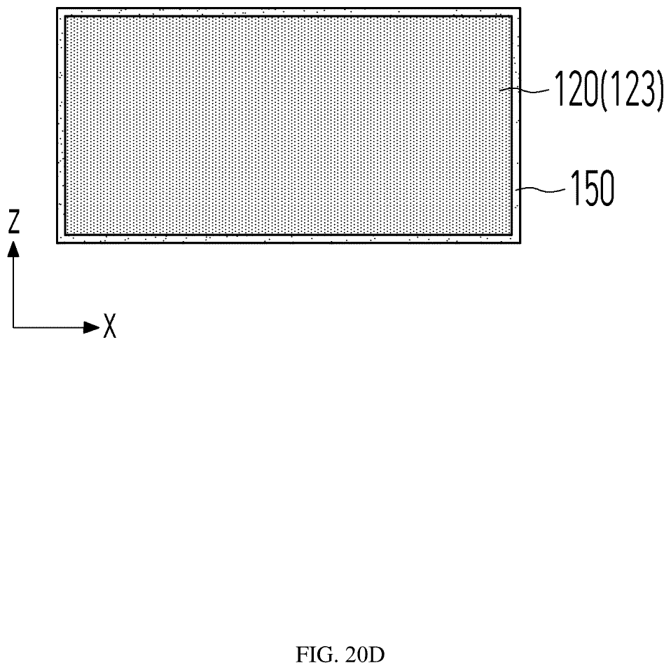

FIG. 19 is a perspective view of the electrical connector 100 according to a preferred fifth embodiment of the present invention, FIG. 20A is a front view of the electrical connector 100 according to a preferred fifth embodiment of the present invention, FIG. 20B is a cross-sectional view taken along line A-A′ of FIG. 20A, FIG. 20C is a cross-sectional view taken along line B-B′ of FIG. 20A, and FIG. 20D is a cross-sectional view taken along line C-C′ of FIG. 20A.

The electrical connector 100 comprises a deformation array 110 and a connecting portion 120.

The deformation array 110 includes a plurality of beam portions 115 extending in the longitudinal direction (±y direction) to be elastically deformed. Each beam portion 115 extends in the longitudinal direction (±y direction) and has a bent portion 116 formed in the middle part. Each beam portion 115 is bent and deformed by an external force applied in the longitudinal direction (±y direction).

The beam portion 115 includes a slit 117. The slit 117 penetrates the beam portion 115 in the second direction (±z direction).

The deformation array 110 includes a plurality of beam portions 115 spaced apart from each other in the first direction (±x direction). The plurality of beam portions 115 are provided to be spaced apart from each other by a first spacing gap S1 in the first direction (±x direction).

Also, the deformation array 110 includes a plurality of beam portions 115 spaced apart from each other in the second direction (±z direction) perpendicular to the first direction (±x direction). The plurality of beam portions 115 are provided to be spaced apart from each other by a second spacing gap S2 in the second direction (±z direction).

The deformation array 110 shown in FIG. 19 includes a plurality of beam portions 115 spaced apart from each other by a first spacing gap S1 in the first direction (±x direction) and also spaced apart from each other by a second spacing gap S2 in the second direction (±z direction) perpendicular to the first direction (±x direction). The sizes of the first spacing gap S1 and the second spacing gap S2 may be the same or different from each other.

The connecting portion 120 connects the beam portions 115 of the deformation array 110.

The connecting portion 120 comprises an upper connecting portion 121 provided on the upper part of the deformation array 110 and a lower connecting portion 123 provided on the lower part of the deformation array 110.

The tip portion 130 comprises an upper tip portion 131 provided on the upper part of the upper connecting portion 121 and a lower tip portion 133 provided on the lower part of the lower connecting portion 123.

The deformation array 110 has a length dimension L1 in the first direction (±x direction) and a length dimension L2 in the second direction (+z direction). Additionally, the connecting portion 120 has a length dimension D1 in the first direction (±x direction) and a length dimension D2 in the second direction (+z direction).

The tip portion 130 in the fifth embodiment can be configured as in the first to fourth embodiments.

The length dimension D11 of the upper connecting portion 121 in the first direction (±x direction) is greater than the length dimension L1 of the deformation array 110 in the first direction (±x direction). Meanwhile, the length dimension D12 of the upper connecting portion 121 in the second direction (±z direction) is greater than the length dimension L2 of the deformation array 110 in the second direction (±z direction). As a result, the length dimension D11 of the upper connecting portion 121 in the first direction (±x direction) is greater than the length dimension L1 of the deformation array 110 in the first direction (±x direction), and the length dimension D12 of the upper connecting portion 121 in the second direction (±z direction) is greater than the length dimension L2 of the deformation array 110 in the second direction (±z direction).

Meanwhile, the length dimension D21 of the lower connecting portion 123 in the first direction (±x direction) is less than or equal to the length dimension D11 of the upper connecting portion 121 in the first direction (±x direction), and the length dimension D22 of the lower connecting portion 123 in the second direction (±z direction) is less than or equal to the length dimension D12 of the upper connecting portion 121 in the second direction (Iz direction). Under these numerical conditions, the electrical connector can be easily installed in the guide hole 210 of the guide plate 200.

### Sixth Embodiment

Next, a sixth embodiment of the electrical connector 100 according to the present invention will be described. However, the following description of the sixth embodiment will focus on the characteristic components compared to the second embodiment, and the description of the same or similar components as in the second embodiment will be omitted as much as possible.

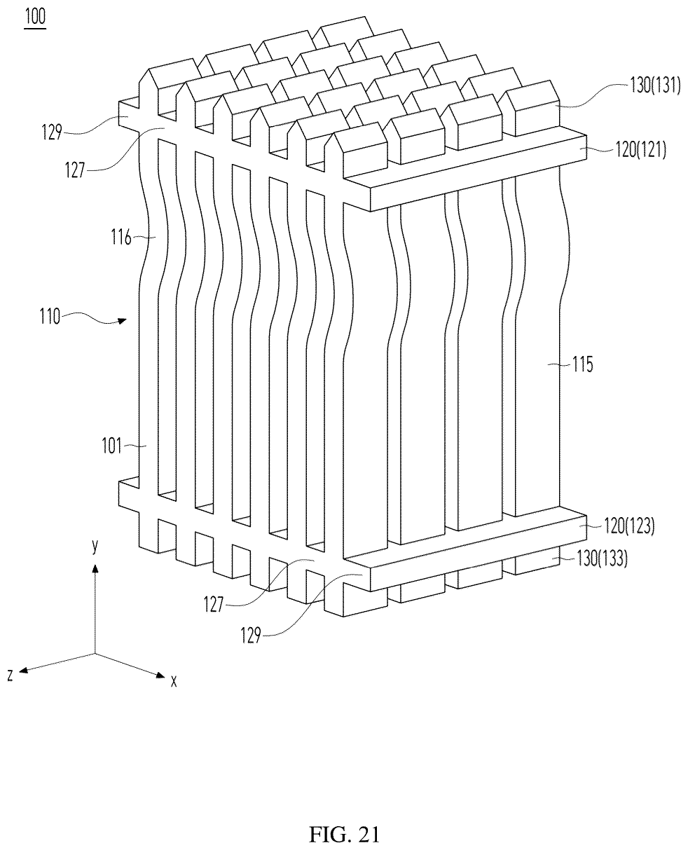

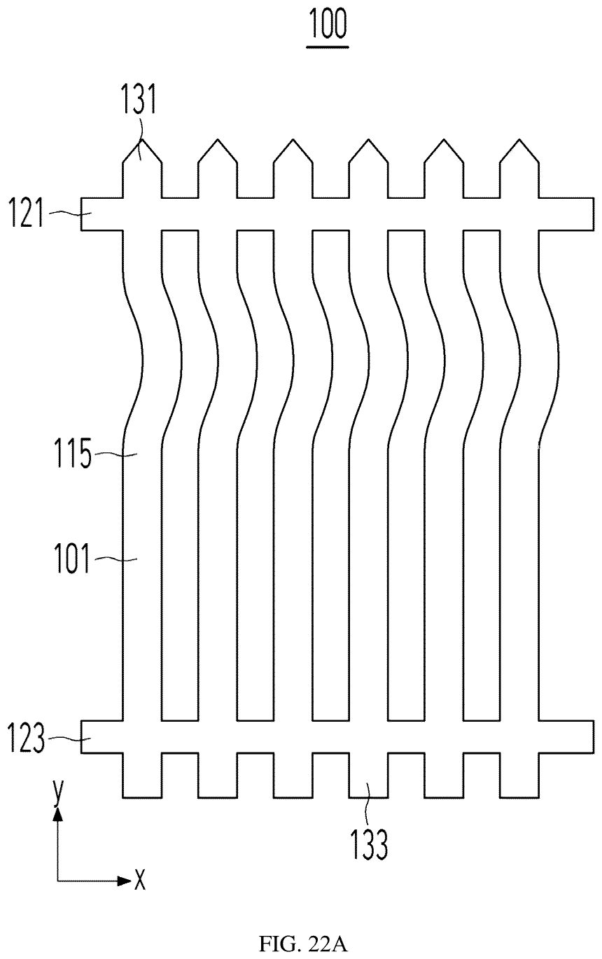

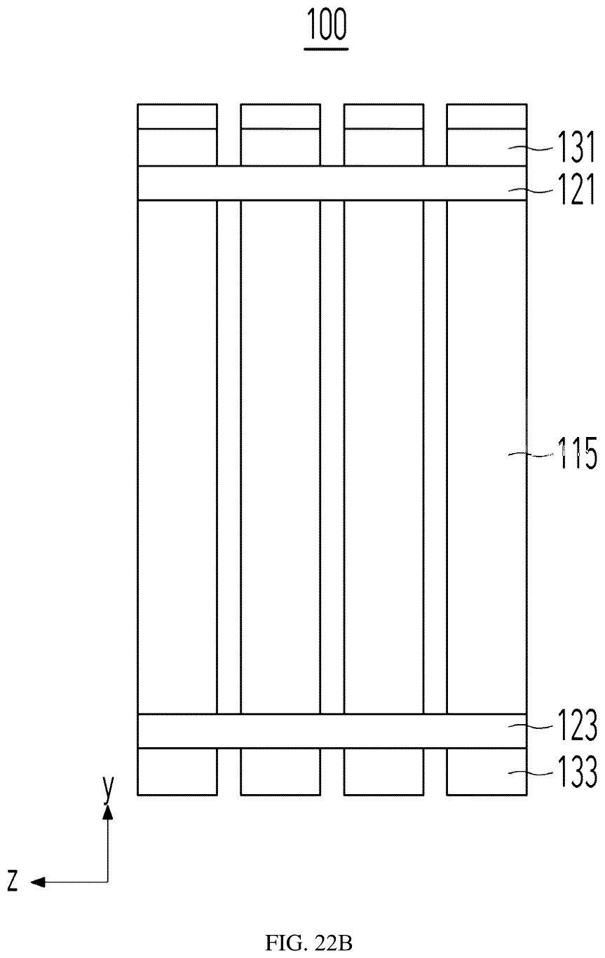

FIG. 21 is a perspective view of an electrical connector 100 according to a preferred sixth embodiment of the present invention, FIG. 22A is a front view of the electrical connector 100 according to the preferred sixth embodiment of the present invention, and FIG. 22B is a side view of the electrical connector 100 according to the preferred sixth embodiment of the present invention.

The electrical connector 100 according to the sixth embodiment comprises a plurality of unit needle pins 101 arranged to be spaced apart from each other and a connecting portion 120 connecting them. The connecting portion 120 comprises an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The sixth embodiment differs from the second embodiment in that it comprises an upper connecting portion 121 provided on the upper part of the deformation array 110 and a lower connecting portion 123 provided on the lower part of the deformation array 110, and it differs from the second embodiment in that it comprises an upper tip portion 131 provided on the upper part of the upper connecting portion 121 and a lower tip portion 133 provided on the lower part of the lower connecting portion 123.

The electrical connector 100 is configured such that the plurality of unit needle pins 101 are connected to each other by the upper connecting portion 121 and the lower connecting portion 123, and each beam portion 115 is spaced apart from each other, each upper tip portion 131 is spaced apart from each other, and each lower tip portion 133 is spaced apart from each other.

The upper connecting portion 121 bundles the upper parts of the plurality of beam portions 115 provided in a bundle form, and the lower connecting portion 123 also bundles the lower parts of the plurality of beam portions 115 provided in a bundle form.

The outer connecting portion 129 of the upper connecting portion 121 is provided only in the first direction (±x direction) and not in the second direction (±z direction), and the outer connecting portion 129 of the lower connecting portion 123 is also provided only in the first direction (±x direction) and not in the second direction (±z direction).

The upper tip portion 131 is provided to be spaced apart from each other in the first direction (±x direction). Meanwhile, the upper tip portion 131 is provided to be spaced apart from each other in the second direction (±z direction). Therefore, the upper tip portion 131 is provided to be spaced apart from each other in the first direction (±x direction) and also spaced apart from each other in the second direction (±z direction).

Each upper tip portion 131 can be provided in alignment with the longitudinal direction of each beam portion 115 corresponding to each beam portion 115.

The spacing distance of the upper tip portions 131 in the first direction (±x direction) is the same as the spacing distance of the beam portions 115 in the first direction (±x direction), and the spacing distance of the upper tip portions 131 in the second direction (±z direction) is the same as the spacing distance of the beam portions 115 in the second direction (±z direction).

The lower tip portion 133 is provided to be spaced apart from each other in the first direction (±x direction). Meanwhile, the lower tip portion 133 is provided to be spaced apart from each other in the second direction (±z direction). Therefore, the lower tip portion 130 is provided to be spaced apart from each other in the first direction (±x direction) and also spaced apart from each other in the second direction (±z direction).

Each lower tip portion 133 can be provided in alignment with the longitudinal direction of each beam portion 115 corresponding to each beam portion 115.

The spacing distance of the lower tip portions 133 in the first direction (±x direction) is the same as the spacing distance of the beam portions 115 in the first direction (±x direction), and the spacing distance of the lower tip portions 133 in the second direction (±z direction) is the same as the spacing distance of the beam portions 115 in the second direction (±z direction).

### Seventh Embodiment

Next, a seventh embodiment of the electrical connector 100 according to the present invention will be described. However, the following description of the seventh embodiment will focus on the characteristic components compared to the sixth embodiment, and the description of the same or similar components as in the sixth embodiment will be omitted as much as possible.

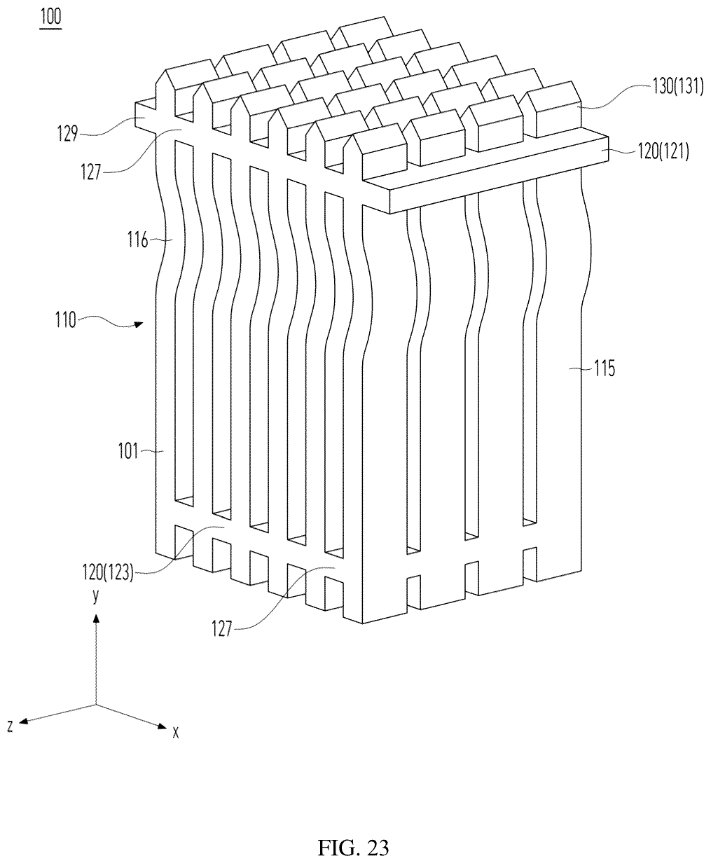

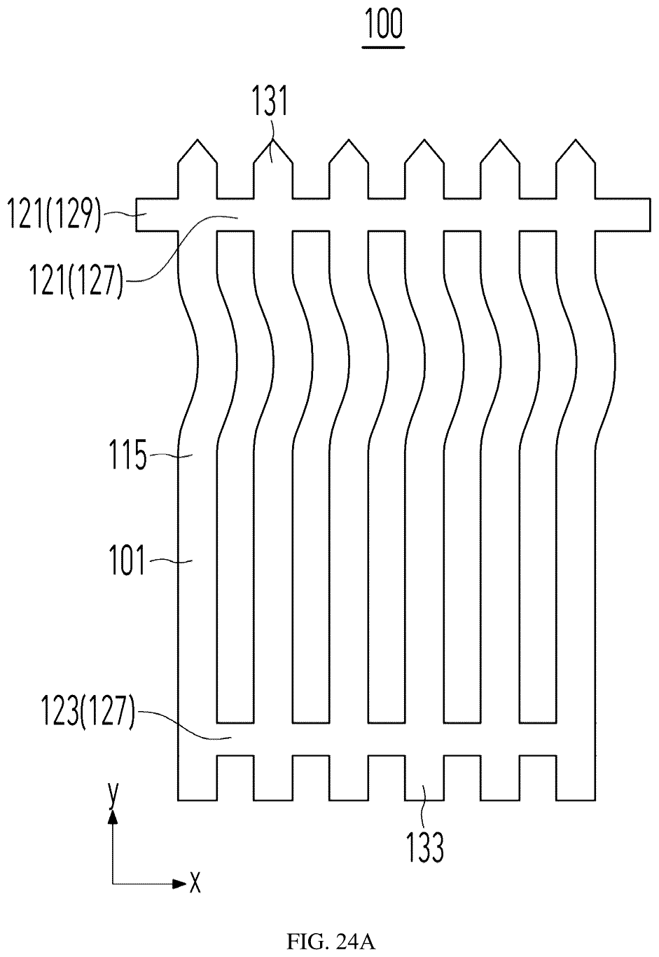

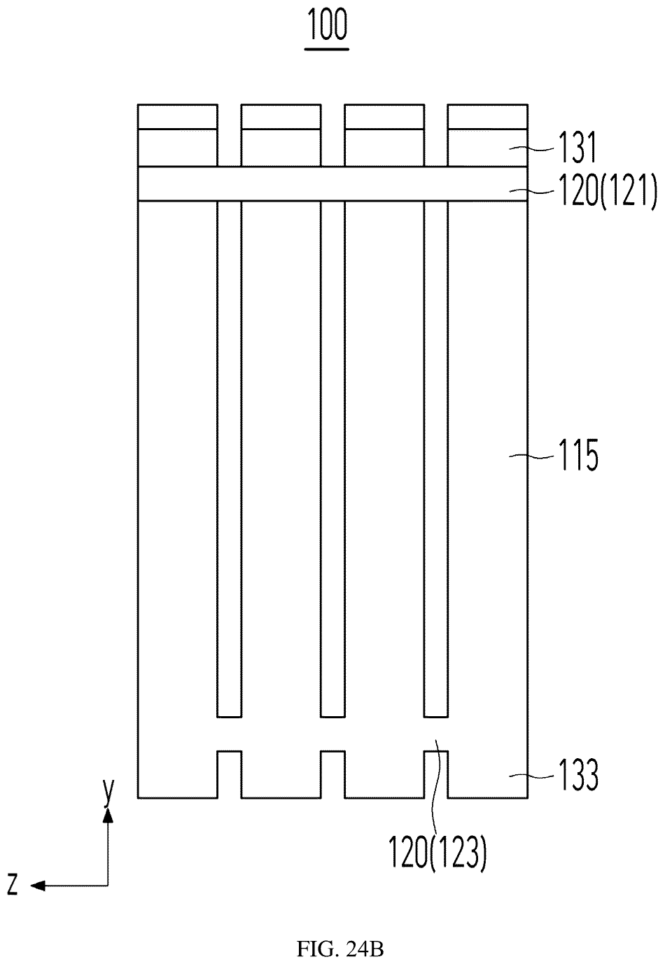

FIG. 23 is a perspective view of an electrical connector 100 according to a preferred seventh embodiment of the present invention, FIG. 24A is a front view of the electrical connector 100 according to the preferred seventh embodiment of the present invention, and FIG. 24B is a side view of the electrical connector 100 according to the preferred seventh embodiment of the present invention.

The electrical connector 100 according to the seventh embodiment comprises a plurality of unit needle pins 101 arranged to be spaced apart from each other and a connecting portion 120 connecting them. The connecting portion 120 comprises an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The seventh embodiment differs from the sixth embodiment in that the lower connecting portion 123 comprises only the inner connecting portion 127 and does not comprise the outer connecting portion 129, while the rest of the configuration is the same.

### Eighth Embodiment

Next, an eighth embodiment of the electrical connector 100 according to the present invention will be described. However, the following description of the eighth embodiment will focus on the characteristic components compared to the seventh embodiment, and the description of the same or similar components as in the seventh embodiment will be omitted as much as possible.

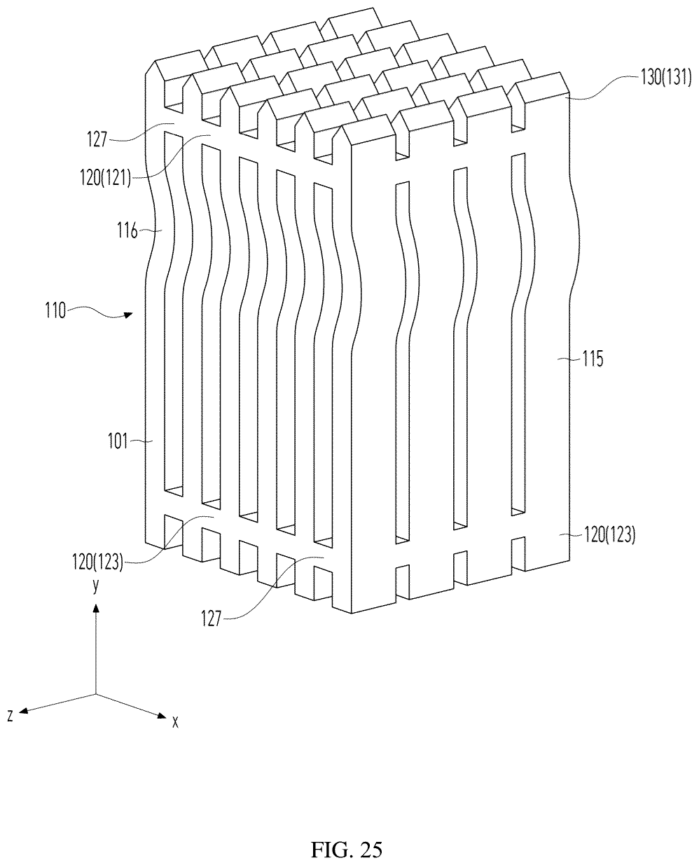

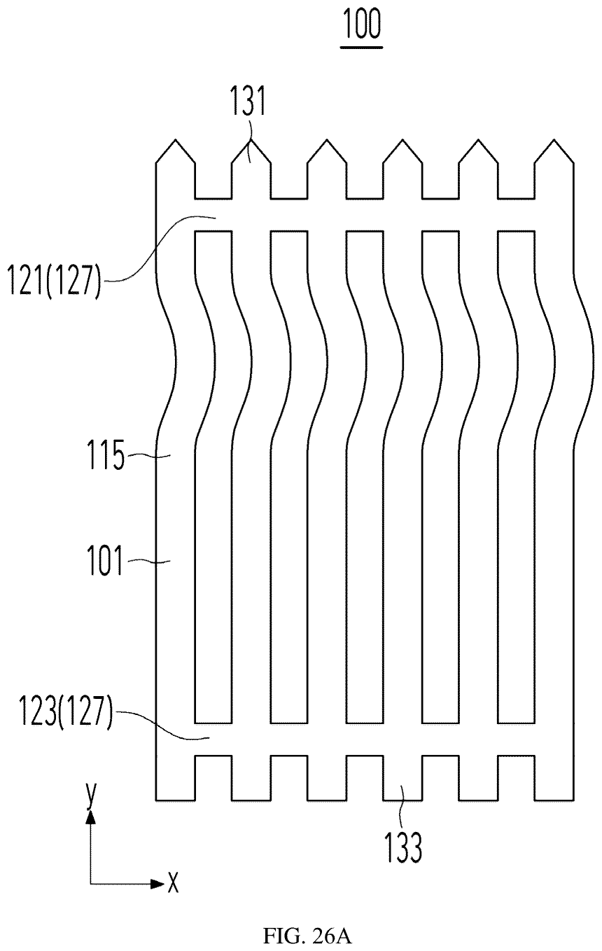

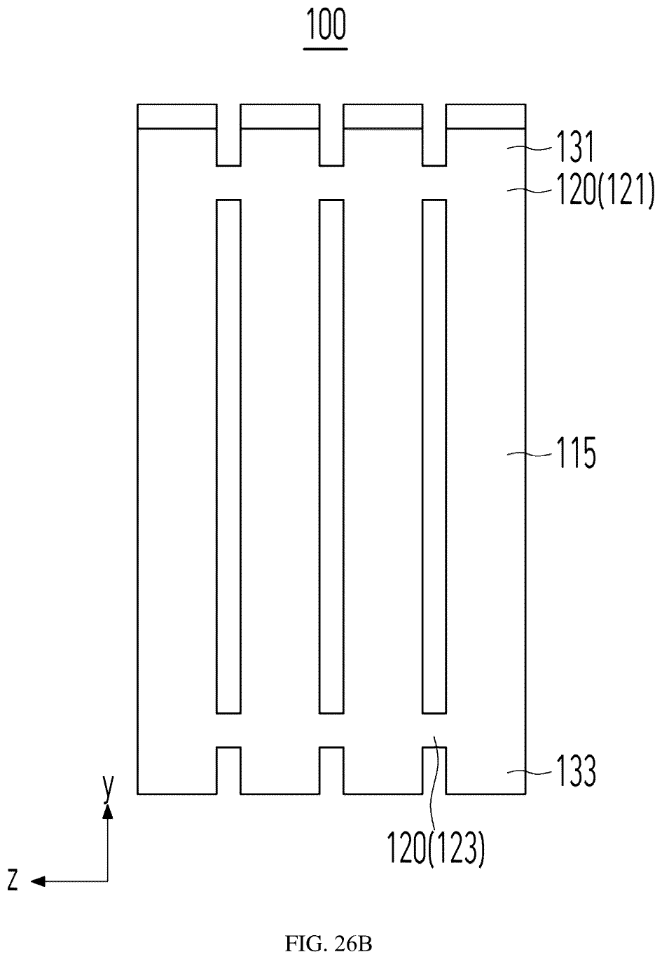

FIG. 25 is a perspective view of an electrical connector 100 according to a preferred eighth embodiment of the present invention, FIG. 26A is a front view of the electrical connector 100 according to the preferred eighth embodiment of the present invention, and FIG. 26B is a side view of the electrical connector 100 according to the preferred eighth embodiment of the present invention.

The electrical connector 100 according to the eighth embodiment comprises a plurality of unit needle pins 101 arranged to be spaced apart from each other and a connecting portion 120 connecting them. The connecting portion 120 comprises an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The upper connecting portion 121 of the eighth embodiment differs from the seventh embodiment in that it comprises only the inner connecting portion 127 and does not comprise the outer connecting portion 129, while the rest of the configuration is the same.

### Ninth Embodiment

Next, a ninth embodiment of the electrical connector 100 according to the present invention will be described. However, the following description of the ninth embodiment will focus on the characteristic components compared to the seventh embodiment, and the description of the same or similar components as in the seventh embodiment will be omitted as much as possible.

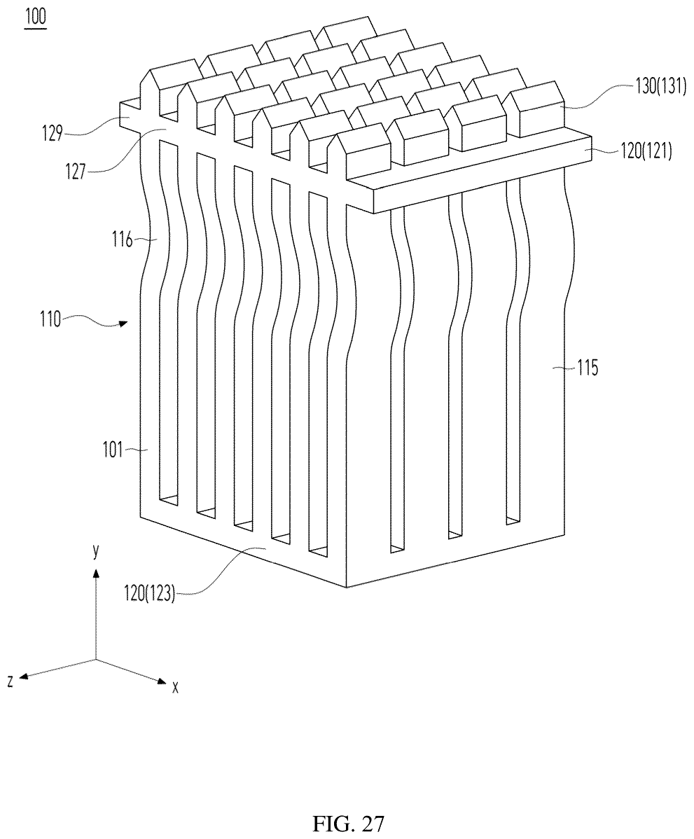

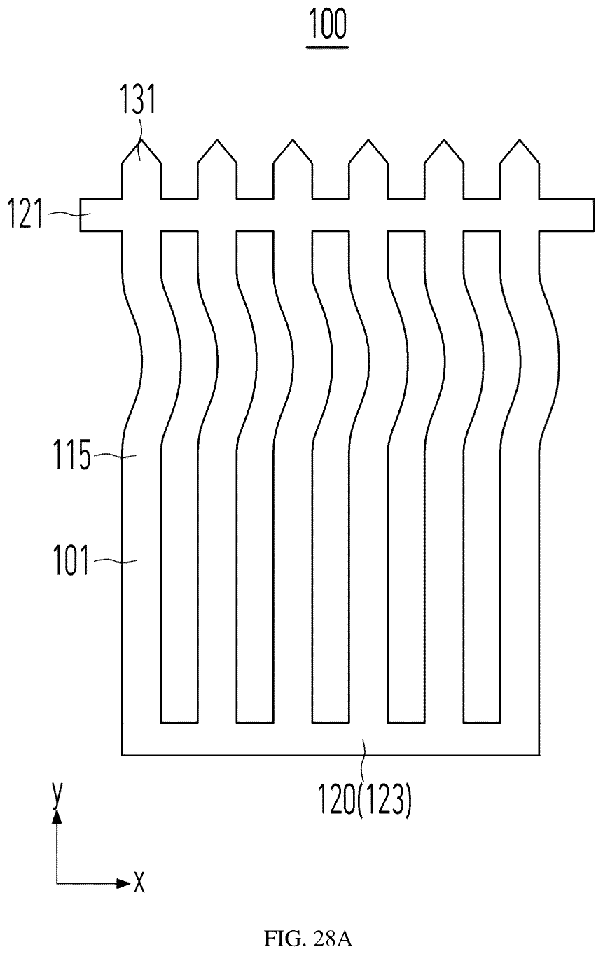

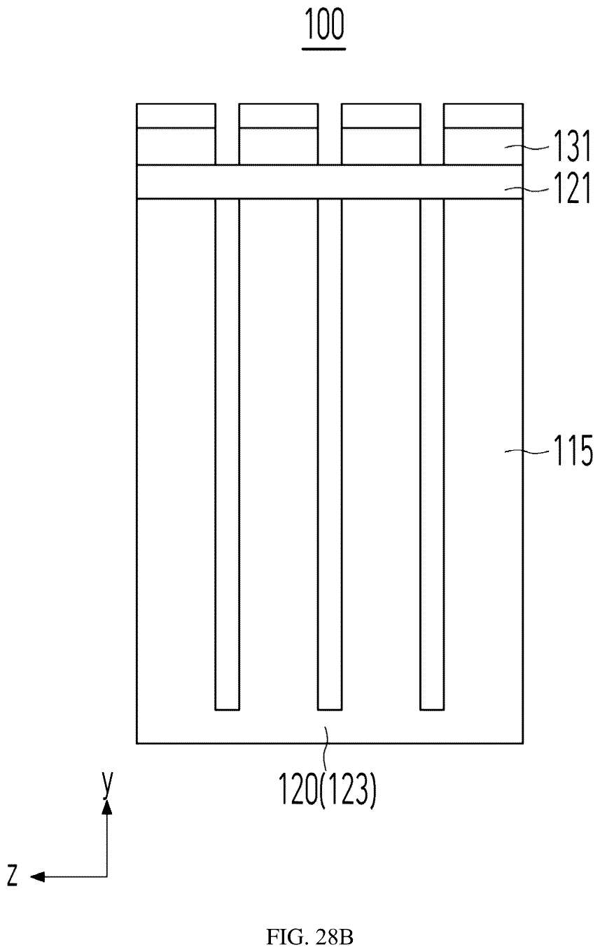

FIG. 27 is a perspective view of an electrical connector 100 according to a preferred ninth embodiment of the present invention, FIG. 28A is a front view of the electrical connector 100 according to the preferred ninth embodiment of the present invention, and FIG. 28B is a side view of the electrical connector 100 according to the preferred ninth embodiment of the present invention.

The electrical connector 100 according to the ninth embodiment comprises a plurality of unit needle pins 101 arranged to be spaced apart from each other and a connecting portion 120 connecting them. The connecting portion 120 comprises an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The ninth embodiment differs from the seventh embodiment in that there is no separate individual tip portion provided at the bottom of the lower connecting portion 123 of the ninth embodiment, while the rest of the configuration is the same.

### Tenth Embodiment

Next, the tenth embodiment of the electrical connector 100 according to the present invention will be described. However, the following description of the tenth embodiment will focus on the characteristic components compared to the second embodiment, and the description of the components that are the same or similar to those of the second embodiment will be omitted as much as possible.

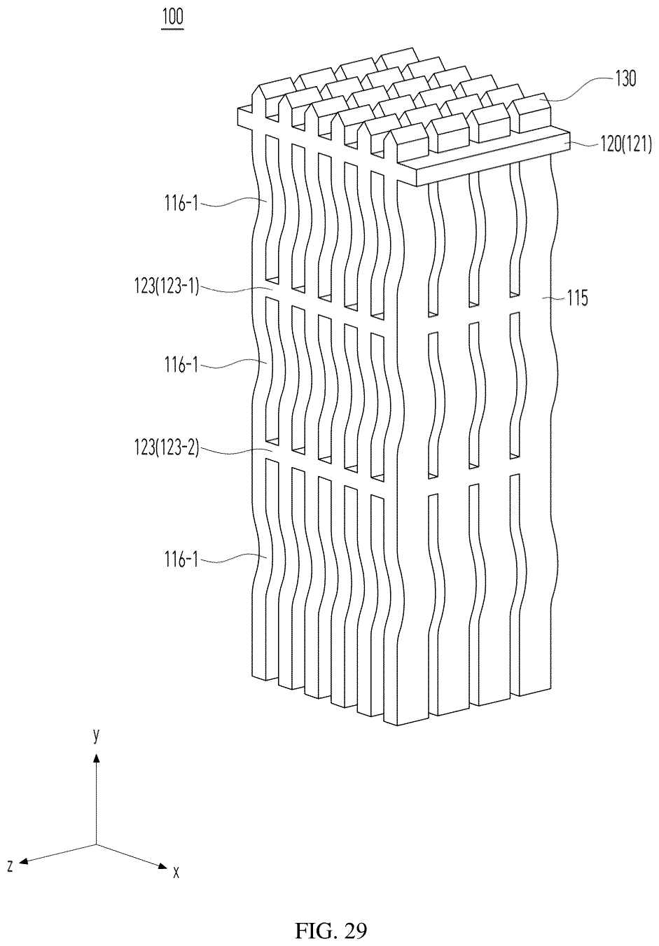

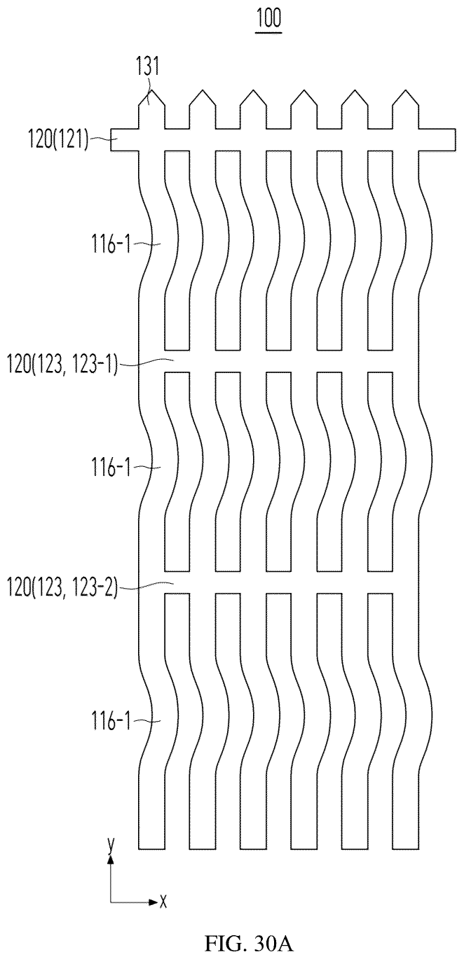

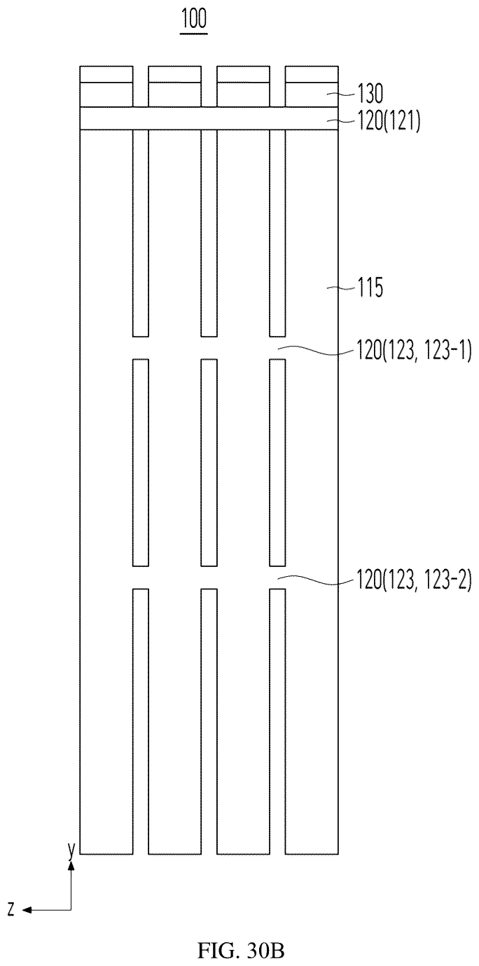

FIG. 29 is a perspective view of an electrical connector 100 according to a preferred tenth embodiment of the present invention, FIG. 30A is a front view of the electrical connector 100 according to the preferred tenth embodiment of the present invention, and FIG. 30B is a side view of the electrical connector 100 according to the preferred tenth embodiment of the present invention.

The electrical connector 100 according to the tenth embodiment comprises a plurality of unit needle pins 101 arranged to be spaced apart from each other and a connecting portion 120 connecting them. The connecting portion 120 includes an upper connecting portion 121, a first lower connecting portion 123-1, and a second lower connecting portion 123-2. The electrical connector 100 is configured such that the plurality of unit needle pins 101 are connected to each other by the connecting portion 120, and each beam portion 115 and tip portion 130 are spaced apart from each other.

The second embodiment has only one connecting portion 120, whereas the tenth embodiment has three connecting portions 120. Additionally, the second embodiment has only one deformation section in the beam portion 115, while the tenth embodiment has multiple deformation sections, which is a structural difference.

The connecting portion 120 of the tenth embodiment includes an upper connecting portion 121 and a lower connecting portion 123, wherein the lower connecting portion 123 includes a first lower connecting portion 123-1 located below the upper connecting portion 121 and a second lower connecting portion 123-2 located below the first lower connecting portion 123-1.

The upper connecting portion 121 includes an inner connecting portion 127 and an outer connecting portion 129, but the first lower connecting portion 123-1 and the second lower connecting portion 123-2 include only the inner connecting portion 127 and do not include the outer connecting portion 129.

A first bending portion 116-1 is provided in the beam portion 115 between the upper connecting portion 121 and the first lower connecting portion 123-1, a second bending portion 116-2 is provided in the beam portion 115 between the first lower connecting portion 123-1 and the second lower connecting portion 123-2, and a third bending portion 116-3 is provided below the second lower connecting portion 123-2.

Meanwhile, in the tenth embodiment, the connecting portion 120 is illustrated as having three parts, but it is not limited to this, and the configuration of the tenth embodiment may include four or more connecting portions 120.

### Eleventh Embodiment

Next, the eleventh embodiment of the electrical connector 100 according to the present invention will be described. However, the following description of the eleventh embodiment will focus on the characteristic components compared to the first embodiment, and the description of the components that are the same or similar to those of the first embodiment will be omitted as much as possible.

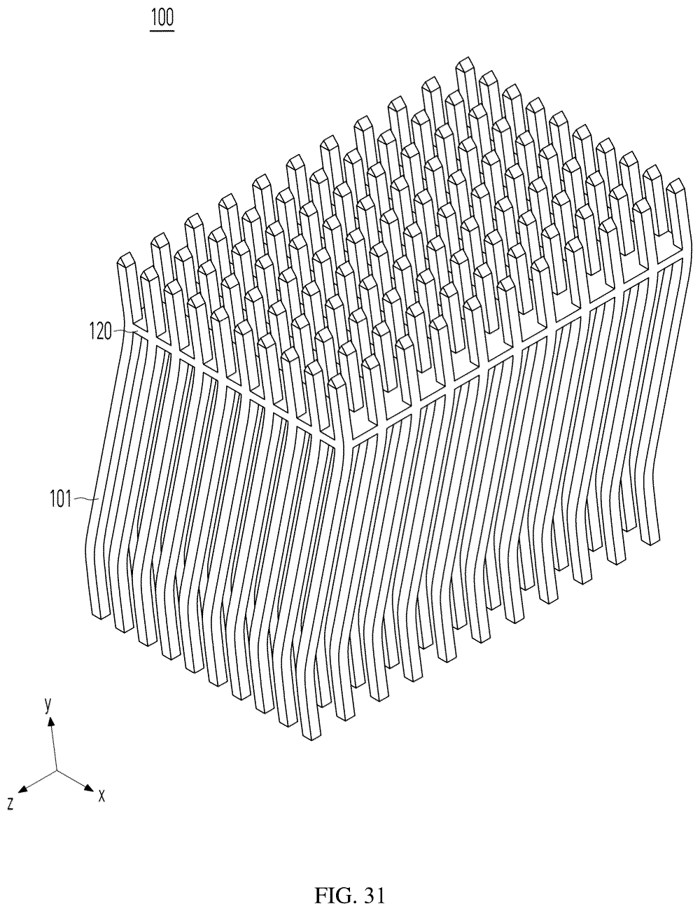

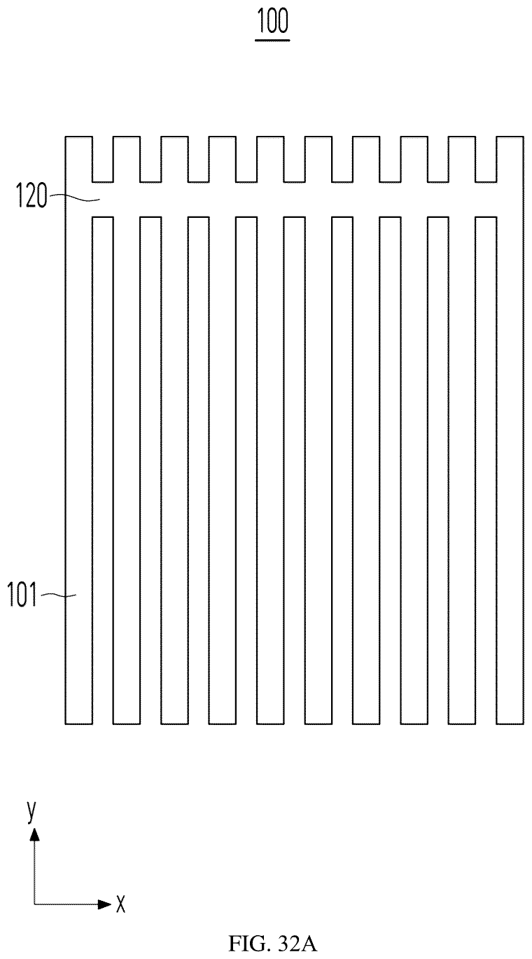

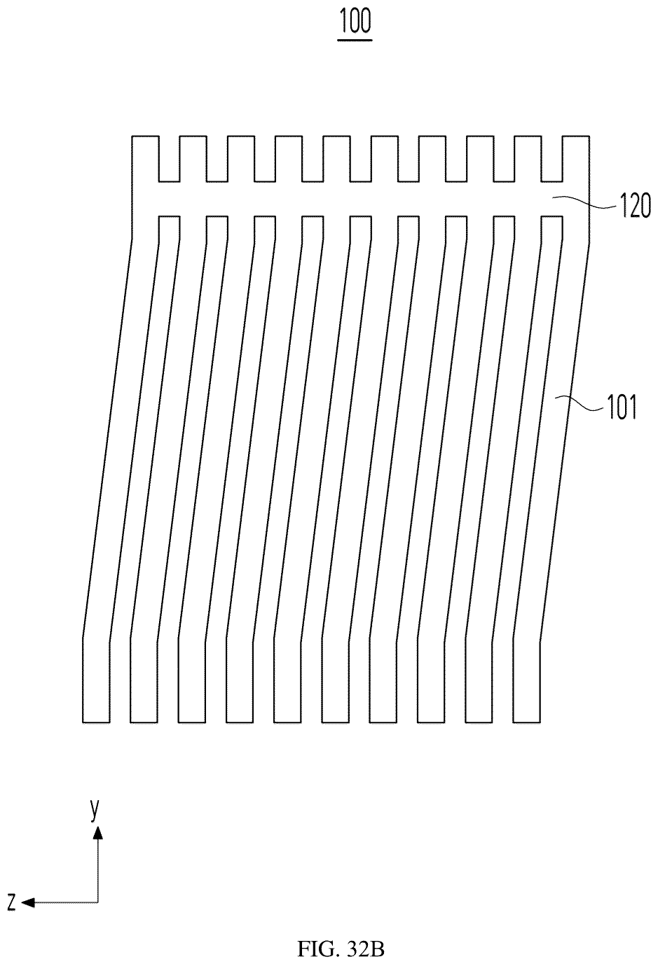

FIG. 31 is a perspective view of an electrical connector 100 according to a preferred eleventh embodiment of the present invention, FIG. 32A is a front view of the electrical connector 100 according to the preferred eleventh embodiment of the present invention, and FIG. 32B is a side view of the electrical connector 100 according to the preferred eleventh embodiment of the present invention.

The electrical connector 100 according to the eleventh embodiment comprises a plurality of unit needle pins 101 arranged to be spaced apart from each other and a connecting portion 120 connecting them. The connecting portion 120 includes an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The unit needle pins 101 of the eleventh embodiment are connected to each other by the connecting portion 120 to form a bundle, which is the same as the configuration of the first embodiment. However, the unit needle pins 101 of the eleventh embodiment have a substantially square cross-sectional shape and sufficient clearance between each unit needle pin 101, which is a difference from the configuration of the first embodiment. By reducing the cross-sectional area of the unit needle pins 101, the overall surface area of the electrical connector 100 can be increased. Additionally, the sufficient spacing between the unit needle pins 101 makes it easier to provide an insulating elastic material between the unit needle pins 101.

The insulating elastic material can be formed of a material including at least one of rubber, silicone, and urethane. The insulating elastic material is preferably a polymer material having a cross-linked structure. Various curable polymer material forming materials can be used to obtain such an insulating elastic connecting portion, and specific examples include conjugated diene rubbers such as polybutadiene rubber, natural rubber, polyisoprene rubber, styrene-butadiene copolymer rubber, acrylonitrile-butadiene copolymer rubber, and their hydrogenated products, block copolymer rubbers such as styrene-butadiene-diene block copolymer rubber, styrene-isoprene block copolymer, and their hydrogenated products, chloroprene rubber, urethane rubber, polyester rubber, epichlorohydrin rubber, silicone rubber, ethylene-propylene copolymer rubber, and ethylene-propylene-diene copolymer rubber.

The insulating elastic material can be provided on the upper portion of the connecting portion 120. According to the configuration in which the insulating elastic material is provided on the upper portion of the connecting portion 120, it is possible to prevent damage to the external terminal 21 of the inspection target 20.

Meanwhile, the insulating elastic material can be provided on the lower portion of the connecting portion 120. According to the configuration in which the insulating elastic material is provided on the lower portion of the connecting portion 120, the insulating elastic material functions to complement the elasticity of the unit needle pins 101. Since the insulating elastic material complements the elasticity of the unit needle pins 101, it is possible to arrange more unit needle pins 101 while reducing the cross-sectional area of the unit needle pins 101, and it is possible to adopt a metal with high electrical conductivity for the unit needle pins 101. The unit needle pins 101 are preferably formed of a metal with high electrical conductivity, such as copper (Cu), silver (Ag), gold (Au), or an alloy thereof. However, it is not limited to this. Although metals with high electrical conductivity have high ductility and low elasticity, it is possible to adopt a metal with high electrical conductivity as the material of the unit needle pins 101 because the unit needle pins 101 include an insulating elastic material.

Meanwhile, the insulating elastic material can be provided on both the upper portion and the lower portion of the connecting portion 120.

### Twelfth Embodiment

Next, the twelfth embodiment of the electrical connector 100 according to the present invention will be described. However, the following description of the twelfth embodiment will focus on the characteristic components compared to the first embodiment, and the description of the components that are the same or similar to those of the first embodiment will be omitted as much as possible.

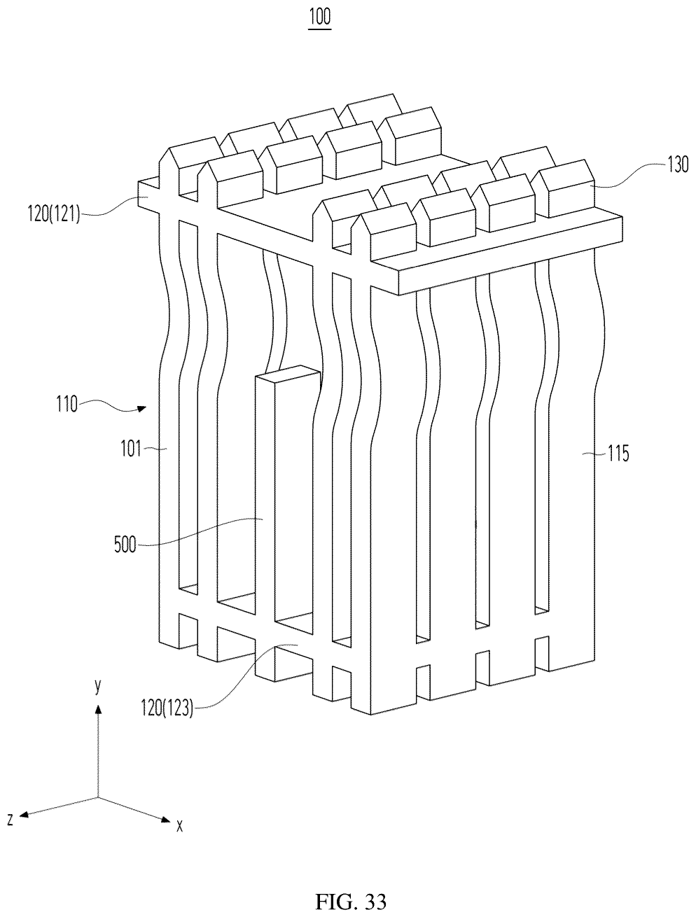

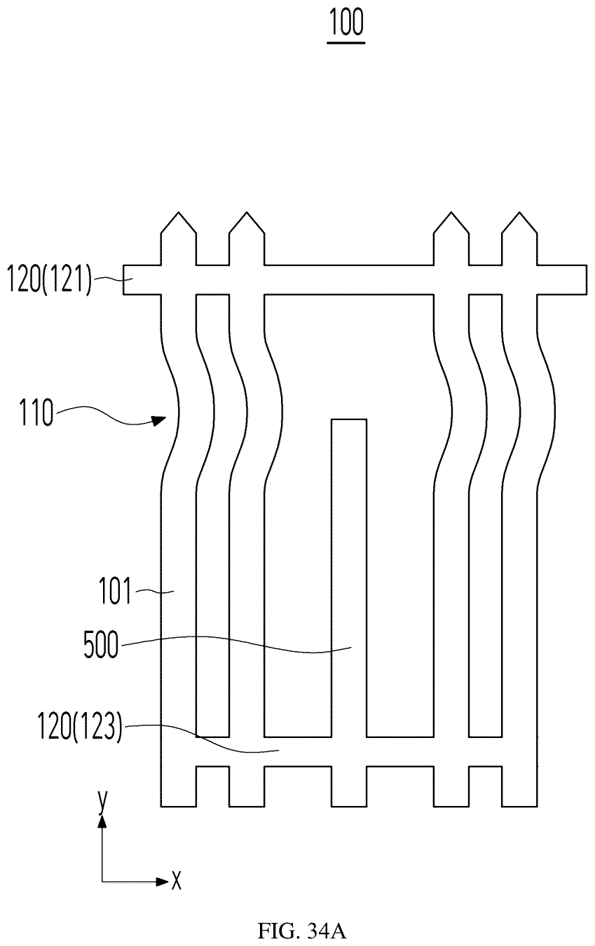

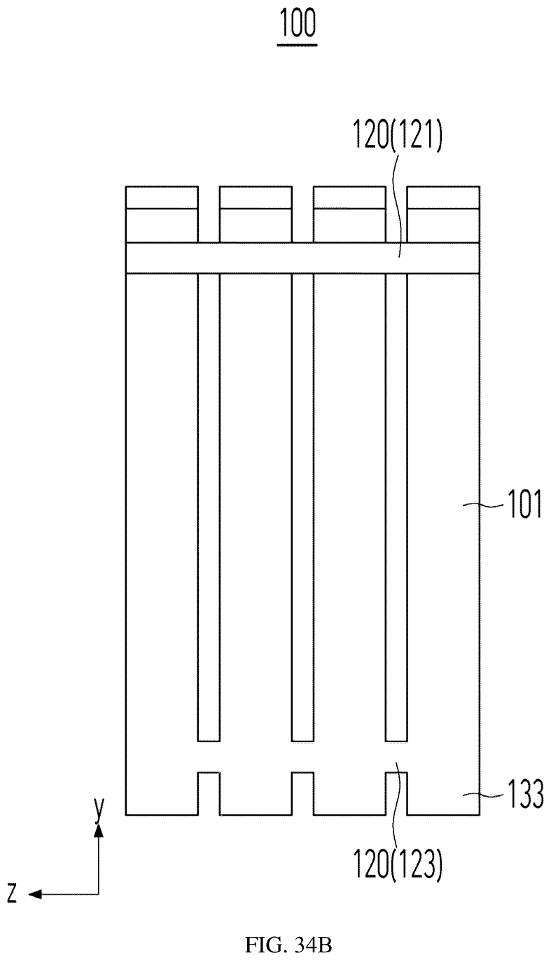

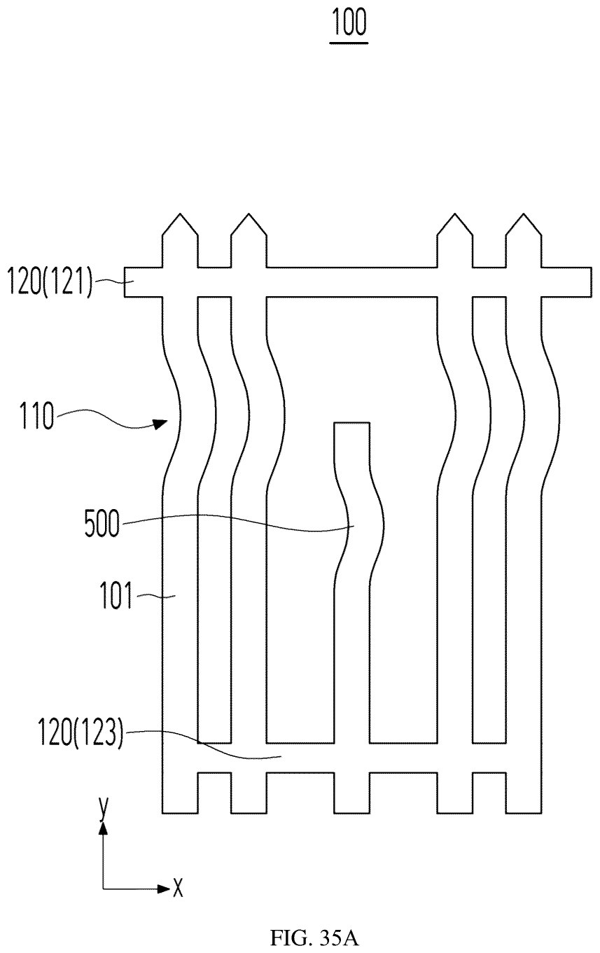

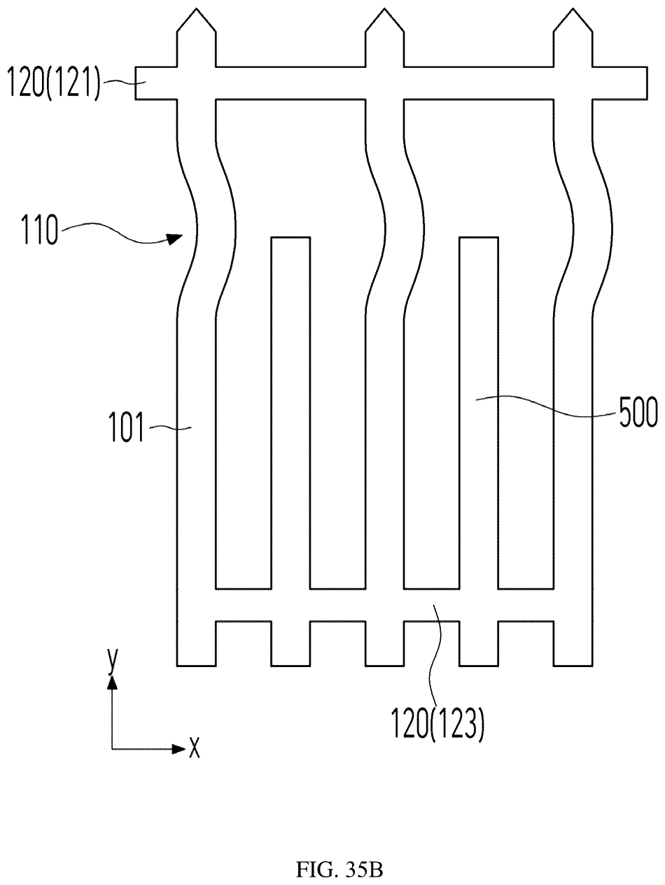

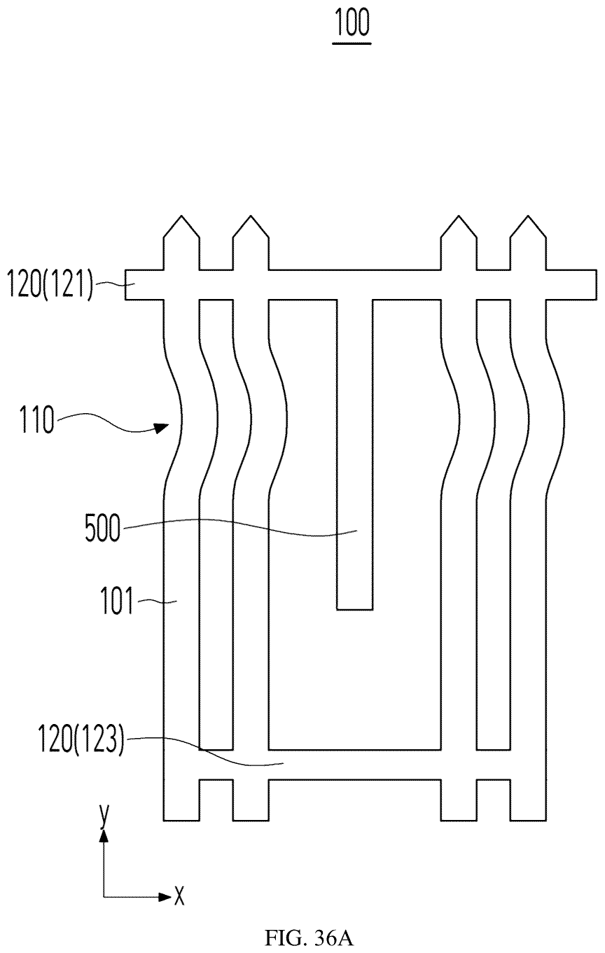

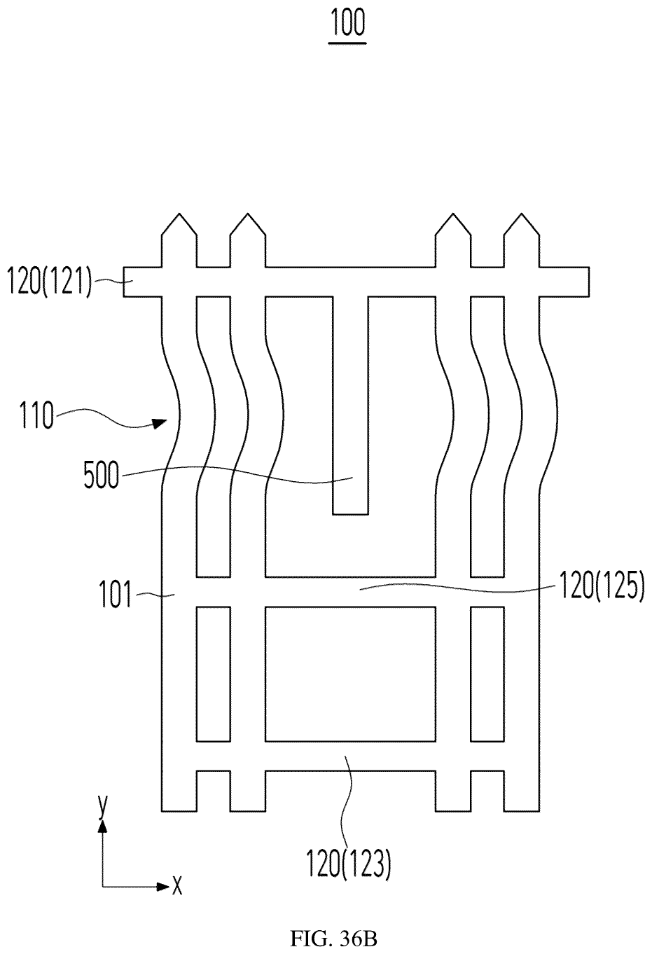

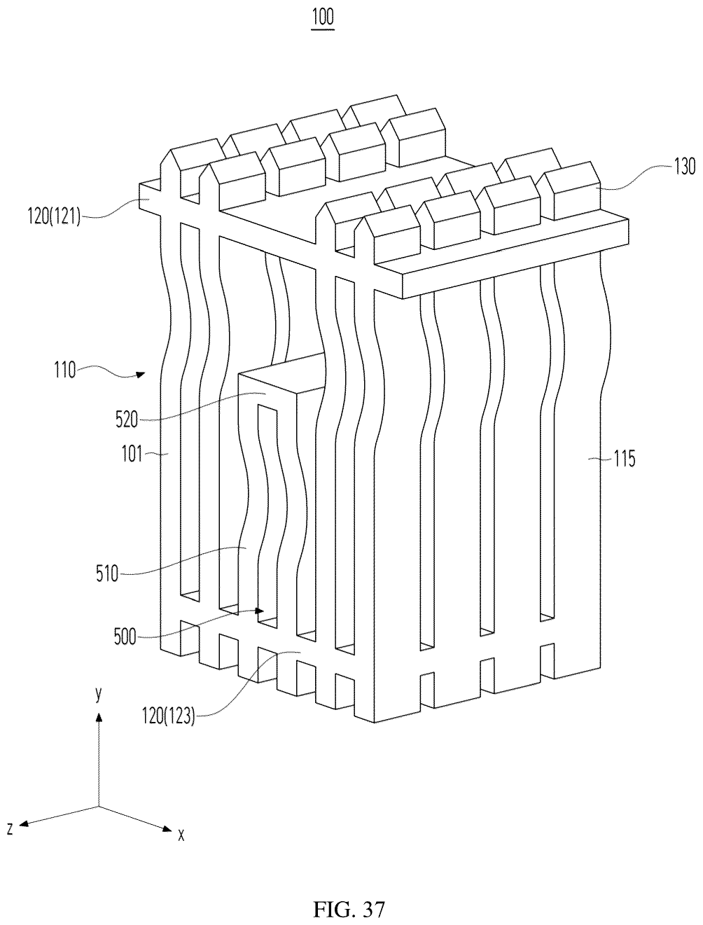

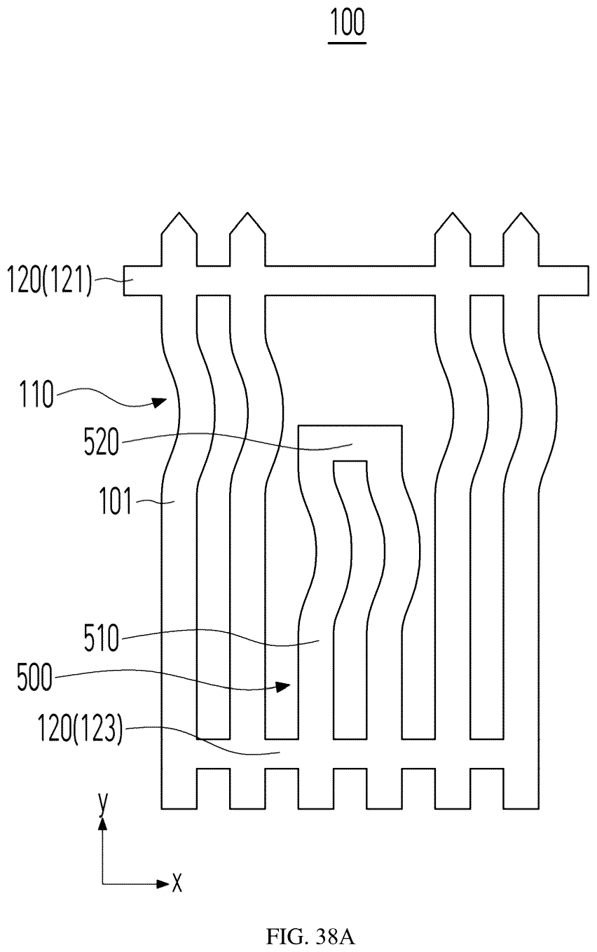

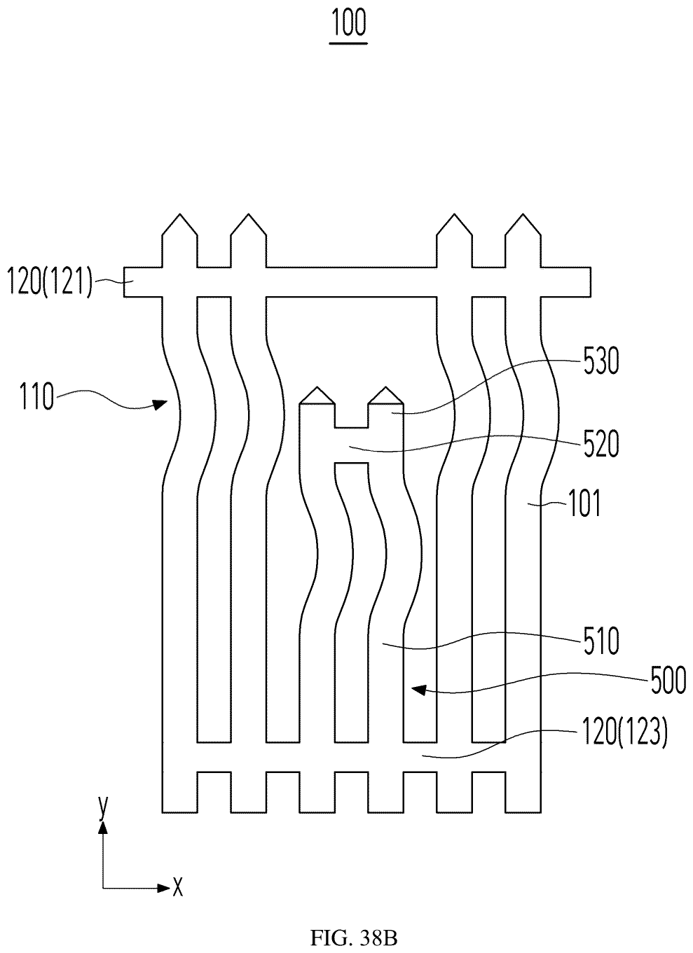

FIG. 33 is a perspective view of an electrical connector 100 according to a preferred twelfth embodiment of the present invention, FIG. 34A is a front view of the electrical connector 100 according to the preferred twelfth embodiment of the present invention, FIG. 34B is a side view of the electrical connector 100 according to the preferred twelfth embodiment of the present invention, FIG. 35A is a front view of a modification of the electrical connector 100 according to the preferred twelfth embodiment of the present invention, FIG. 35B is a front view of a modification of the electrical connector 100 according to the preferred twelfth embodiment of the present invention, FIG. 36A is a front view of a modification of the electrical connector 100 according to the preferred twelfth embodiment of the present invention, FIG. 36B is a front view of a modification of the electrical connector 100 according to the preferred twelfth embodiment of the present invention, FIG. 37 is a perspective view of a modification of the electrical connector 100 according to the preferred twelfth embodiment of the present invention, FIG. 38A is a front view of FIG. 37, and FIG. 38B is a modification of the electrical connector 100 shown in FIG. 37.

The electrical connector 100 according to the twelfth embodiment comprises a plurality of unit needle pins 101 arranged to be spaced apart from each other and a connecting portion 120 connecting them. The connecting portion 120 includes an upper connecting portion 121 and a lower connecting portion 123. The electrical connector 100 is configured such that the plurality of unit needle pins 101 are connected to each other by the connecting portion 120, and each beam portion 115 and tip portion 130 are spaced apart from each other.

The electrical connector 100 according to the twelfth embodiment differs from the configuration of the first embodiment in that it includes at least one stopper 500 to prevent excessive deformation of the deformation array 110. The stopper 500 is provided at a position where it can contact the connecting portion 120 when the deformation array 110 is excessively compressed. At least one stopper 500 is provided.

Referring to FIGS. 33, 34A, and 34B, the connecting portion 120 includes an upper connecting portion 121 provided on the upper part of the deformation array 110 and a lower connecting portion 123 provided on the lower part of the deformation array 110. This configuration may allow the unit needle pins 101 to be connected by the upper connecting portion 121 and the lower connecting portion 123 in a bundled form.

The stopper 500 is provided to extend in the longitudinal direction (±y direction) from the lower connecting portion 123 between the upper connecting portion 121 and the lower connecting portion 123. The lower part of the stopper 500 is connected to the lower connecting portion 123, and the upper part of the stopper 500 is provided as a free end.

The deformation array 110 may be compressed and deformed by external force and may be excessively compressed unintentionally. Such excessive compression deformation can cause damage to the beam portion 115 of the deformation array 110. However, according to the twelfth embodiment, even if the deformation array 110 is excessively compressed, the upper connecting portion 121 descends and contacts the stopper 500, thereby preventing further compression deformation of the deformation array 110 and preventing damage to the beam portion 115.

The stopper 500 may be provided between the beam portions 115. Preferably, it may be located at the center of the deformation array 110 in the first direction (±x direction). However, the position of the stopper 500 is not limited to this and can be located at any position that can prevent excessive deformation of the deformation array 110.

Although only one stopper 500 is shown in the drawings, it is possible to provide a plurality of stoppers spaced apart from each other.

Referring to FIG. 35A, the stopper 500 is provided in an elastically deformable structure. Through the configuration of the elastically deformable stopper 500, it is possible to prevent damage to the upper connecting portion 121 and/or the stopper 500 when the upper connecting portion 121 and the stopper 500 collide.

Referring to FIG. 35B, a plurality of stoppers 500 may be provided. By providing a plurality of stoppers 500, it is possible to prevent damage to the stopper 500 by dispersing the stress.

Referring to FIG. 36A, the stopper 500 is provided to extend in the longitudinal direction (±y direction) from the upper connecting portion 121 between the upper connecting portion 121 and the lower connecting portion 123. The upper part of the stopper 500 is connected to the upper connecting portion 121, and the lower part of the stopper 500 is provided as a free end. In this case, if the deformation array 110 is excessively compressed, the lower end of the stopper 500 descends and contacts the lower connecting portion 123, thereby preventing further compression deformation of the deformation array 110 and preventing damage to the beam portion 115.

Referring to FIG. 36B, the connecting portion 120 includes an upper connecting portion 121, a lower connecting portion 123, and an intermediate connecting portion 125 provided between the upper connecting portion 121 and the lower connecting portion 123. Compared to FIG. 36A, the length of the stopper 500 shown in FIG. 36B is shorter, and when the deformation array 110 is excessively compressed, the lower end of the stopper 500 contacts the intermediate connecting portion 125, thereby preventing further compression deformation of the deformation array 110 and preventing damage to the beam portion 115.

Referring to FIGS. 37 and 38A, the electrical connector 100 comprises a plurality of unit needle pins 101 arranged to be spaced apart from each other and a connecting portion 120 connecting them. The connecting portion 120 includes an upper connecting portion 121 and a lower connecting portion 123. The stopper 500 is provided to extend in the longitudinal direction (±y direction) from the lower connecting portion 123 between the upper connecting portion 121 and the lower connecting portion 123.

The stopper 500 comprises a plurality of stopper beam portions 510 and a stopper connecting portion 520 connecting the plurality of stopper beam portions 510. This can improve the rigidity of the stopper 500.

Even if the deformation array 110 is excessively compressed, the upper connecting portion 121 descends and contacts the stopper 500 with secured rigidity, thereby preventing further compression deformation of the deformation array 110 and preventing damage to the beam portion 115.

Referring to FIG. 38B, the structure differs from that of FIGS. 37 and 38A in that a stopper tip portion 530 is provided on the upper part of the stopper connecting portion 520, while the rest of the configuration is the same. Therefore, in the structure of FIGS. 37 and 38A, the upper surface of the stopper connecting portion 520 prevents the descent of the upper connecting portion 121, but in the structure shown in FIG. 38B, the stopper tip portion 530 prevents the descent of the upper connecting portion 121.

### Additional Explanation of the Connecting Portion

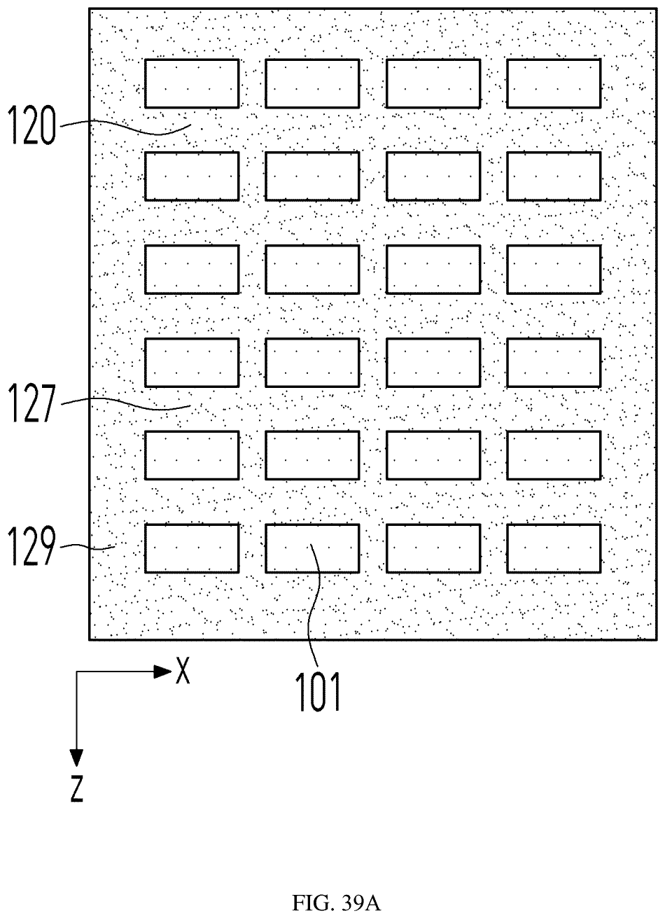

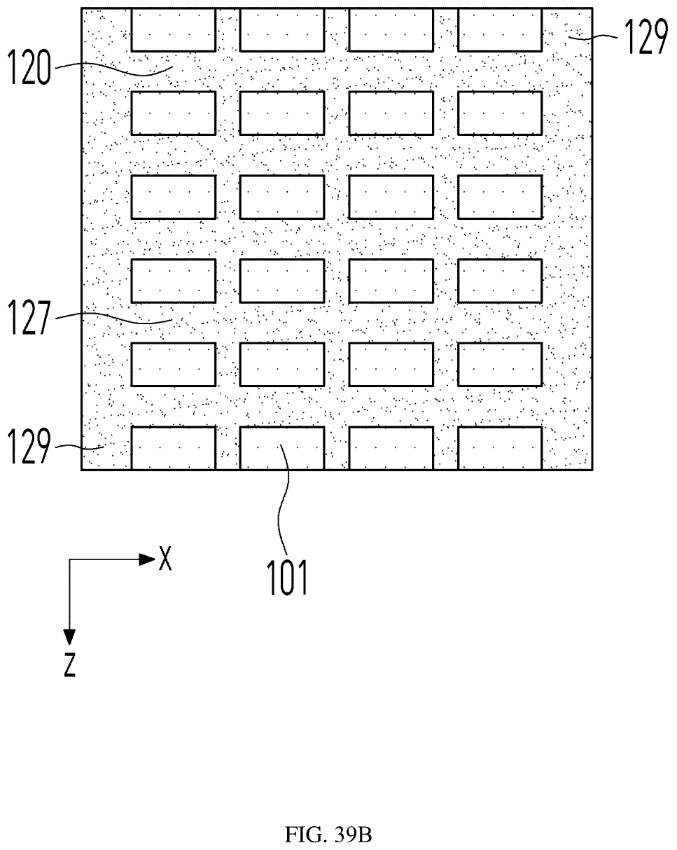

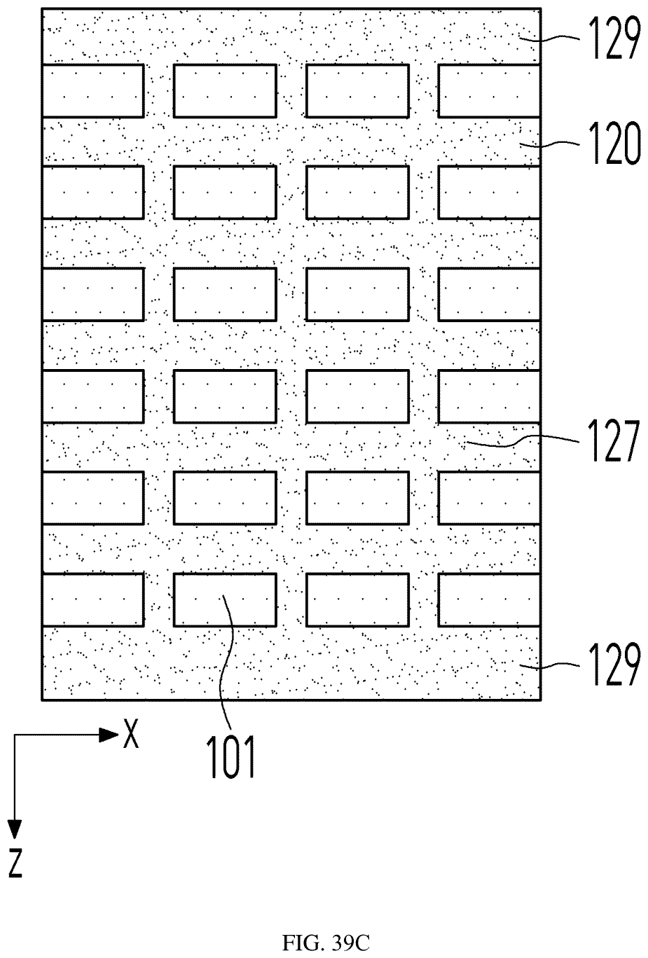

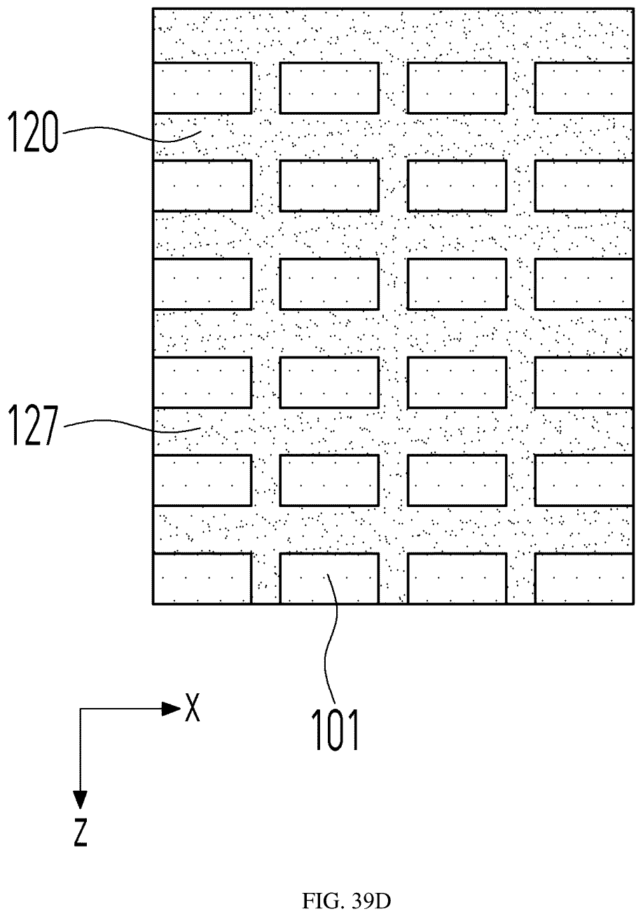

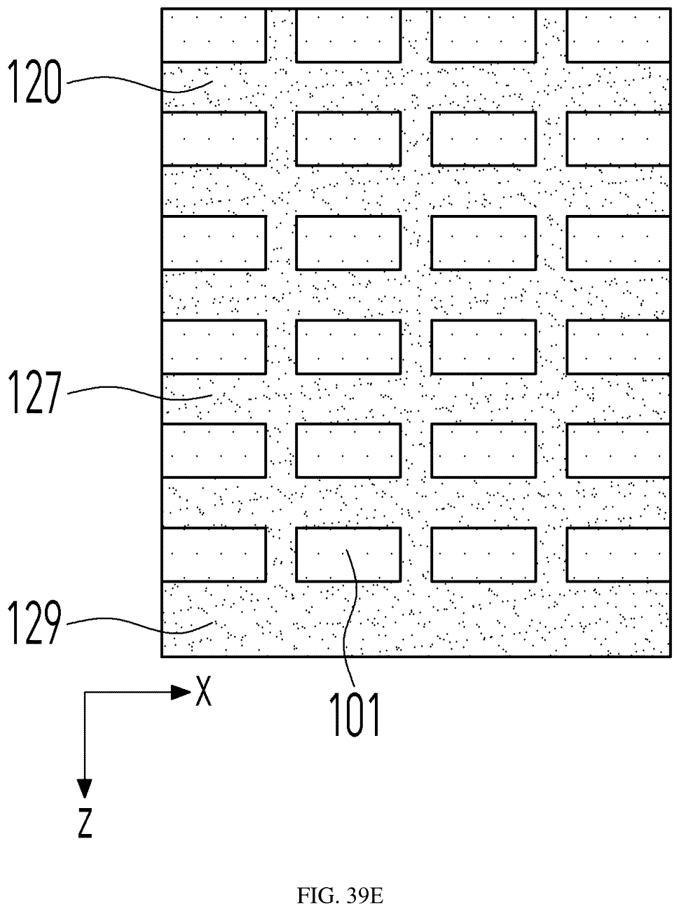

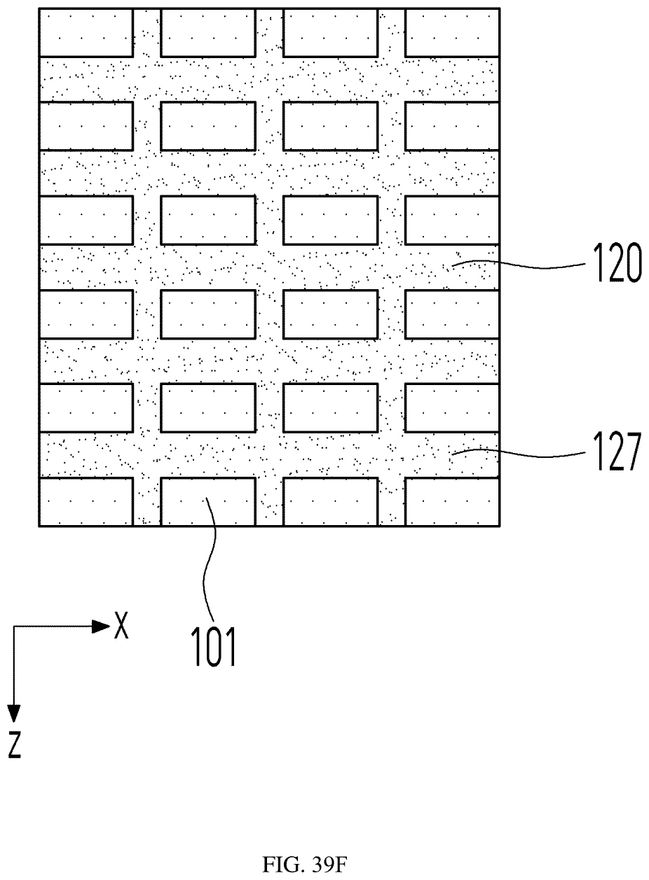

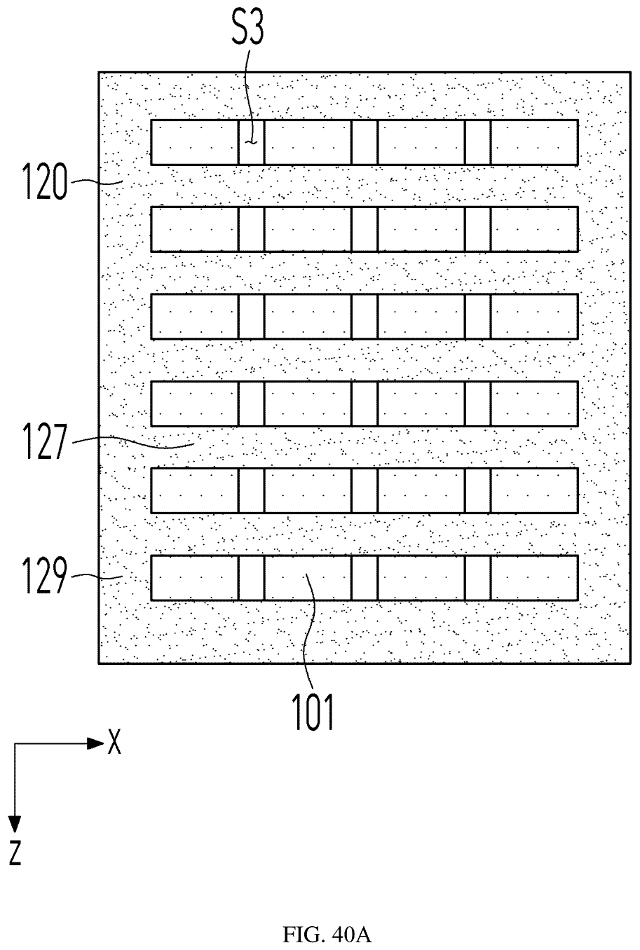

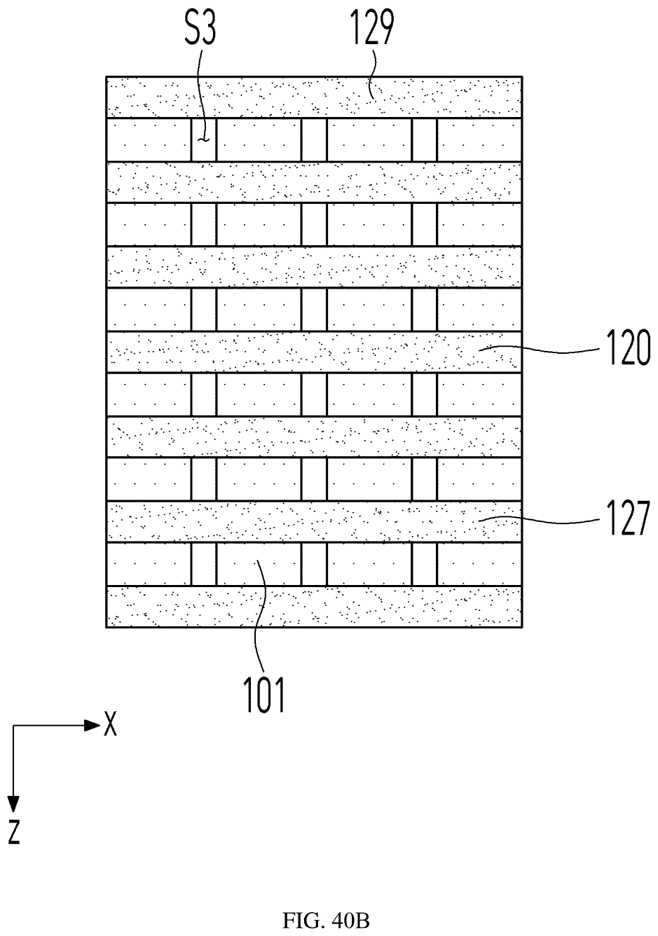

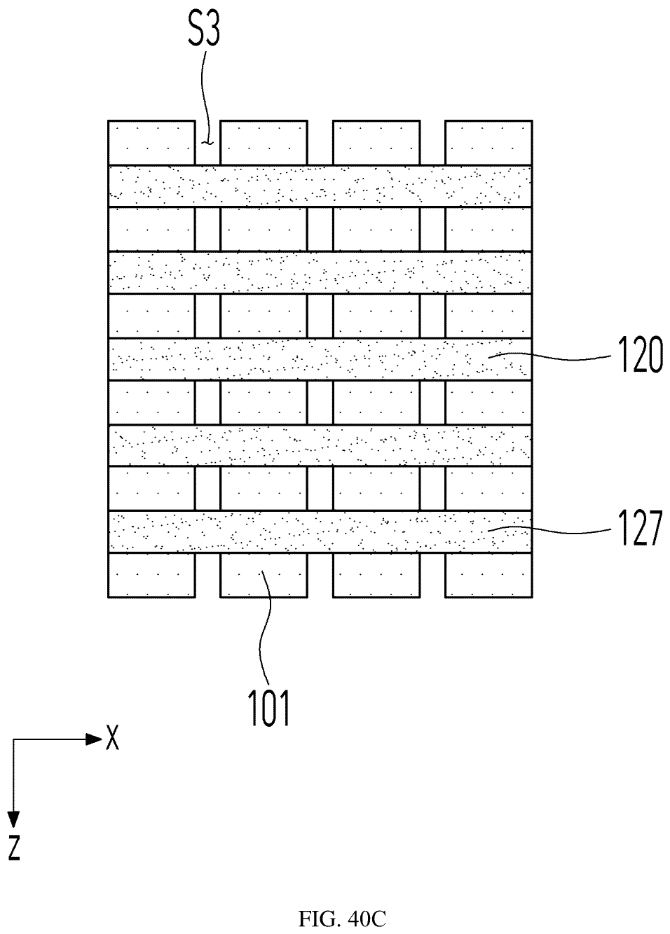

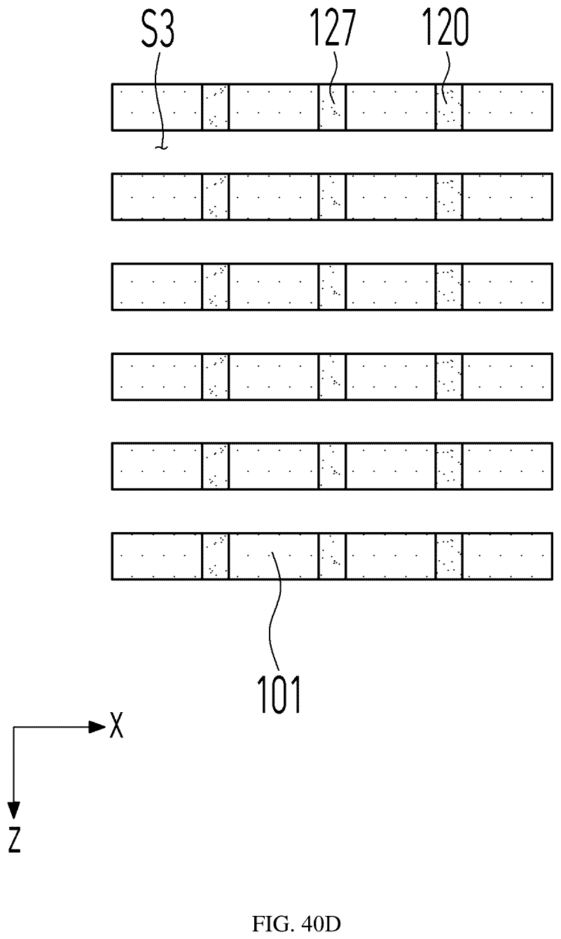

Hereinafter, the coupling structure of the unit needle pins 101 of the connecting portion 120 will be described with reference to FIGS. 39A to 40D. FIGS. 39A to 40D are plan views of the x-z plane at the position of the connecting portion 120 according to a preferred embodiment of the present invention.

The configuration of the connecting portion 120 described below may correspond to at least one of the connecting portion 120, the upper connecting portion 121, the lower connecting portion 123, and the intermediate connecting portion 125 described above.

Referring to FIGS. 39A to 39F, the connecting portion 120 connects the unit needle pins 101 to each other without gaps between the connecting portion 120 and the unit needle pins 101.

As shown in FIGS. 39A to 39C, in the configuration where the connecting portion 120 includes an inner connecting portion 127 and an outer connecting portion 129, the unit needle pins 101 are provided within a range smaller than the area of the connecting portion 120.

The outer connecting portion 129 may be provided at least one or more. Referring to FIG. 39A, the outer connecting portion 129 is formed across four sides. Referring to FIG. 39B, the outer connecting portion 129 is formed on two sides in the first direction (±x direction). Referring to FIG. 39C, the outer connecting portion 129 is formed on two sides in the second direction (±z direction). Referring to FIGS. 39D and 39E, the outer connecting portion 129 is formed on one side in the second direction (±z direction). Although FIGS. 39D and 39E illustrate the outer connecting portion 129 provided on one side in the second direction (±z direction), the outer connecting portion 129 may alternatively be formed on one side in the first direction (±x direction). Meanwhile, as shown in FIG. 39F, in the configuration where the connecting portion 120 includes only the inner connecting portion 127 and does not include the outer connecting portion 129, the unit needle pins 101 are provided within the area range of the connecting portion 120.

As the connecting portion 120 and the unit needle pins 101 are connected without gaps, it is possible to prevent foreign substances from entering the lower part of the connecting portion 120.

Referring to FIGS. 40A to 40D, the connecting portion 120 connects the unit needle pins 101 to each other while providing gaps S3 between the unit needle pins 101. The gaps S3 are provided between the unit needle pins 101, either between the unit needle pins 101 in the first direction (±x direction) or between the unit needle pins 101 in the second direction (±z direction).

Referring to FIG. 40A, the outer connecting portion 129 is formed on four sides, and the unit needle pins 101 are provided in the order of unit needle pin 101, gap S3, and unit needle pin 101 in the first direction (±x direction). Also, in the second direction (±z direction), the unit needle pins 101 are provided in the order of unit needle pin 101, connecting portion 120, and unit needle pin 101.

Referring to FIG. 40B, the outer connecting portion 129 is formed in a band shape in the first direction (±x direction) on two sides, and the unit needle pins 101 are provided in the order of unit needle pin 101, gap S3, and unit needle pin 101 in the first direction (±x direction). Also, in the second direction (±z direction), the unit needle pins 101 are provided in the order of unit needle pin 101, connecting portion 120, and unit needle pin 101. Additionally, the inner connecting portion 127 is provided in a band shape in the first direction (±x direction) to connect adjacent unit needle pins 101 to each other.

While FIGS. 40A and 40B show the configuration where the connecting portion 120 includes the inner connecting portion 127 and the outer connecting portion 129, FIG. 40C differs in that the connecting portion 120 includes only the inner connecting portion 127 and does not include the outer connecting portion 129.

Referring to FIG. 40C, the unit needle pins 101 are provided in the order of unit needle pin 101, gap S3, and unit needle pin 101 in the first direction (±x direction). Also, in the second direction (±z direction), the unit needle pins 101 are provided in the order of unit needle pin 101, connecting portion 120, and unit needle pin 101. Additionally, the inner connecting portion 127 is provided in a band shape in the first direction (±x direction) to connect adjacent unit needle pins 101 to each other.

Referring to FIG. 40D, in the first direction (±x direction) based on the unit needle pin 101, the unit needle pin 101, the connecting portion 120, and the unit needle pin 101 are repeatedly provided in sequence. Additionally, in the second direction (±z direction) based on the unit needle pin 101, the unit needle pin 101, the gap S3, and the unit needle pin 101 are repeatedly provided in sequence. Furthermore, the gap S3 is continuously provided in a band form in the first direction (±x direction).

In the configuration provided with the gap S3, a subsequent plating layer (not shown) can be formed on the side of the unit needle pin 101 and the side of the connecting portion 120 exposed through the gap S3.

In a structure without the gap S3, high-frequency current flows bypassing along the upper surface, side surface, and lower surface of the connecting portion 120. However, in a structure with the gap S3, the high-frequency current can flow directly along the side of the unit needle pin 101 and the side of the connecting portion 120 exposed through the gap S3 without bypassing. Therefore, the structure with the gap S3 has the effect of shortening the current path.

Meanwhile, in the previous description, the connecting portion 120 was described as being made of an electrically conductive material, but it is not limited to this, and the connecting portion 120 can be made of an electrically insulating material. The electrically insulating material here includes any insulating material that can bundle and fix the unit needle pins 101 together.

When the connecting portion 120 is made of an electrically insulating material, each unit needle pin 101 of the electrical connector 100 is not electrically connected to each other by the connecting portion 120.

As described above, although the preferred embodiments of the present invention have been described with reference to the accompanying drawings, those skilled in the art can variously modify or change the present invention without departing from the spirit and scope of the present invention as set forth in the following claims.

What is claimed is:

1. An electrical connector comprising:
a plurality of unit needle pins arranged to be spaced apart from each other and having beam portions extending in a longitudinal direction to be elastically deformed; and
a connecting portion fixing the plurality of unit needle pins to be spaced apart from each other.

2. The electrical connector of claim 1, wherein
the connecting portion is formed in a first direction and a second direction perpendicular to the longitudinal direction of the unit needle pin.

3. The electrical connector of claim 1, wherein
the unit needle pin includes a beam portion and a tip portion, and
the unit needle pins adjacent to each other are bundled to be spaced apart from each other through the connecting portion provided between the beam portion and the tip portion.

4. The electrical connector of claim 1, wherein
the unit needle pin includes a beam portion and a tip portion, and
the plurality of unit needle pins are connected to each other by the connecting portion, and each of the beam portions are spaced apart from each other and each of the tip portions are also spaced apart from each other.

5. An electrical connector comprising:
a deformation array having a plurality of beam portions extending in a longitudinal direction to be elastically deformed; and
a connecting portion to which the beam portions of the deformation array are connected.

6. The electrical connector of claim 5, wherein
the deformation array has the beam portions spaced apart from each other in a first direction.

7. The electrical connector of claim 5, wherein
the deformation array has the beam portions spaced apart from each other in the first direction and also spaced apart from each other in a second direction perpendicular to the first direction.

8. The electrical connector of claim 5, further comprising
a tip portion provided on an upper portion of the connecting portion.

9. The electrical connector of claim 8, wherein
the tip portion is provided to be spaced apart from each other in the first direction.

10. The electrical connector of claim 8, wherein
the tip portion is provided to be spaced apart from each other in the first direction and also spaced apart from each other in the second direction.

11. The electrical connector of claim 5, further comprising
a stopper preventing excessive compressive deformation of the deformation array.

12. The electrical connector of claim 5, wherein
a length dimension of the connecting portion in the first direction is greater than a length dimension of the deformation array in the first direction.

13. The electrical connector of claim 5, wherein
a length dimension of the connecting portion in the second direction is greater than a length dimension of the deformation array in the second direction.

14. The electrical connector of claim 5, wherein
a length dimension of the connecting portion in the first direction is greater than a length dimension of the deformation array in the first direction, and
a length dimension of the connecting portion in the second direction is greater than a length dimension of the deformation array in the second direction.

15. The electrical connector of claim 5, wherein
the connecting portion includes:
an upper connecting portion provided on an upper portion of the deformation array; and
a lower connecting portion provided on a lower portion of the deformation array.

16. The electrical connector of claim 15, further comprising:
an upper tip portion provided on an upper portion of the upper connecting portion; and
a lower tip portion provided on a lower portion of the lower connecting portion.

17. The electrical connector of claim 5, comprising
a subsequent plating layer formed on a surface of the electrical connector.

18. The electrical connector of claim 17, wherein
the subsequent plating layer is also provided inside the connecting portion by penetrating through the inside of the connecting portion.
